(19) United States
(12) Patent Application Publication
(10) Pub. No.: US 2021/0126195 A1
(43) Pub. Date: Apr. 29, 2021

(54) ORGANIC ELECTROLUMINESCENCE DEVICE AND POLYCYCLIC COMPOUND FOR ORGANIC ELECTROLUMINESCENCE DEVICE

(71) Applicant: Samsung Display Co., Ltd., Yongin-si (KR)

(72) Inventors: Hirokazu KUWABARA, Yokohama (JP); Ryuhei FURUE, Yokohama (JP)

(21) Appl. No.: 16/926,091

(22) Filed: Jul. 10, 2020

(30) Foreign Application Priority Data
Oct. 23, 2019 (KR) 10-2019-0132477

(51) Int. Cl. H01L 51/00; C07F 5/02; C09K 11/06

(52) U.S. Cl. CPC H01L 51/008; H01L 51/5012; C09K 11/06; C07F 5/027

(57) ABSTRACT

An organic electroluminescence device includes a first electrode, a hole transport region disposed on the first electrode, an emission layer disposed on the hole transport region, an electron transport region disposed on the emission layer, an electron transport region provided on the emission layer, and a second electrode disposed on the electron transport region, wherein the emission layer includes a polycyclic compound represented by Formula 1 to obtain high luminous efficiency:

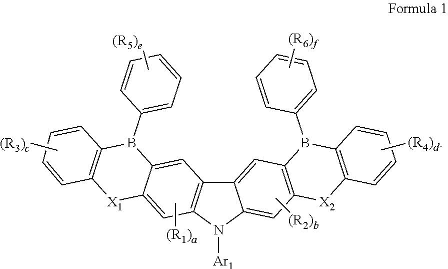

### CROSS-REFERENCE TO RELATED APPLICATIONS

This application claims priority to and the benefit of Korean Patent Application No. 10-2019-0132477, filed on Oct. 23, 2019, the entire content of which is hereby incorporated by reference.

### BACKGROUND

One or more aspects of embodiments of the present disclosure relate to an organic electroluminescence device and a polycyclic compound for an organic electroluminescence device.

Organic electroluminescence display devices are being actively conducted as image display devices. An organic electroluminescence display device is different from a liquid crystal display device and is a so-called a self-luminescent display device, in which holes and electrons respectively injected from a first electrode and a second electrode recombine in an emission layer, and thus a luminescent material including an organic compound in the emission layer may emit light to implement display.

In the application of an organic electroluminescence device to a display device, there is a demand for an organic electroluminescence device having a low driving voltage, high luminous efficiency, and/or a long lifespan, and materials for an organic electroluminescence device stably attaining such demands are being continuously developed.

In recent years, in order to implement a highly efficient organic electroluminescence device, material technologies using phosphorescence emission using triplet state energy, delayed fluorescence using triplet-triplet annihilation (TTA) (in which singlet excitons are generated by collision of triplet excitons), and/or thermally activated delayed fluorescence (TADF) phenomena are being developed.

### SUMMARY

One or more aspects of embodiments of the present disclosure are directed toward a long-life, highly efficient organic electroluminescence device, and a polycyclic compound used therein.

One or more aspects of embodiments of the present disclosure are directed toward an organic electroluminescence device including a thermally activated delayed fluorescence (TADF) emission material, and a polycyclic compound used as a thermally activated delayed fluorescence emission material.

One or more example embodiments of the present disclosure provide an organic electroluminescence device including a first electrode, a hole transport region disposed on the first electrode, an emission layer disposed on the hole transport region, an electron transport region disposed on the emission layer, and a second electrode disposed on the electron transport region, wherein the emission layer includes a polycyclic compound represented by Formula 1:

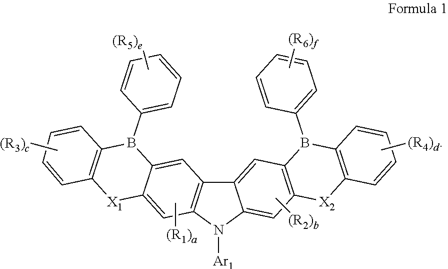

In Formula 1, X₁ and X₂ may each independently be NAr₂, O, or S, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms, R₁ to R₆ may each independently be a hydrogen atom, a deuterium atom, a halogen atom, a substituted or unsubstituted amine group, a substituted or unsubstituted thiol group, a substituted or unsubstituted alkoxy group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring, a and b may each independently be an integer of 0 to 2, c and d may each independently be an integer of 0 to 4, and e and f may each independently be an integer of 0 to 5.

The polycyclic compound represented by Formula 1 may be represented by Formula 2:

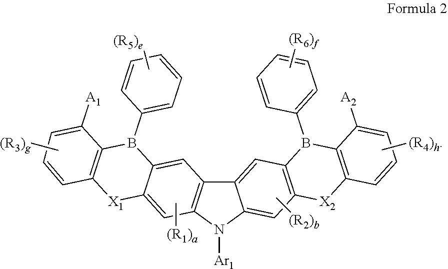

In Formula 2, A₁ and A₂ may each independently be NR₇R₈, OR₉, SR₁₀, or bonded to an adjacent group to form a ring, R₇ to R₁₀ are each independently a hydrogen atom, a deuterium atom, a substituted or unsubstituted alkyl group having 1 to 20 carbon atoms, a substituted or unsubstituted aryl group having 6 to 30 ring-form ing carbon atoms, a substituted or unsubstituted heteroaryl group having 2 to 30 ring-forming carbon atoms, or bonded to an adjacent group to form a ring, g and h are each independently an integer of 0 to 3, and X₁, X₂, Ar₁, R₁ to R₆, a, b, e and f are the same as defined in Formula 1.

The polycyclic compound represented by Formula 2 may be represented by Formula 3:

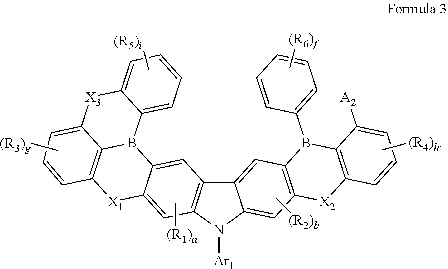

In Formula 3, X₃ may be NAr₃, O, or S, Ara may be a substituted or unsubstituted aryl group having 6 to 30 ring-forming carbon atoms or a substituted or unsubstituted heteroaryl group having 2 to 30 ring-forming carbon atoms, i may be an integer of 0 to 4, and A₂, X₁, X₂, Ar₁, R₁ to R₆, a, b, f, g and h may each independently be the same as defined in Formula 2.

The polycyclic compound represented by Formula 2 may be represented by Formula 4:

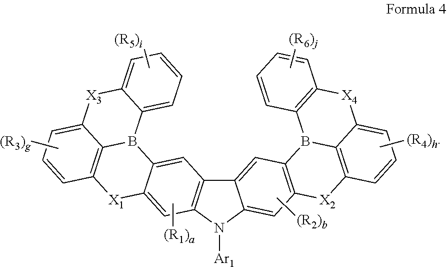

In Formula 4, X₃ and X₄ may each independently be NAr₃, O, or S, Ara may be a substituted or unsubstituted aryl group having 6 to 30 ring-forming carbon atoms or a substituted or unsubstituted heteroaryl group having 2 to 30 ring-forming carbon atoms, i and j may each independently be an integer of 0 to 4, and X₁, X₂, Ar₁, R₁ to R₆, a, b, g and h may each independently be the same as defined in Formula 2.

X₁ to X₄ may each independently be NAr₃ or O, and Ar₃ may be a substituted or unsubstituted aryl group having 6 to 30 ring-forming carbon atoms.

Ar₁ may be represented by Formula 5:

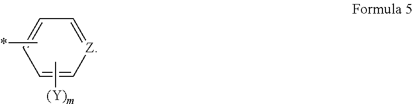

In Formula 5, Z may be CA₁ or N, A₁ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, Y may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and m may be an integer of 0 to 4.

R₅ and R₆ may each independently be a hydrogen atom, a deuterium atom, a substituted or unsubstituted alkyl group having 1 to 20 carbon atoms, or bonded to an adjacent group to form a ring.

X₁ and X₂ may each independently be NAr₂, and X₃ and X₄ may each independently be NAr₃.

X₁ and X₂ may each independently be NAr₂, and X₃ and X₄ may each independently be O.

X₁ and X₂ may each independently be O, and X₃ and X₄ may each independently be NAr₃.

X₁ to X₄ may each independently be O.

The compound represented by Formula 1 may be any one of the compounds represented by Compound Group 1.

One or more example embodiments of the present disclosure provide a polycyclic compound represented by Formula 1.

### BRIEF DESCRIPTION OF THE DRAWINGS

FIG. 1 is a schematic cross-sectional view illustrating an organic electroluminescence device according to an embodiment of the present disclosure;

FIG. 2 is a schematic cross-sectional view illustrating an organic electroluminescence device according to an embodiment of the present disclosure;

FIG. 3 is a schematic cross-sectional view illustrating an organic electroluminescence device according to an embodiment of the present disclosure; and

FIG. 4 is a schematic cross-sectional view illustrating an organic electroluminescence device according to an embodiment of the present disclosure.

### DETAILED DESCRIPTION

The present disclosure may have various modifications and may be embodied in different forms, and example embodiments will be explained in detail with reference to the accompany drawings. The present disclosure should not be construed as being limited to the embodiments set forth herein. Rather, all modifications, equivalents, and substitutions that are included in the spirit and technical scope of the present disclosure should be included in the present disclosure.

It will be understood that when an element or layer is referred to as being “on”, “connected to” or “coupled to” another element or layer, it can be directly on, connected or coupled to the other element or layer, or intervening element(s) or layer(s) may be present.

Like numbers refer to like elements throughout, and duplicative descriptions thereof may not be provided. Also, in the drawings, the thickness, the ratio, and the dimensions of elements may be exaggerated for an effective description of technical contents.

As used herein, the singular forms “a,” “an,” and “the” are intended to include the plural forms as well, unless the context clearly indicates otherwise. The term “and/or,” includes any and all combinations of one or more of the associated listed items. Further, the use of “may” when describing embodiments of the present disclosure refers to “one or more embodiments of the present disclosure”.

It will be understood that, although the terms “first”, “second”, etc. may be used herein to describe various elements, these elements should not be limited by these terms. These terms are only used to distinguish one element from another. For example, a first element could be alternatively termed a second element, and, similarly, a second element could be alternatively termed a first element, without departing from the scope of example embodiments of the present disclosure. The terms of a singular form may include plural forms unless the context clearly indicates otherwise.

In addition, terms such as “below,” “lower,” “above,” “upper,” and/or the like are used to describe the relationship of the configurations shown in the drawings. The terms are used as relative concepts, and are described with reference to the direction indicated in the drawings.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the terms “includes,” “including,” “comprises,” “comprising,” and/or “have” are intended to specify the presence of stated features, integers, steps, operations, elements, components, or combinations thereof in the disclosure, but do not preclude the presence or addition of one or more other features, integers, steps, operations, elements, components, or combinations thereof.

Hereinafter, an organic electroluminescence device according to an embodiment of the present disclosure and a compound of an embodiment included therein will be described with reference to the accompanying drawings.

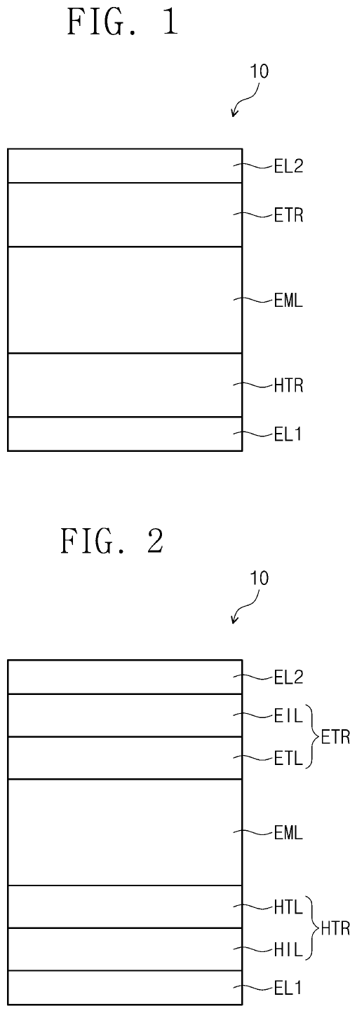

FIGS. 1 to 4 are schematic cross-sectional views illustrating an organic electroluminescence device according to an embodiment of the present disclosure. Referring to FIGS. 1 to 4, in an organic electroluminescence device 10 according to an embodiment, a first electrode EL1 and a second electrode EL2 are disposed to face each other and an emission layer EML may be disposed between the first electrode EL1 and the second electrode EL2.

The organic electroluminescence device 10 of an embodiment may further include a plurality of functional layers between the first electrode EL1 and the second electrode EL2 in addition to the emission layer EML. The plurality of functional layers may include a hole transport region HTR and an electron transport region ETR. For example, the organic electroluminescence device 10 according to an embodiment may include the first electrode EL1, the hole transport region HTR, the emission layer EML, the electron transport region ETR, and the second electrode EL2 stacked in sequence. In some embodiments, the organic electroluminescence device 10 of an embodiment may include a capping layer CPL disposed on the second electrode EL2.

The organic electroluminescence device 10 of an embodiment may include a polycyclic compound of an embodiment, which will be described later, in the emission layer EML disposed between the first electrode EL1 and the second electrode EL2. However, embodiments are not limited thereto, and the organic electroluminescence device 10 of an embodiment may include the polycyclic compound not only in the emission layer EML but also in the hole transport region HTR and/or electron transport region ETR (which are among the plurality of functional layers disposed between the first electrode EL1 and the second electrode EL2), or in the capping layer CPL disposed on the second electrode EL2.

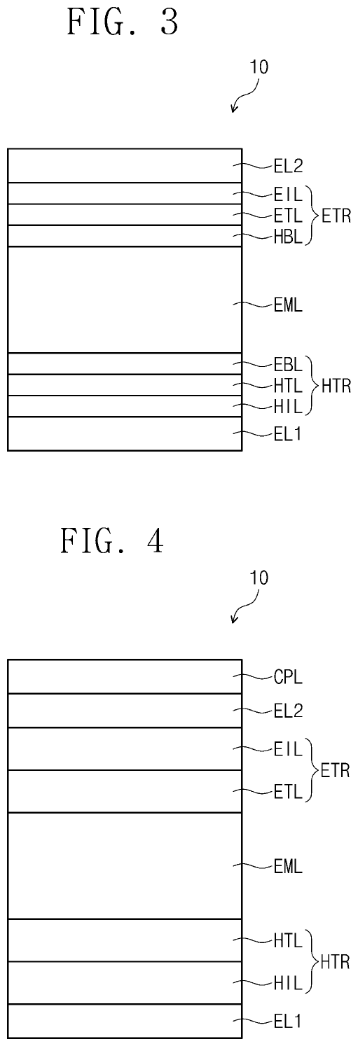

FIG. 2 illustrates a cross-sectional view of an organic electroluminescence device 10 of an embodiment, in which the hole transport region HTR includes a hole injection layer HIL and a hole transport layer HTL, and the electron transport region ETR includes an electron injection layer EIL and an electron transport layer ETL. FIG. 3 illustrates a cross-sectional view of an organic electroluminescence device 10 of an embodiment, in which the hole transport region HTR includes the hole injection layer HIL, the hole transport layer HTL, and an electron blocking layer EBL, and the electron transport region ETR includes the electron injection layer EIL, the electron transport layer ETL, and a hole blocking layer HBL. FIG. 4 illustrates a cross-sectional view of an organic electroluminescence device 10 of an embodiment including a capping layer CPL disposed on the second electrode EL2.

The first electrode EL1 may have conductivity (e.g., may be conductive). The first electrode EL1 may be formed of a metal alloy and/or a conductive compound. The first electrode EL1 may be a pixel electrode or an anode. The first electrode EL1 may be a transmissive electrode, a transflective electrode, or a reflective electrode. When the first electrode EL1 is a transmissive electrode, the first electrode EL1 may include a transparent metal oxide (such as indium tin oxide (ITO), indium zinc oxide (IZO), zinc oxide (ZnO), and/or indium tin zinc oxide (ITZO)). When the first electrode EL1 is a transflective electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca, LiF/Al, molybdenum (Mo), titanium (Ti), indium (In), tin (Sn), zinc (Zn), a compound thereof, a mixture thereof (for example, a mixture of Ag and Mg) or an oxide thereof. In some embodiments, the first electrode EL1 may have a multilayer structure including a reflective layer and/or a transflective layer, and a transmissive layer formed of ITO, IZO, ZnO, ITZO, etc. For example, the first electrode EL1 may have a three-layer structure of ITO/Ag/ITO, but embodiments of the present disclosure are not limited thereto. The first electrode EL1 may have a three-layer structure of ITO/Ag/ITO, but embodiments of the present disclosure are not limited thereto. The thickness of the first electrode EU may be about 1,000 Å to about 10,000 Å, for example, about 1,000 Å to about 3,000 Å.

The hole transport region HTR may be provided on the first electrode EL1. The hole transport region HTR may include at least one of a hole injection layer HIL, a hole transport layer HTL, a hole buffer layer, or an electron blocking layer EBL.

The hole transport region HTR may have or be a single layer formed of a single material, a single layer formed of a plurality of different materials, or a multilayer structure including a plurality of layers formed of a plurality of different materials.

For example, the hole transport region HTR may have a single layer structure of a hole injection layer HIL or a hole transport layer HTL, or may have a single layer structure formed of a hole injection material and a hole transport material. In some embodiments, the hole transport region HTR may have a single layer structure formed of a plurality of different materials, or a structure in which a hole injection layer

HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer EBL are stacked in order from the first electrode EL1, but embodiments are not limited thereto.

The hole transport region HTR may be formed using any suitable method (such as a vacuum deposition method, a spin coating method, a cast method, a Langmuir-Blodgett (LB) method, an inkjet printing method, a laser printing method, and/or a laser induced thermal imaging (LITI) method).

The hole injection layer HIL may include, for example, a phthalocyanine compound (such as copper phthalocyanine; N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris{N,-(2-naphthyl)-N-phenylamino)-triphenylamine (2-TNATA), poly(3,4-ethylene dioxythiophene)/poly(4-styrene sulfonate) (PEDOT/PSS), polyaniline/dodecylbenzene sulfonic acid (PANI/DBSA), polyaniline/camphor sulfonic acid (PANI/CSA), polyaniline/poly(4-styrene sulfonate) (PANI/PSS), N,N′-di(naphthalene-1-yl)-N,N′-diphenyl-benzidine (NPD), triphenylamine-containing polyether ketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

The hole transport layer HTL may include any suitable material available in the art. For example, the hole transport layer HTL may further include carbazole derivatives (such as N-phenyl carbazole and/or polyvinyl carbazole), fluorine derivatives, N,N′-bis(3-methylphenyl)-N,N′-diphenyl-[1,1-biphenyl]-4,4′-diamine (TPD), triphenylamine derivatives (such as 4,4′,4″-tris(N-carbazolyl)triphenylamine (TCTA)), N,N′-di(1-naphthalene-1-yl)-N,N′-diphenyl-benzidine (NPD), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The electron blocking layer EBL may include, for example, carbazole derivatives (such as N-phenyl carbazole and/or polyvinyl carbazole), fluorine derivatives, N,N′-bis(3-methylphenyl)-N,N′-diphenyl-[1,1-biphenyl]-4,4′-diamine (TPD), triphenylamine derivatives (such as 4,4′,4″-tris(N-carbazolyl)triphenylamine (TCTA)), N,N′-di(1-naphthalene-1-yl)-N,N′-diphenyl-benzidine (NPD), 4,4′-cyclohexylidene bis[N,N-bis(4-methylphenyl]benzenamine] (TAPC), 3,3′-Dimethyl-N4, N4, N4′, N4′-tetra-m-tolyl-[1,1′-biphenyl]-4,4′-diamine (HMTPD), mCP, etc.

The thickness of the hole transport region HTR may be about 50 Å to about 15,000 Å, for example, about 100 Å to about 5,000 Å. The thickness of the hole injection region HIL may be, for example, about 30 Å to about 1,000 Å, and the thickness of the hole transport layer HTL may be about 30 Å to about 1,000 Å. For example, the thickness of the electron blocking layer EBL may be about 10 Å to about 1,000 Å. When the thicknesses of the hole transport region HTR, the hole injection layer HIL, the hole transport layer HTL and/or the electron blocking layer EBL satisfy the above-described ranges, satisfactory hole transport properties may be achieved without a substantial increase in driving voltage.

The hole transport region HTR may further include, in addition to the above-described materials, a charge generating material to increase conductivity. The charge generating material may be dispersed substantially uniformly or non-uniformly in the hole transport region HTR. The charge generating material may be, for example, a p-dopant. The p-dopant may be or include a quinone derivative, a metal oxide, or a cyano group-containing compound, but is not limited thereto. Non-limiting examples of the p-dopant include quinone derivatives (such as tetracyanoquinodimethane (TCNQ) and/or 2,3,5,6-tetrafluoro-7,7,8,8-tetracyanoquinodimethane (F4-TCNQ)), metal oxides (such as tungsten oxide and/or molybdenum oxide), etc.

In some embodiments, the hole transport region HTR may further include at least one of a hole buffer layer or an electron blocking layer EBL in addition to the hole injection layer HIL and the hole transport layer HTL. The hole buffer layer may compensate for a resonance distance according to the wavelength of light emitted from an emission layer EML, and may thereby increase light emission efficiency. The materials that may be included in the hole transport region HTR may be included in the hole buffer layer. The electron blocking layer EBL may prevent or reduce electrons from being injected from the electron transport region ETR to the hole transport region HTR.

The emission layer EML is provided on the hole transport region HTR. The thickness of the emission layer EML may be, for example, about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML may be to emit one of red, green, blue, white, yellow or cyan light. The emission layer EML may include a fluorescence-emitting material or a phosphorescence-emitting material.

In an embodiment, the emission layer EML may be a fluorescence emission layer. For example, some of the light emitted from the emission layer EML may result from thermally activated delayed fluorescence (TADF). For example, the emission layer EML may include a luminescent component to emit thermally activated delayed fluorescence, and in an embodiment, the emission layer EML may be an emission layer to emit blue light via thermally activated delayed fluorescence.

The emission layer EML of the organic electroluminescence device 10 of an embodiment includes a polycyclic compound according to an embodiment of the present disclosure.

In the description, the term “substituted or unsubstituted” may indicate that one (e.g., a group or position) may be unsubstituted, or substituted with at least one substituent selected from the group consisting of a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkoxy group, a hydrocarbon ring group, an aryl group, and a heterocyclic group. In addition, each of the substituents may be further substituted or unsubstituted. For example, a biphenyl group may be interpreted as an aryl group or a phenyl group substituted with a phenyl group.

In the description, the term “bonded to an adjacent group to form a ring” may indicate that one (e.g., a group or position) is bonded to an adjacent group to form a substituted or unsubstituted hydrocarbon ring, or a substituted or unsubstituted heterocycle. The term “hydrocarbon ring” includes an aliphatic hydrocarbon ring and an aromatic hydrocarbon ring. The term “heterocycle” includes an aliphatic heterocycle and an aromatic heterocycle. The rings formed by being bonded to an adjacent group may be monocyclic or polycyclic. In addition, rings may be connected to other rings to form a spiro structure.

In the description, the term “adjacent group” may refer to a substituent on the same atom or point, a substituent on an atom that is directly connected to the base atom or point, or a substituent sterically positioned (e.g., within intramolecular bonding distance) to the corresponding substituent. For example, in 1,2-dimethylbenzene, the two methyl groups may be interpreted as “adjacent groups” to each other, and in 1,1-diethylcyclopentane, the two ethyl groups may be interpreted as “adjacent groups” to each other.

In the description, non-limiting examples of the halogen atom include a fluorine atom, a chlorine atom, a bromine atom and an iodine atom.

In the description, the alkyl group may be a linear, branched or cyclic type. The number of carbon atoms in the alkyl group may be 1 to 50, 1 to 30, 1 to 20, 1 to 10, or 1 to 6. Non-limiting examples of the alkyl group include methyl, ethyl, n-propyl, isopropyl, n-butyl, s-butyl, t-butyl, i-butyl, 2-ethylbutyl, 3,3-dimethylbutyl, n-pentyl, pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, c-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc.

In the description, the term “alkenyl group” may refer to a hydrocarbon group including at least one carbon-carbon double bond in the middle or at the terminus of an alkyl group having 2 or more carbon atoms. The alkenyl group may be linear or branched. The number of carbon atoms is not specifically limited, and may be 2 to 30, 2 to 20, or 2 to 10. Non-limiting examples of the alkenyl group include a vinyl group, a 1-butenyl group, a 1-pentenyl group, a 1,3-butadienyl aryl group, a styrenyl group, a styryl vinyl group, etc.

In the description, the term “alkynyl group” may refer to a hydrocarbon group including at least one carbon-carbon triple bond in the middle or at the terminus of an alkyl group having 2 or more carbon atoms. The alkynyl group may be linear or branched. The number of carbon atoms is not specifically limited, and may be 2 to 30, 2 to 20, or 2 to 10. Non-limiting examples of the alkynyl group may include an ethynyl group, a propynyl group, etc.

In the description, the term “hydrocarbon ring group” may refer to any functional group or substituent derived from an aliphatic hydrocarbon ring, or an any functional group or substituent derived from an aromatic hydrocarbon ring. The number of ring-forming carbon atoms in the hydrocarbon ring group may be 5 to 60, 5 to 30, or 5 to 20.

In the description, the term “aryl group” may refer to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Non-limiting examples of the aryl group include phenyl, naphthyl, fluorenyl, anthracenyl, phenanthryl, biphenyl, terphenyl, quaterphenyl, quinqphenyl, sexiphenyl, triphenylenyl, pyrenyl, benzofluoranthenyl, chrysenyl, etc.

In the description, the term “heterocyclic group” may refer to any functional group or substituent derived from a ring containing at least one of boron (B), oxygen (O), nitrogen (N), phosphorus (P), silicon (Si), or sulfur (S) as a hetero atom. When the heterocyclic group contains two or more hetero atoms, the two or more hetero atoms may be the same as or different from each other. The heterocyclic group may be an aliphatic heterocyclic group or an aromatic heterocyclic group. The aromatic heterocyclic group may be a heteroaryl group. The aliphatic heterocycle and aromatic heterocycle may each independently be monocyclic or polycyclic. The number of ring-form ing carbon atoms in in the heterocyclic group may be 2 to 30, 2 to 20, or 2 to 10.

In the description, the term “aliphatic heterocyclic group” may include at least one of B, O, N, P, Si, or S as a hetero atom. The number of ring-forming carbon atoms in the aliphatic heterocyclic group may be 2 to 30, 2 to 20, or 2 to 10. Non-limiting examples of the aliphatic heterocyclic group include an oxirane group, a thiirane group, a pyrrolidine group, a piperidine group, a tetrahydrofuran group, a tetrahydrothiophene group, a thiane group, a tetrahydropyran group, a 1,4-dioxane group, etc.

Non-limiting examples of the heteroaryl group include a thiophenyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, a triazolyl group, an acridyl group, a pyridazinyl group, a pyrazinyl group, a quinolinyl group, a quinazolinyl group, a quinoxalinyl group, a phenoxazinyl group, a phthalazinyl group, a pyrido pyrimidyl group, a pyrido pyrazinyl group, a pyrazino pyrazinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzimidazolyl group, a benzothiazolyl group, a benzocarbazolyl group, a benzothiophenyl group, a dibenzothiophenyl, a thienothiophenyl group, a benzofuranyl, a phenanthrolinyl group, a thiazolyl group, an isoxazolyl group, an oxadiazolyl group, a thiadiazolyl group, a phenothiazolyl group, a phenothiazinyl group, a dibenzosilolyl group, a dibenzofuranyl group, etc.

In the description, the number of carbon atoms in an amine group is not particularly limited, but may be 1 to 30. The amine group may include an alkyl amine group, an aryl amine group, or a heteroaryl amine group. Non-limiting examples of the amine group include a methylamine group, a dimethylamine group, a phenylamine group, a diphenylamine group, a naphthylamine group, a 9-methyl-anthracenylamine group, a triphenylamine group, etc.

In the description, the term “thiol group” may include an alkylthio group and an arylthio group.

In the description, the term “alkoxy group” may be linear, branched or cyclic. The number of carbon atoms in the alkoxy group is not particularly limited, and for example, may be 1 to 20 or 1 to 10. Non-limiting examples of an oxy group include methoxy, ethoxy, n-propoxy, isopropoxy, butoxy, pentyloxy, hexyloxy, octyloxy, nonyloxy, decyloxy, benzyloxy, etc.

In the description, “-⋅” refers to a position to be connected.

The polycyclic compound according to an embodiment of the present disclosure is represented by Formula 1:

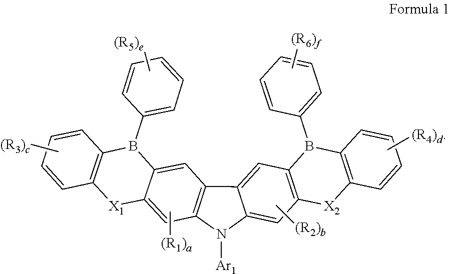

In Formula 1, X₁ and X₂ may each independently be NAr₂, O, or S.

In Formula 1, Ar₁ and Are may each independently be a substituted or unsubstituted aryl group having 6 to 30 ring-forming carbon atoms or a substituted or unsubstituted heteroaryl group having 2 to 30 ring-forming carbon atoms.

In Formula 1, R₁ to R₆ may each independently be a hydrogen atom, a deuterium atom, a halogen atom, a substituted or unsubstituted amine group, a substituted or unsubstituted thiol group, a substituted or unsubstituted alkoxy group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula 1, a and b may each independently be an integer of 0 to 2. When a is 2, a plurality of R₁'s may be the same as or different from each other, and when b is 2, a plurality of R₂'s may be the same as or different from each other.

In Formula 1, c and d may each independently be an integer of 0 to 4. When c is 2 or more, a plurality of R₃'s may be the same as or different from each other, and when d is 2 or more, a plurality of R₄'s may be the same as or different from each other.

In Formula 1, e and f may each independently be an integer of 0 to 5. When e is 2 or more, a plurality of R₅'s may be the same as or different from each other, and when f is 2 or more, a plurality of R₆'s may be the same as or different from each other.

In an embodiment, Formula 1 may be represented by Formula 2:

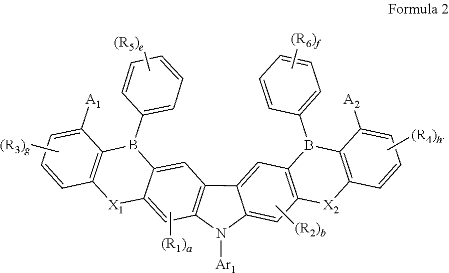

In Formula 2, A₁ and A₂ may each independently be NR₇R₈, OR₉, SR₁₀, or may be bonded to an adjacent group to form a ring. Here, the bonding of A₁ and/or A₂ to an adjacent group to form a ring means that, for example, when A₁ and/or A₂ is NR₇R₈, OR₉, or SR₁₀, the R substituent of that group may be bonded to a sterically adjacent benzene ring and N, O, or S to form a ring.

In Formula 2, R₇ to R₁₀ may each independently be a hydrogen atom, a deuterium atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula 2, g and h may each independently be an integer of 0 to 3. When g is an integer of 2 or more, a plurality of R₃'s may be the same as or different from each other, and when h is an integer of 2 or more, a plurality of R₄'s may be the same as or different from each other.

In Formula 2, X₁, X₂, Ar₁, R₁ to R₆, a, b, e and f may each independently be the same as defined in Formula 1.

In an embodiment, A₁ of Formula 2 may be bonded to the adjacent benzene ring substituent on the neighboring boron atom (B) to form a fused ring. For example, Formula 2 may be represented by Formula 3:

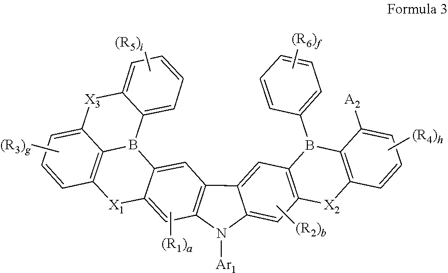

In Formula 3, X₃ may be NAr₃, O, or S.

In Formula 3, Ar₃ may be a substituted or unsubstituted aryl group having 6 to 30 ring-forming carbon atoms or a substituted or unsubstituted heteroaryl group having 2 to 30 ring-forming carbon atoms.

In Formula 3, i may be an integer of 0 to 4. When i is an integer of 2 or more, a plurality of R₅'s may be the same as or different from each other.

In Formula 3, A₂, X₁, X₂, Ar₁, R₁ to R₆, a, b, f, g and h may each independently be the same as defined in Formula 2.

In an embodiment, A₁ and A₂ may be bonded to a benzene ring bonded to a boron atom (B) to form a ring. For example, Formula 2 may be represented by Formula 4:

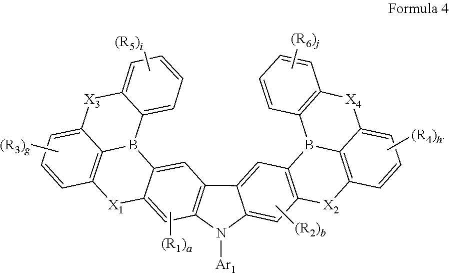

In Formula 4, X₃ and X₄ may each independently be NAr₃, O, or S.

In Formula 4, Ar₃ may be a substituted or unsubstituted aryl group having 6 to 30 ring-forming carbon atoms or a substituted or unsubstituted heteroaryl group having 2 to 30 ring-forming carbon atoms.

In Formula 4, i and j may each independently be an integer of 0 to 4. When i is an integer of 2 or more, a plurality of R₅'s may be the same as or different from each other, and when j is an integer of 2 or more, a plurality of R₆'s may be the same as or different from each other.

In Formula 4, X₁, X₂, Ar₁, R₁ to R₆, a, b, g and h may each independently be the same as defined in Formula 2.

In an embodiment, X₁ to X₄ in Formula 4 may each independently be NAr₃ or O.

In an embodiment, Ar₃ in Formula 3 or Formula 4 may be a substituted or unsubstituted aryl group having 6 to 30 ring-forming carbon atoms.

In an embodiment, Ar₁ in Formula 1 to Formula 4 may be represented by Formula 5:

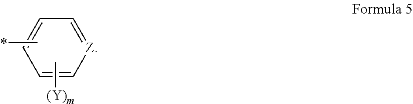

In Formula 5, Z may be CA₁ or N.

In Formula 5, A₁ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 5, Y may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 5, m may be an integer of 0 to 4. When m is an integer of 2 or more, a plurality of Y's may be the same as or different from each other.

In the Formula 5, “-⋅” refers to a position connected to N in Formula 1 to Formula 4.

In an embodiment, R₅ and R₆ of Formulas 1 to 4 may each independently be a hydrogen atom, a deuterium atom, a substituted or unsubstituted alkyl group having 1 to 20 carbon atoms, or may be bonded to an adjacent group to form a ring.

In an embodiment, X₁ and X₂ in Formula 4 may each independently be NAr₂, and X₃ and X₄ may each independently be NAr₃. For example, Formula 4 may be represented by Formula 6:

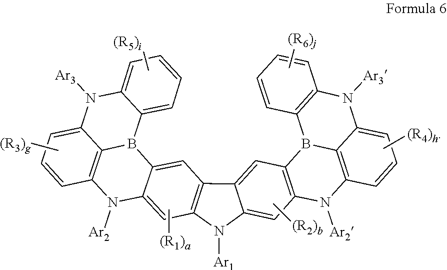

In Formula 6, Ar₂′ and Ar₃′ may each independently be a substituted or unsubstituted aryl group having 6 to 30 ring-forming carbon atoms or a substituted or unsubstituted heteroaryl group having 2 to 30 ring-forming carbon atoms.

In Formula 6, Ar₁ to Ar₃, R₁ to R₆, a, b, g, h, i and j may each independently be the same as defined in Formula 4.

In an embodiment, X₁ and X₂ in Formula 4 may each independently be O, and X₃ and X₄ may each independently be NAr₃. For example, Formula 4 may be represented by Formula 7:

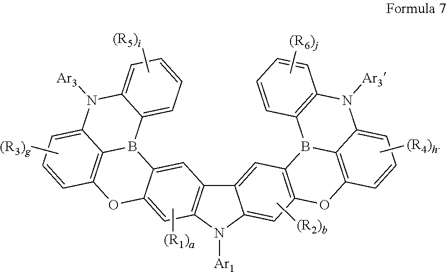

In Formula 7, Ar₃′ may be a substituted or unsubstituted aryl group having 6 to 30 ring-forming carbon atoms or a substituted or unsubstituted heteroaryl group having 2 to 30 ring-forming carbon atoms.

In Formula 7, Ar₁, Ar₃, R₁ to R₆, a, b, g, h, i and j may each independently be the same as defined in Formula 4.

In an embodiment, X₁ and X₂ in Formula 4 may each independently be NAr₂, and X₃ and X₄ may each independently be O. For example, Formula 4 may be represented by Formula 8:

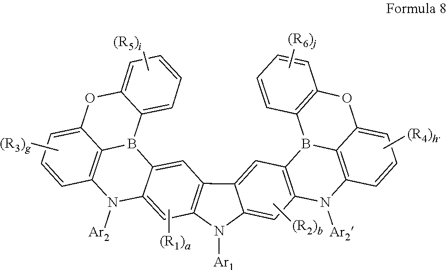

In Formula 8, Ar₂′ may be a substituted or unsubstituted aryl group having 6 to 30 ring-forming carbon atoms or a substituted or unsubstituted heteroaryl group having 2 to 30 ring-forming carbon atoms.

In Formula 8, Ar₁, Ar₂, R₁ to R₆, a, b, g, h, i and j may each independently be the same as defined in Formula 4.

In an embodiment, X₁ to X₄ in Formula 4 may each independently be O. For example, Formula 4 may be represented by Formula 9:

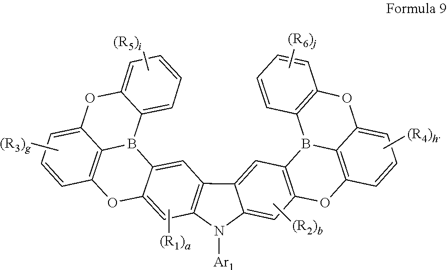

In Formula 9, Ar₁, R₁ to R₆, a, b, g, h, i and j may each independently be the same as defined in Formula 4.

In an embodiment, X₁ in Formula 4 may be NAr₂, X₂ may be O, and X₃ and X₄ may each independently be NAr₃. For example, Formula 4 may be represented by Formula 10:

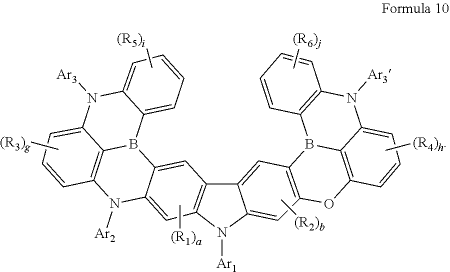

In Formula 10, Ar₃′ may be a substituted or unsubstituted aryl group having 6 to 30 ring-forming carbon atoms or a substituted or unsubstituted heteroaryl group having 2 to 30 ring-forming carbon atoms.

In Formula 10, Ar₁, Ar₂, Ar₃, R₁ to R₆, a, b, g, h, i and j may each independently be the same as defined in Formula 4.

In an embodiment, the polycyclic compound represented by Formula 1 may be any one selected from the compounds represented by Compound Group 1. However, the present disclosure is not limited thereto.

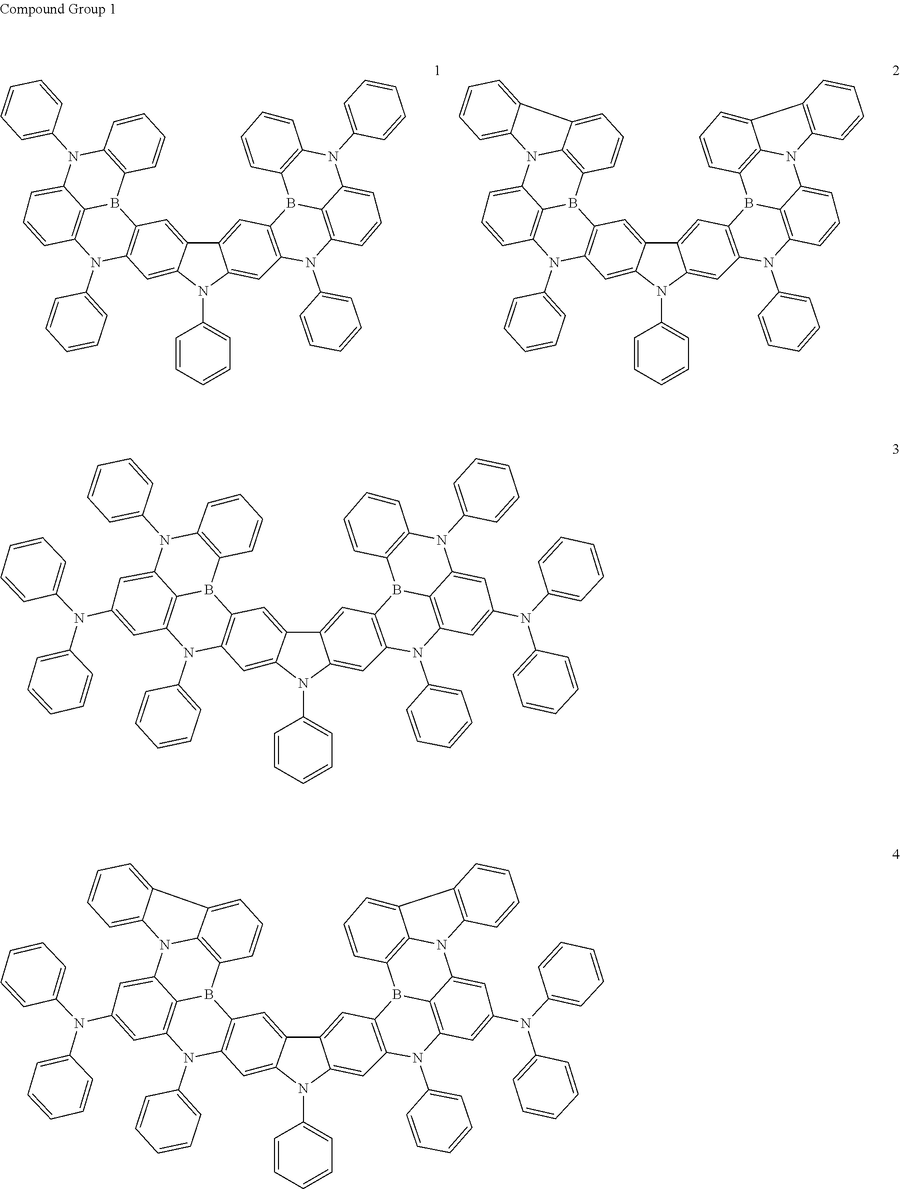

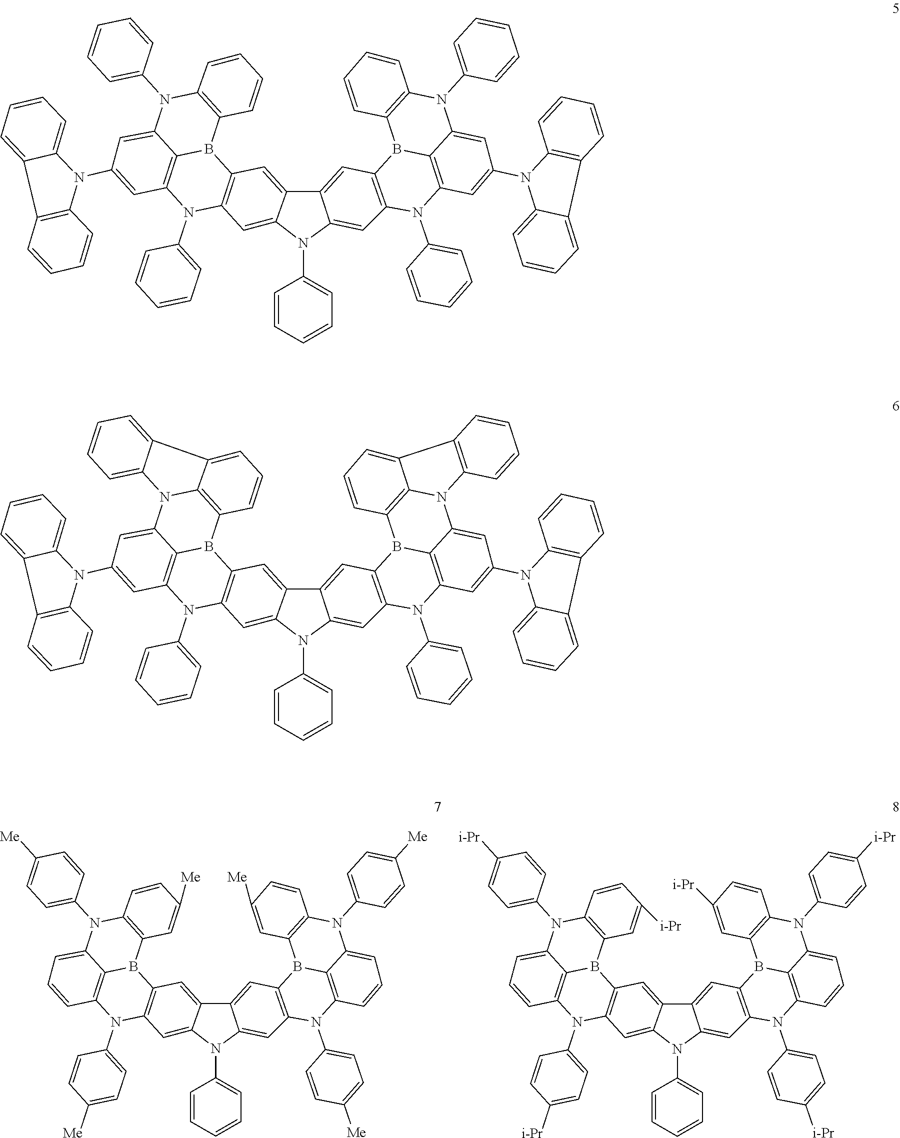

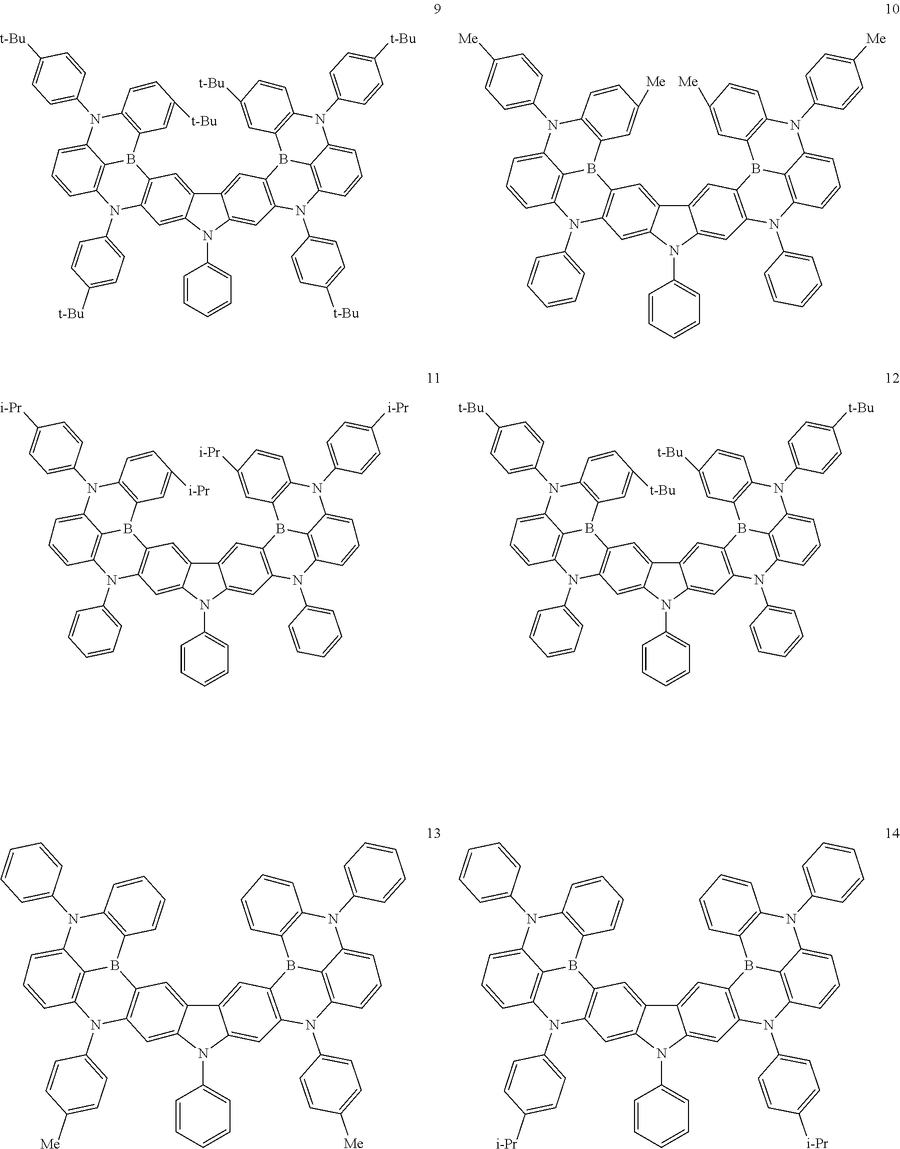

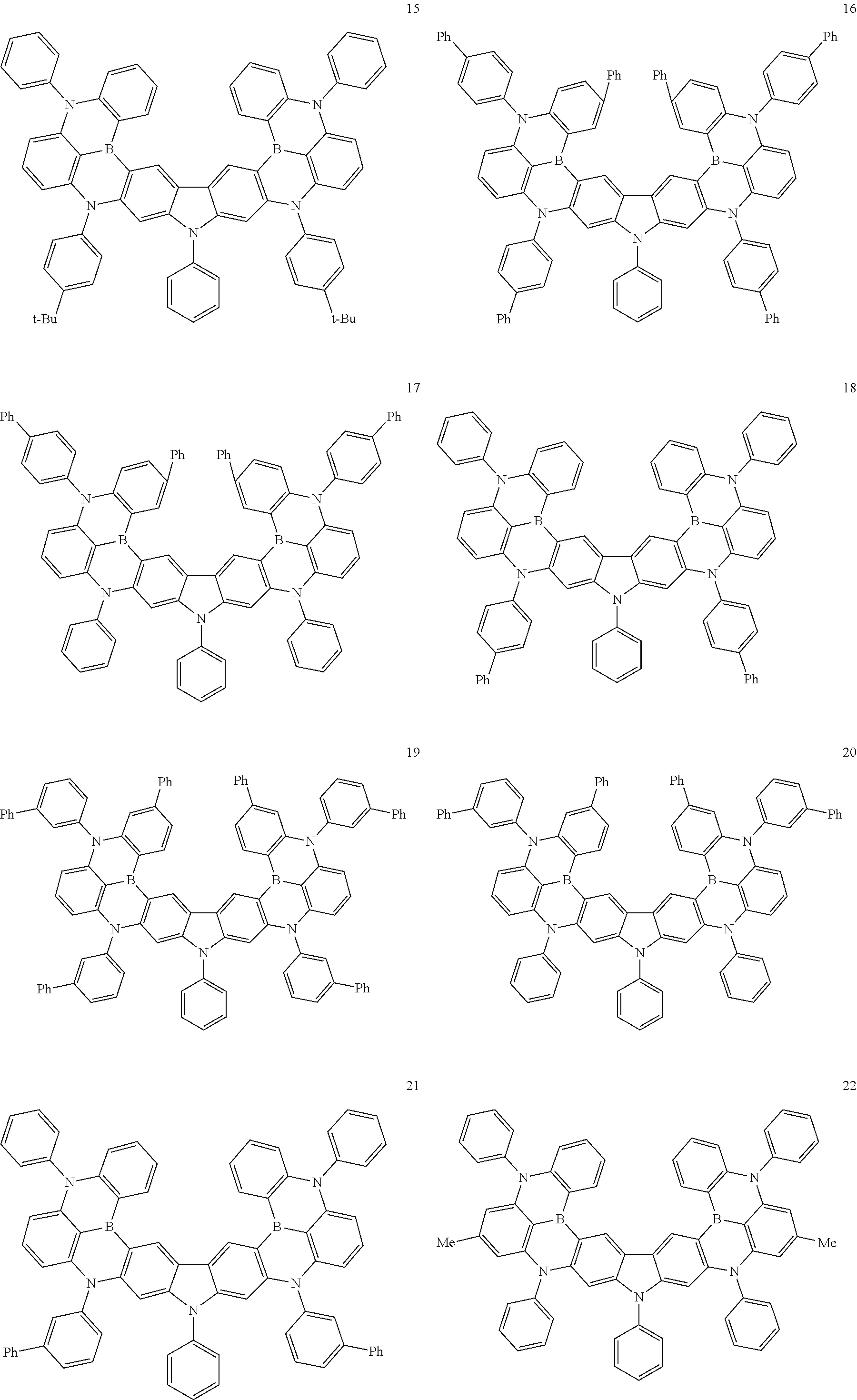

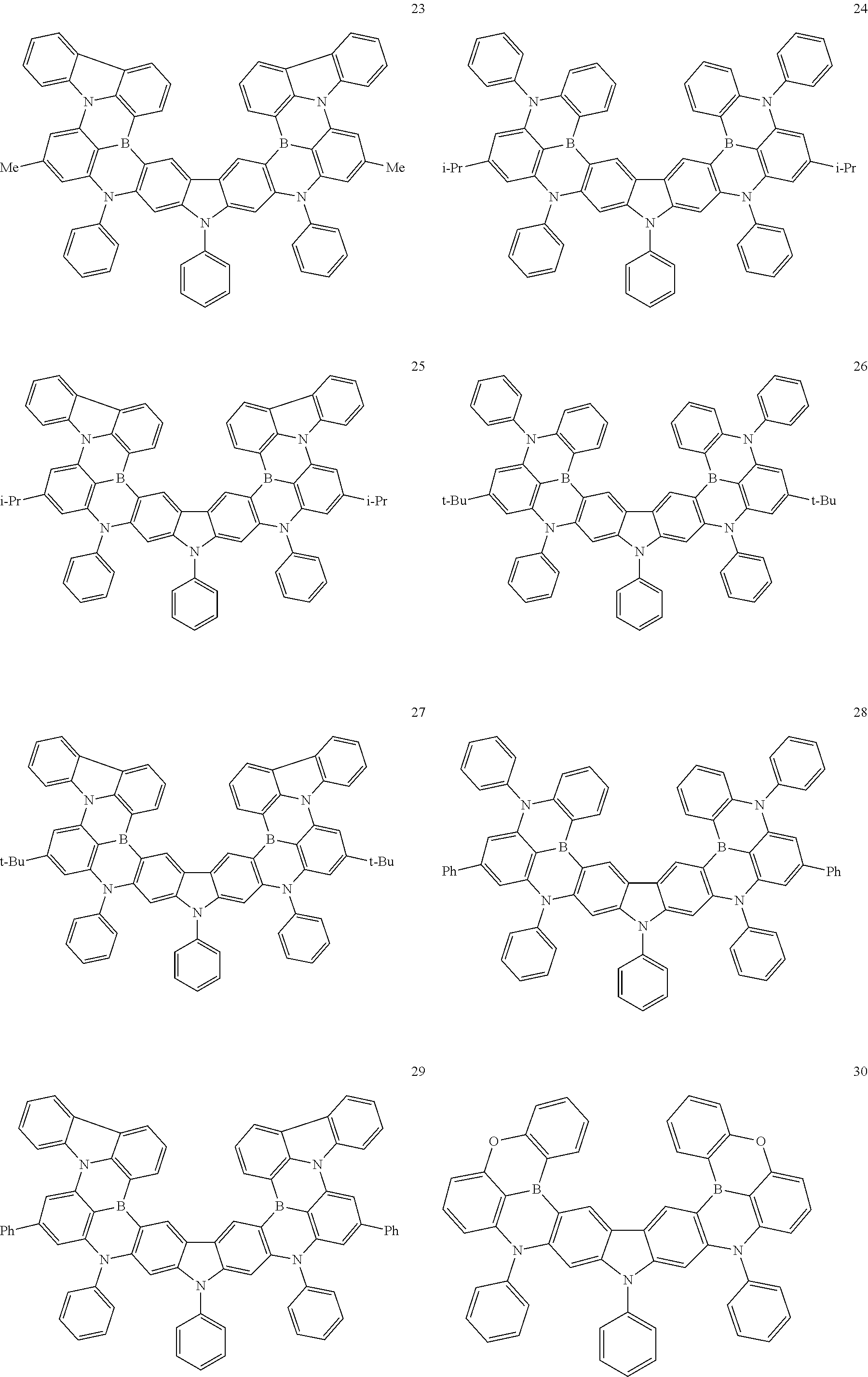

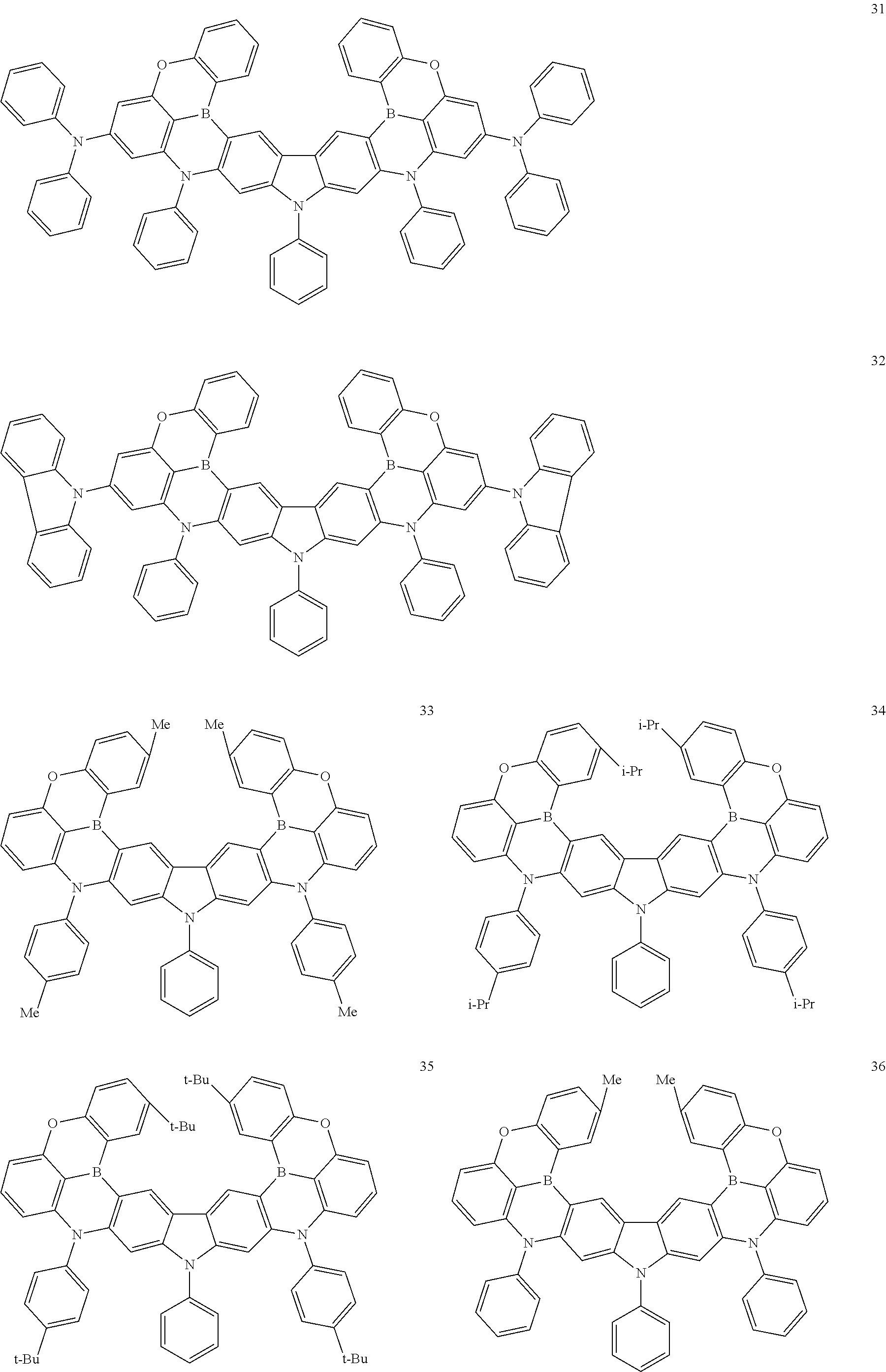

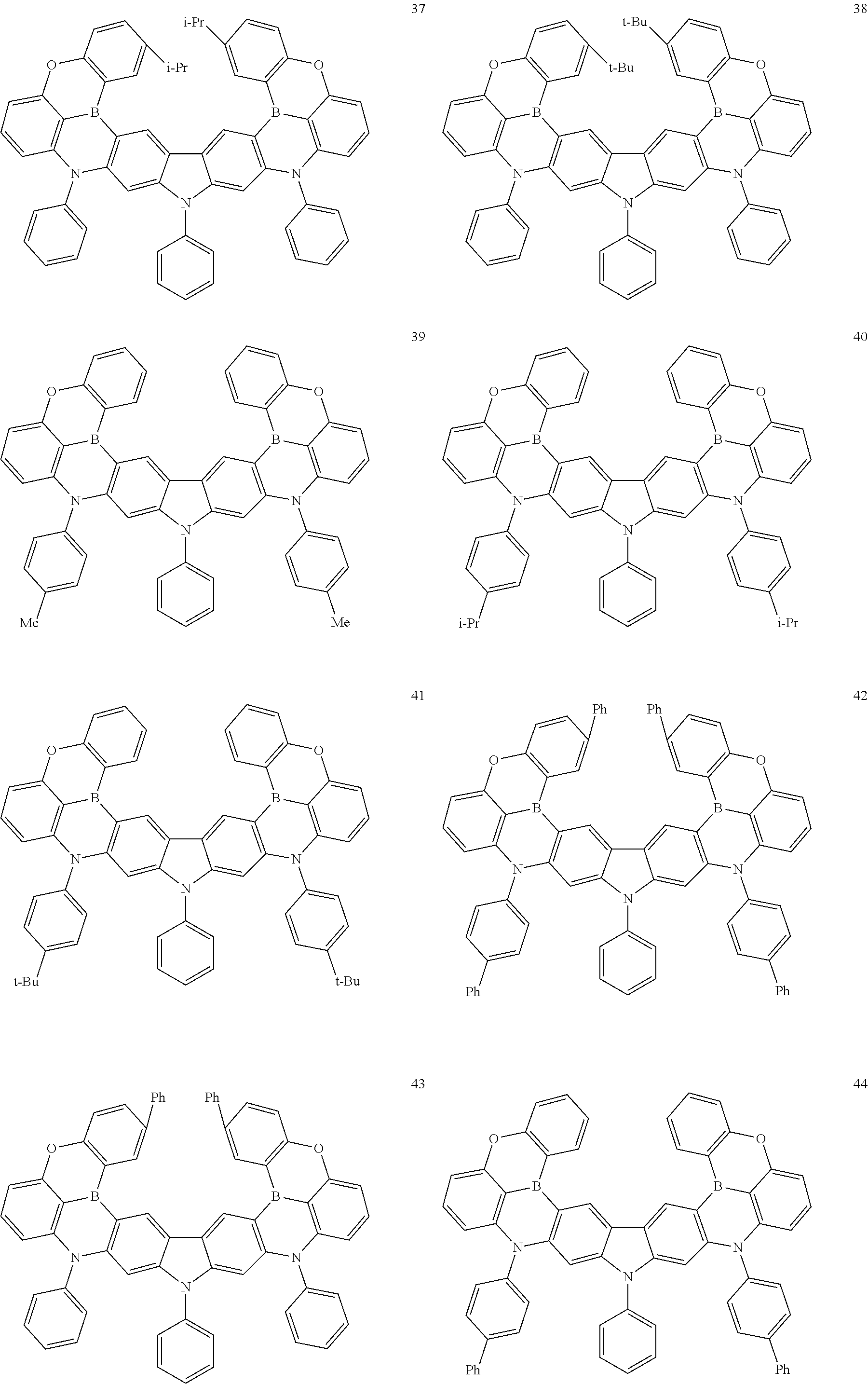

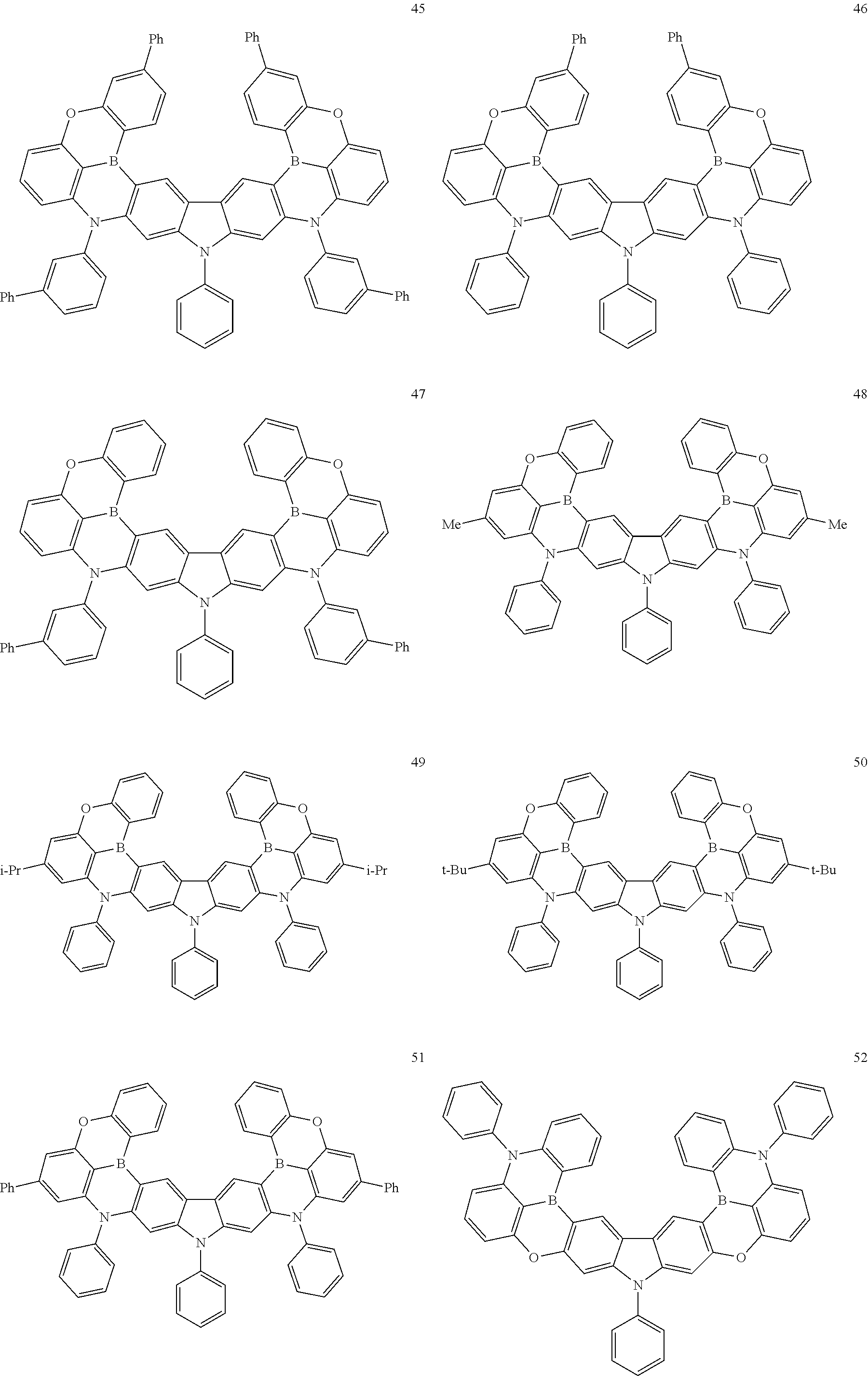

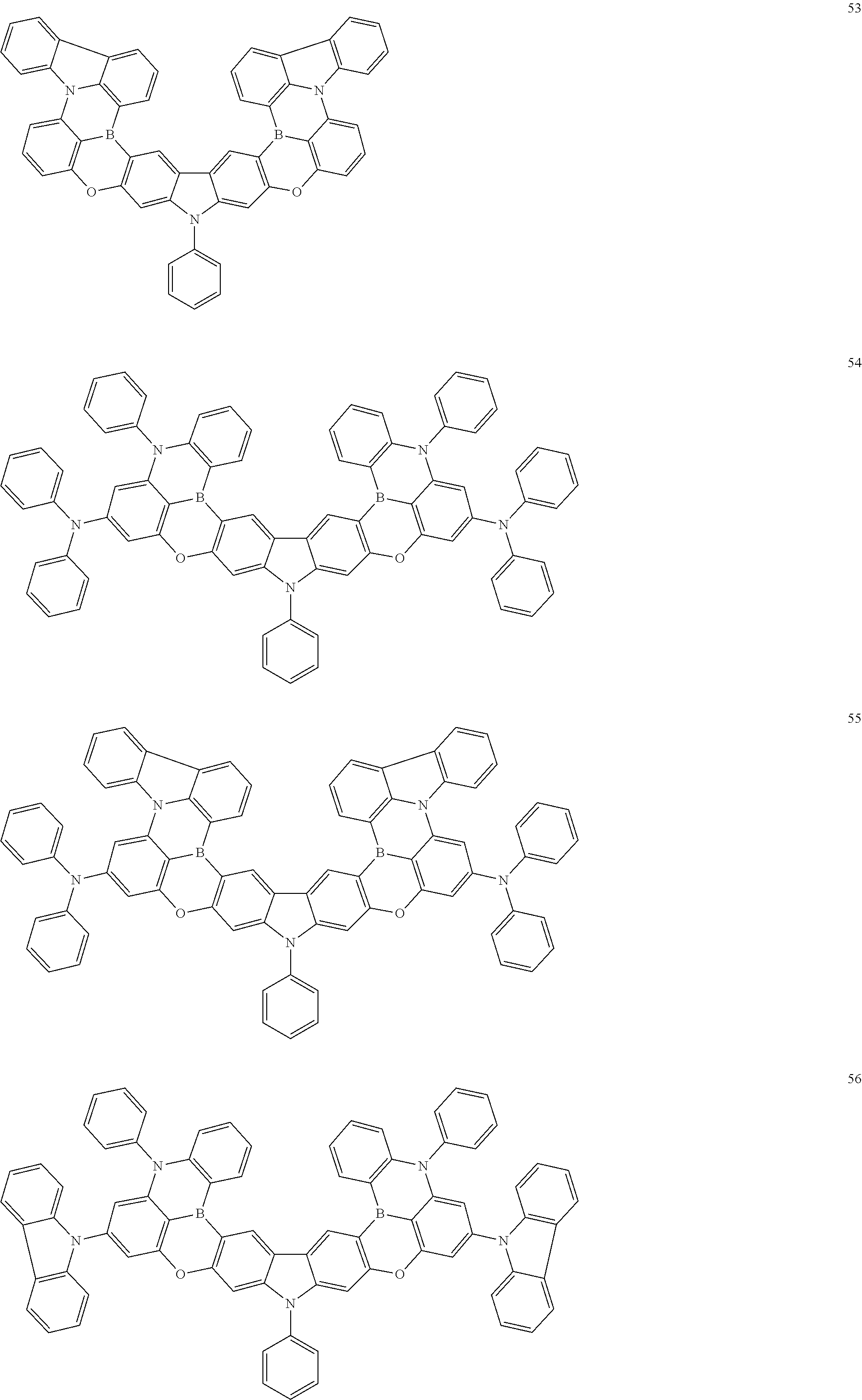

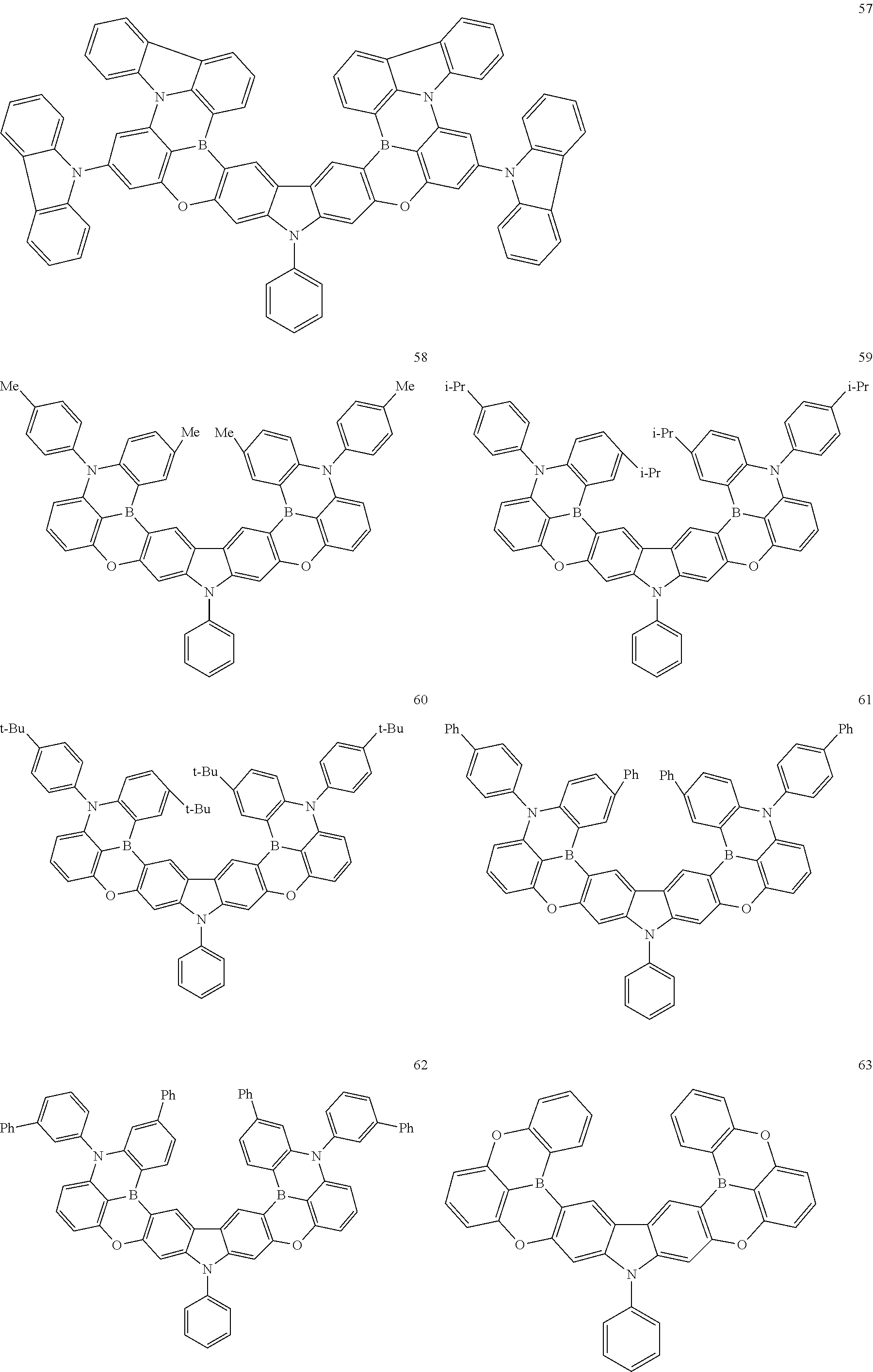

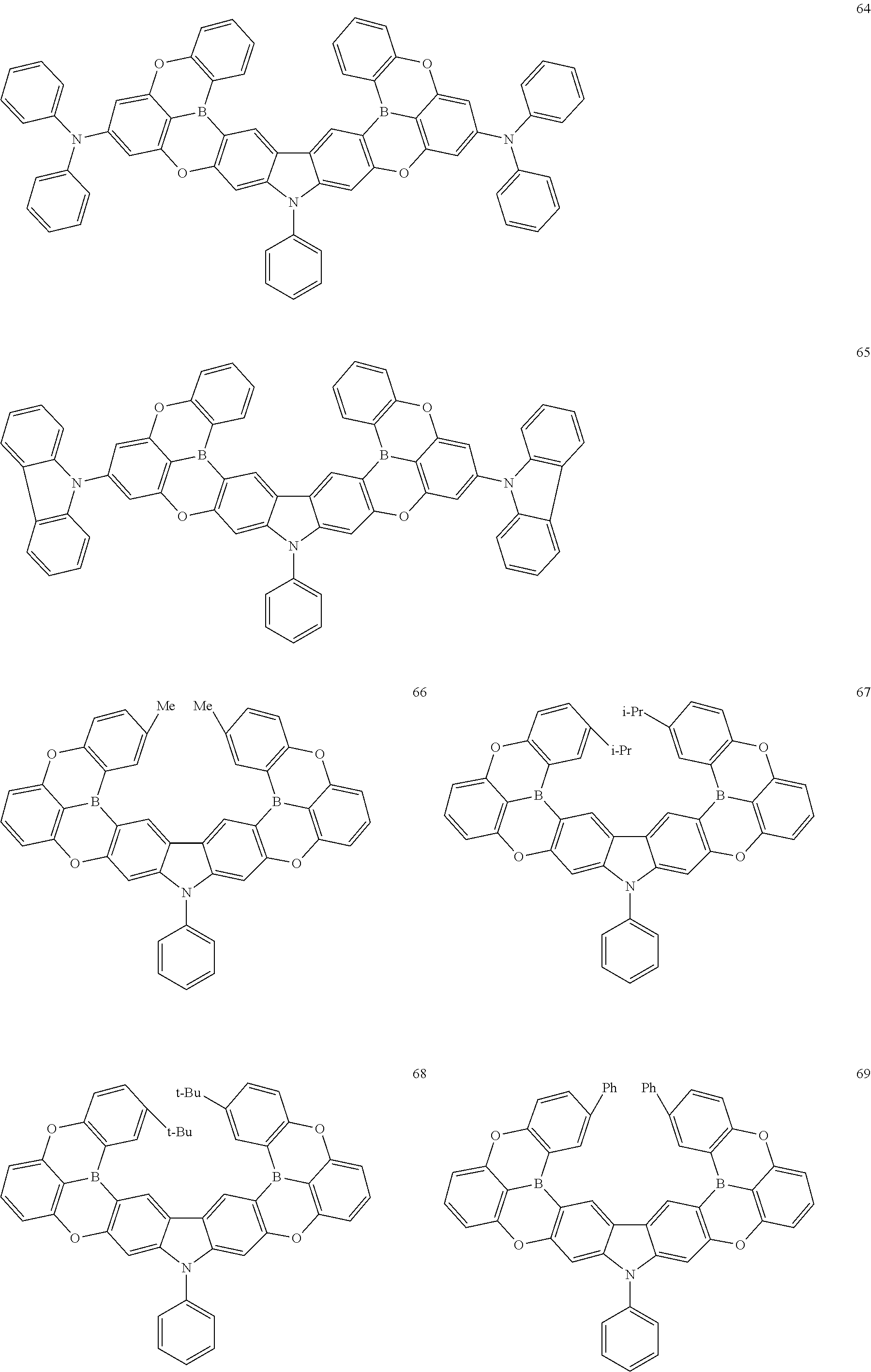

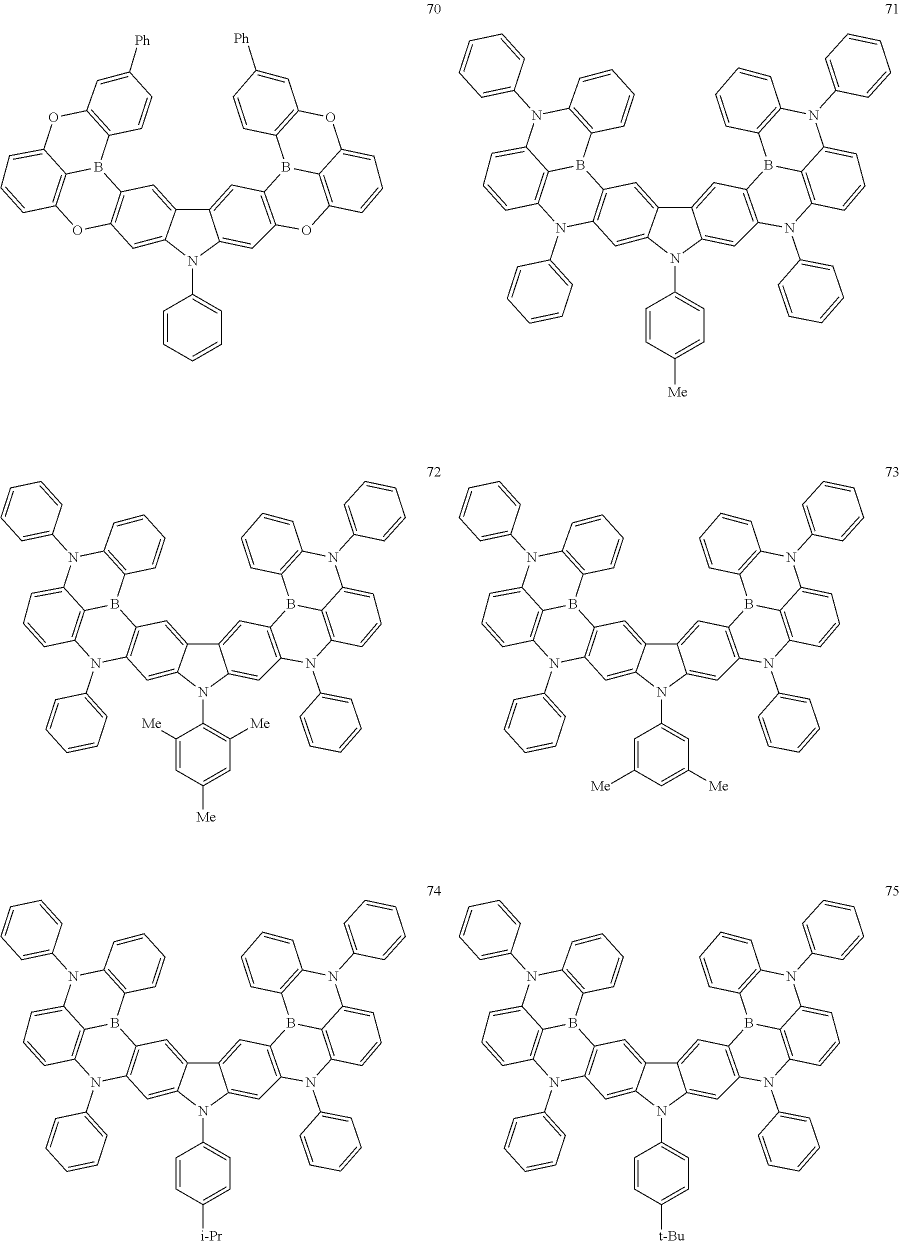

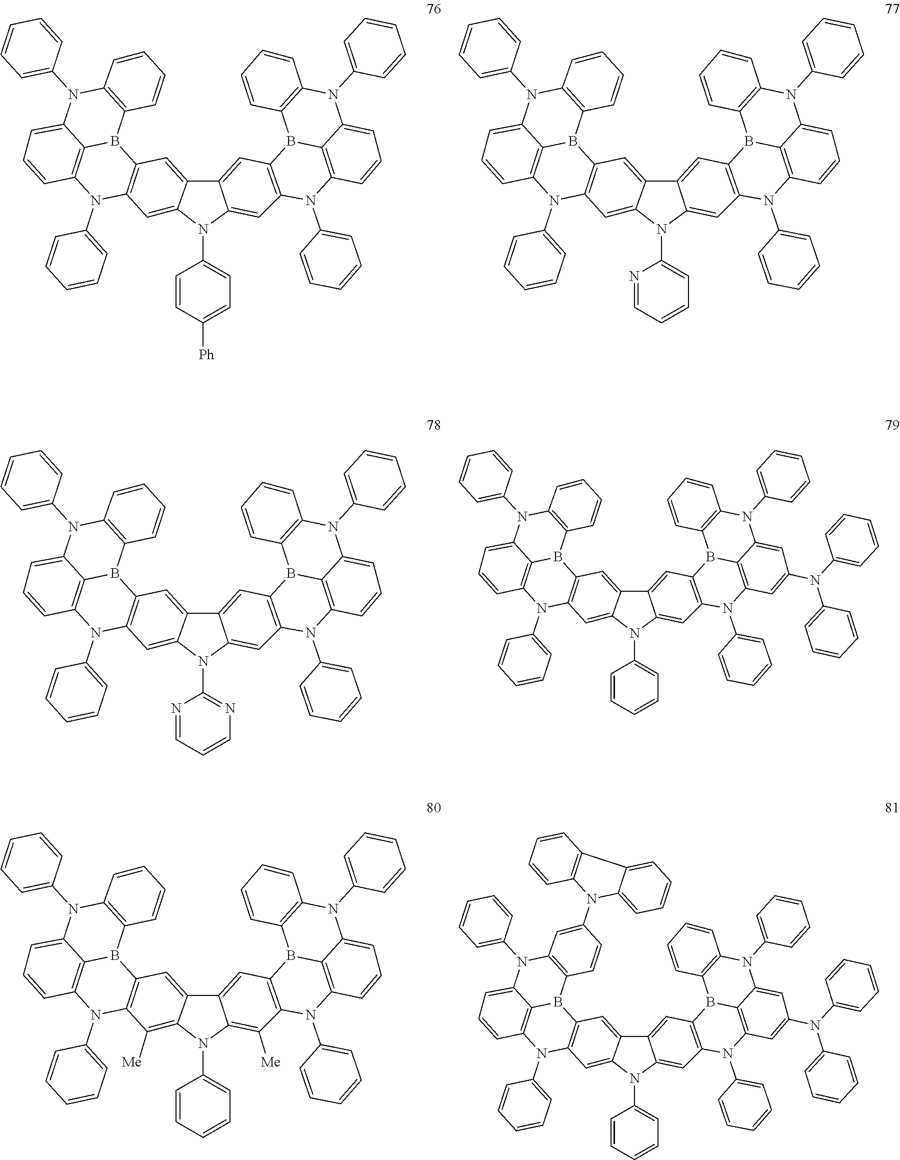

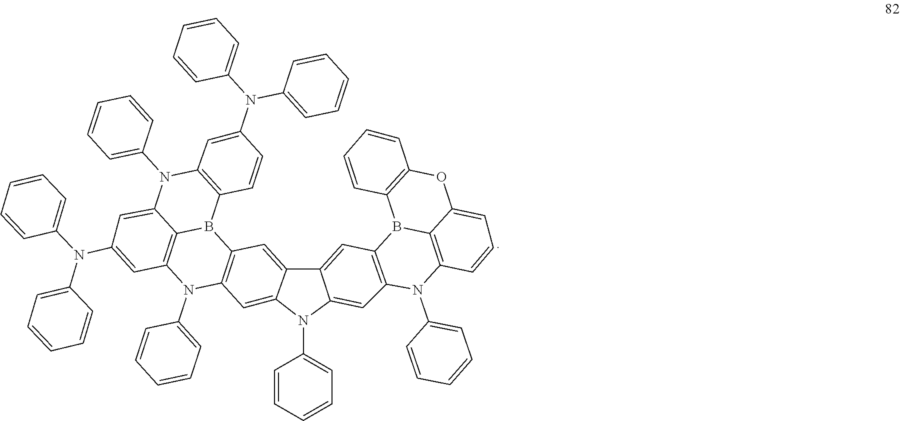 [SMILES: c1ccc(N(c2ccccc2)c2ccc3c(c2)N(c2ccccc2)c2cc(N(c4ccccc4)c4ccccc4)cc4c2B3c2cc3c5cc6c(cc5n(-c5ccccc5)c3cc2N4c2ccccc2)N(c2ccccc2)c2cccc3c2B6c2ccccc2O3)cc1]

The polycyclic compound represented by the above Formulae 1 to 10 may be used in the organic electroluminescence device 10 of an embodiment, thereby improving the efficiency and/or lifespan of the organic electroluminescence device. For example, the polycyclic compound described above may be used in the emission layer EML of the organic electroluminescence device 10 of an embodiment so that the luminous efficiency and/or lifespan of the organic electroluminescence device may be improved.

In an embodiment, the emission layer EML includes a host and a dopant, wherein the host may be a host for delayed fluorescence emission, and the dopant may be a dopant for delayed fluorescence emission. In some embodiments, the polycyclic compound of an embodiment represented by Formula 1 may be included as a dopant material of the emission layer EML. For example, the polycyclic compound represented by Formula 1 may be used as a TADF dopant.

In some embodiments, the organic electroluminescence device 10 of an embodiment may include a plurality of emission layers. The plurality of emission layers may be sequentially stacked, and for example, the organic electroluminescence device 10 including the plurality of emission layers may be to emit white light. The organic electroluminescence device including a plurality of emission layers may be an organic electroluminescence device having a tandem structure. When the organic electroluminescence device 10 includes a plurality of emission layers, at least one emission layer EML may include the polycyclic compound according to the present disclosure as described above.

The emission layer EML may further include any suitable material as a dopant. For example, the dopant may be or include a styryl derivative (such as 1,4-bis[2-(3-N-ethylcarbazolyl)vinyl]benzene (BCzVB), 4-(di-p-tolylamino)-4″-[(di-p-tolylamino)styryl]stilbene (DPAVB), and/or N-(4-(E)-2-(6-(E)-4-(diphenylamino)styryl)naphthalen-2-yl)vinyl)phenyl)-N-phenylbenzenamine (N-BDAVBi), perylene and/or derivatives thereof (such as 2,5,8,11-tetra-t-butylperylene (TBPe)), pyrene and/or derivatives thereof (such as 1,1-dipyrene, 1,4-dipyrenylbenzene, 1,4-bis(N,N-diphenylamino)pyrene, and/or 1,6-bis(N,N-diphenylamino)pyrene), 2,5,8,11-tetra-t-butylperylene (TBP), and/or 1,3,5-tris(N-phenylbenzimidazole-2-yl)benzene (TPBi), but is not limited thereto.

The emission layer EML may further include any suitable host material available in the art. For example, the emission layer EML may be or include at least one of tris(8-hydroxyquinolino)aluminum (Alq₃), bis[2-(diphenylphosphino)phenyl]ether oxide (DPEPO), 4,4′-bis(N-carbazolyl)-1,1′-biphenyl (CBP), 1,3-Bis(carbazolyl-9-yl)benzene (mCP), 2,8-bis(diphenylphosphoryl)dibenzofuran (PPF), poly(N-vinylcarbazole) (PVK), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), 2,8-bis(diphenylphosphoryl)dibenzofuran (PPF), or 1,3,5-tris(N-phenylbenzimidazole-2-yl)benzene (TPBi), but is not limited thereto.

When the emission layer EML is to emit red light, the emission layer EML may further include, for example, a fluorescent material including PBD:Eu (DBM)₃(Phen) (tris(dibenzoylmethanato) phenanthroline europium) and/or perylene. When the emission layer EML is to emit red light, a dopant included in the emission layer EML may be, for example, a metal or organometallic complex such as bis(1-phenylisoquinoline) acetylacetonate iridium (PIQIr(acac)), bis(1-phenylquinoline) acetylacetonate iridium (PQIr(acac)), tris(1-phenylquinoline) iridium (PQIr) and/or octaethylporphyrin platinum (PtOEP), rubrene and derivatives thereof, and/or 4-dicyanomethylene-2-(p-dimethylaminostyryl)-6-methyl-4H-pyran (DCM) and derivatives thereof.

When the emission layer EML is to emit green light, the emission layer EML may further include a fluorescent material including, for example, tris(8-hydroxyquinolino)aluminum (Alq₃). When the emission layer EML is to emit green light, a dopant included in the emission layer EML may be, for example, a metal or organometallic complex such as fac-tris(2-phenylpyridine) iridium (Ir(ppy)₃) and/or coumarin and derivatives thereof.

When the emission layer EML is to emit blue light, the emission layer EML may further include a fluorescent material including any one selected from the group consisting of, for example, spiro-DPVBi (spiro-DPVBi), spiro-6P (spiro-6P), distyryl-benzene (DSB), distyryl-arylene (DSA), polyfluorene-based polymer (PFO), and poly(p-phenylene vinylene)-based polymer (PPV). When the emission layer EML is to emit blue light, a dopant included in the emission layer EML may be, for example, a metal or organometallic complex such as (4,6-F2ppy)₂Irpic, and/or perylene and derivatives thereof.

In the organic electroluminescence device 10 of an embodiment illustrated in FIGS. 1 to 4, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may have or be a single layer formed of a single material, a single layer formed of a plurality of different materials, or a multilayer structure including a plurality of layers formed of a plurality of different materials.

In some embodiments, for example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL and a hole blocking layer HBL/electron transport layer ETL/electron injection layer EIL are stacked in order from the emission layer EML, but is not limited thereto. The thickness of the electron transport region ETR may be, for example, about 1000 Å to about 1,500 Å.

The electron transport region ETR may be formed using any suitable method, such as a vacuum deposition method, a spin coating method, a cast method, a Langmuir-Blodgett (LB) method, an inkjet printing method, a laser printing method, a laser induced thermal imaging (LITI) method, etc.

When the electron transport region ETR includes the electron transport layer ETL, the electron transport region ETR may include an anthracene-based compound. However, the present disclosure is not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate (Bebq2), 9,10-di(naphthalene-2-yl)anthracene (ADN), or a mixture thereof. The thickness of the electron transport layer ETL may be about 100 Å to about 1,000 Å, for example, about 150 Å to about 500 Å. When the thickness of the electron transport layer ETL satisfies the above-described range, satisfactory electron transport properties may be obtained without a substantial increase in driving voltage.

When the electron transport region ETR includes the electron injection layer EIL, the electron transport region ETR may be formed of a metal halide (such as LiF, NaCl, CsF, RbCl, and/or RbI), a lanthanide metal (such as Yb), a metal oxide (such as Li₂O and/or BaO), and/or lithium quinolate (LiQ), but is not limited thereto. The electron injection layer EIL may also be formed of a mixture material of an electron transport material and an insulating organo-metal salt. The organo-metal salt may be a material having an energy band gap of about 4 eV or more. The organo-metal salt may include, for example, metal acetate(s), metal benzoate(s), metal acetoacetate(s), metal acetylacetonate(s), and/or metal stearate(s). The thickness of the electron injection layers EIL may be about 1 Å to about 100 Å, or about 3 Å to about 90 Å. When the thickness of the electron injection layer EIL satisfies the above-described range, satisfactory electron injection properties may be obtained without a substantial increase in driving voltage.

The electron transport region ETR may include a hole blocking layer HBL as described above. The hole blocking layer HBL may include, for example, at least one of 2,9-dimethyl-4,7-diphenyl-1,10-phenanthroline (BCP), bis[2-(diphenylphosphino)phenyl]ether oxide (DPEPO), or 4,7-diphenyl-1,10-phenanthroline (Bphen), but is not limited thereto.

The second electrode EL2 is provided on the electron transport region ETR. The second electrode EL2 may be a common electrode or a cathode. The second electrode EL2 may be a transmissive electrode, a transflective electrode, or a reflective electrode. When the second electrode EL2 is a transmissive electrode, the second electrode EL2 may include or be formed of a transparent metal oxide, for example, ITO, IZO, ZnO, ITZO, etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, In, Sn, Zn, a compound thereof, a mixture thereof (for example, a mixture of Ag and Mg), or an oxide thereof. In some embodiments, the second electrode EL2 may have a multilayer structure including a reflective layer and/or a transflective layer formed of the above-described materials, and a transparent conductive layer formed of ITO, IZO, ZnO, ITZO, etc.

In some embodiments, the second electrode EL2 may be connected with an auxiliary electrode. When the second electrode EL2 is connected with the auxiliary electrode, the resistance of the second electrode EL2 may decrease.

Referring to FIG. 4, the organic electroluminescence device 10 according to an embodiment may further include a capping layer CPL on the second electrode EL2. The capping layer CPL may include, for example, α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol-9-yl)triphenylamine (TCTA), N, N′-bis(naphthalen-1-yl), etc.

The organic electroluminescence device 10 according to an embodiment of the present disclosure may include a polycyclic compound represented by Formula 1 as described above to thereby obtain superior luminous efficiency and long-life characteristics. In addition, the organic electroluminescence device 10 according to an embodiment may achieve high efficiency and long-life characteristics in a blue wavelength region.

Hereinafter, a compound according to an embodiment of this present disclosure and an organic electroluminescence device of an embodiment will be described in more detail with reference to Examples and Comparative Examples. The Examples shown below are illustrated only for the understanding of this present disclosure, and the scope of the present disclosure is not limited thereto.

### EXAMPLES

### Synthesis of Polycyclic Compounds

An example synthesis method for a polycyclic compound is provided below, and synthesis methods for polycyclic compounds according to embodiments of the present disclosure are not limited thereto.

### 1. Synthesis of Compound 1

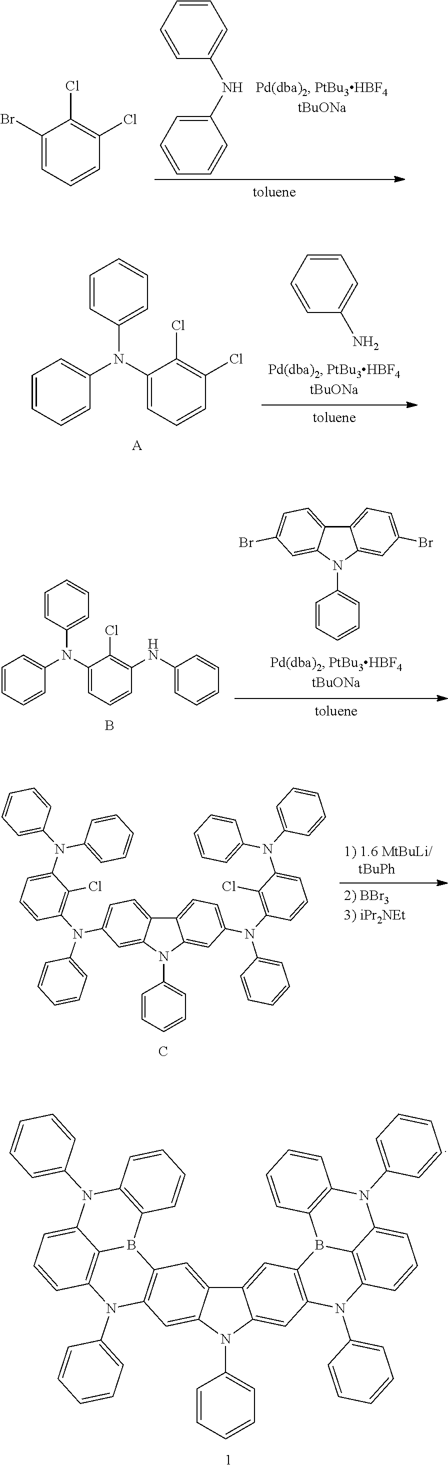

In an Ar atmosphere, 1-bromo-2,3-dichlorobenzene (25.0 g, 111 mmol), diphenylamine (19.7 g, 116 mmol), bis(dibenzylidene acetone)palladium(0) (Pd(dba)₂, 1.91 g, 3.32 mmol), tri-tert-butyl phosphonium tetrafluoro borate (HP(t-Bu)₃BF₄), 0.798 g, 4.43 mmol), and sodium tert-butoxide (NaOt-Bu, 16.0 g, 166 mmol) were added to 550 mL of toluene, and heated and stirred at 80° C. for 2 hours. After adding water, the resultant mixture was subjected to Celite filtering and liquid separation to concentrate an organic layer. The concentrated organic layer was purified by silica gel column chromatography to obtain A (27.8 g, 80% yield). The molecular weight of A was 314 as measured by FAB MS.

In an Ar atmosphere, A (25.0 g, 79.6 mmol), aniline (7.41 g, 79.6 mmol), Pd (dba)₂ (1.37 g, 2.39 mmol), HP(t-Bu)₃BF₄ (0.574 g, 3.18 mmol), and NaOt-Bu (11.5 g, 119 mmol) were added to 400 mL of toluene, and heated and stirred at 80° C. for 2 hours. After adding water, the resultant mixture was subjected to Celite filtering and liquid separation to concentrate an organic layer. The concentrated organic layer was purified by silica gel column chromatography to obtain B (20.0 g, yield 68%). The molecular weight of B was 371 as measured by FAB MS.

In an Ar atmosphere, 2,7-dibromo-9-phenyl-9H-carbazole (8.00 g, 20.0 mmol), B (18.5 g, 49.9 mmol), Pd (dba)₂ (0.803 g, 1.40 mmol), HP (t-Bu)₃BF₄ (0.288 g, 1.60 mmol), and NaOt-Bu (5.75 g, 59.8 mmol) were added to 100 mL of toluene, and heated and stirred at 80° C. for 8 hours. After adding water, the resultant mixture was subjected to Celite filtering and liquid separation to concentrate an organic layer. The concentrated organic layer was purified by silica gel column chromatography to obtain C (14.7 g, yield 75%). The molecular weight of C was 981 as measured by FAB MS.

In an Ar atmosphere, C (14.0 g, 15.1 mmol) and tert-butylbenzene (160 ml) were cooled to −30° C., and tert-butyllithium (1.6 M/L pentane, 38 mL, 60 mmol) was added slowly. After returning to room temperature for 1 hour, the resultant mixture was heated and stirred at 60° C. for 3 hours. The reaction solution was cooled to 30° C., BBr₃ (15.1 g, 60 mmol) was added slowly, and heated and stirred at an internal temperature of 30° C. for 1 hour. The reaction solution was ice-cooled, N, N-diisopropylethylamine (7.80 g, 60 mmol) was added, and heated and stirred at an inside temperature of 100° C. for 2 hours, allowing pentane to evaporate). Water was added after cooling, and the resultant mixture was subjected to Celite filtering and liquid separation to concentrate an organic layer. The concentrated organic layer was purified by silica gel column chromatography to obtain Compound 1 (2.80 g, yield 20%). The molecular weight of Compound 1 was 928 as measured by FAB MS. Sublimation purification (350° C., 8.7×10⁻³ Pa) was carried out and device evaluation was performed.

### 2. Synthesis of Compound 2

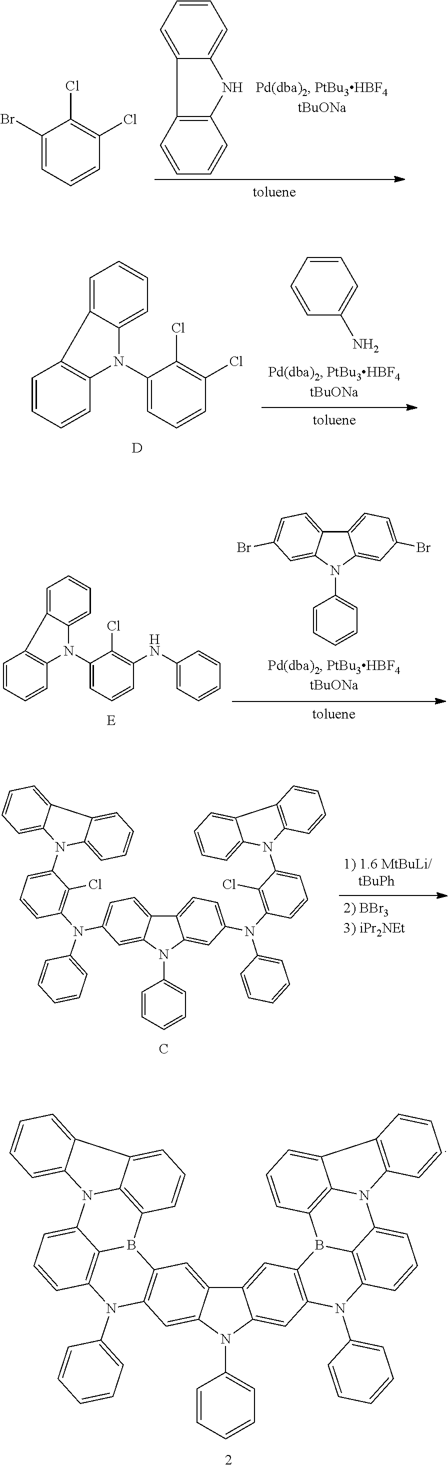

1.3 g (yield 15%) of Compound 2 was synthesized by substantially the same reaction used for Compound 1, except that carbazole (19.4 g, 0.116 mol) was used instead of diphenylamine in the synthesis of Compound 1. The molecular weight of Compound 2 was 924 as measured by FAB MS. Sublimation purification (380° C., 7.7×10⁻³ Pa) was carried out and device evaluation was performed.

### 3. Synthesis of Compound 3

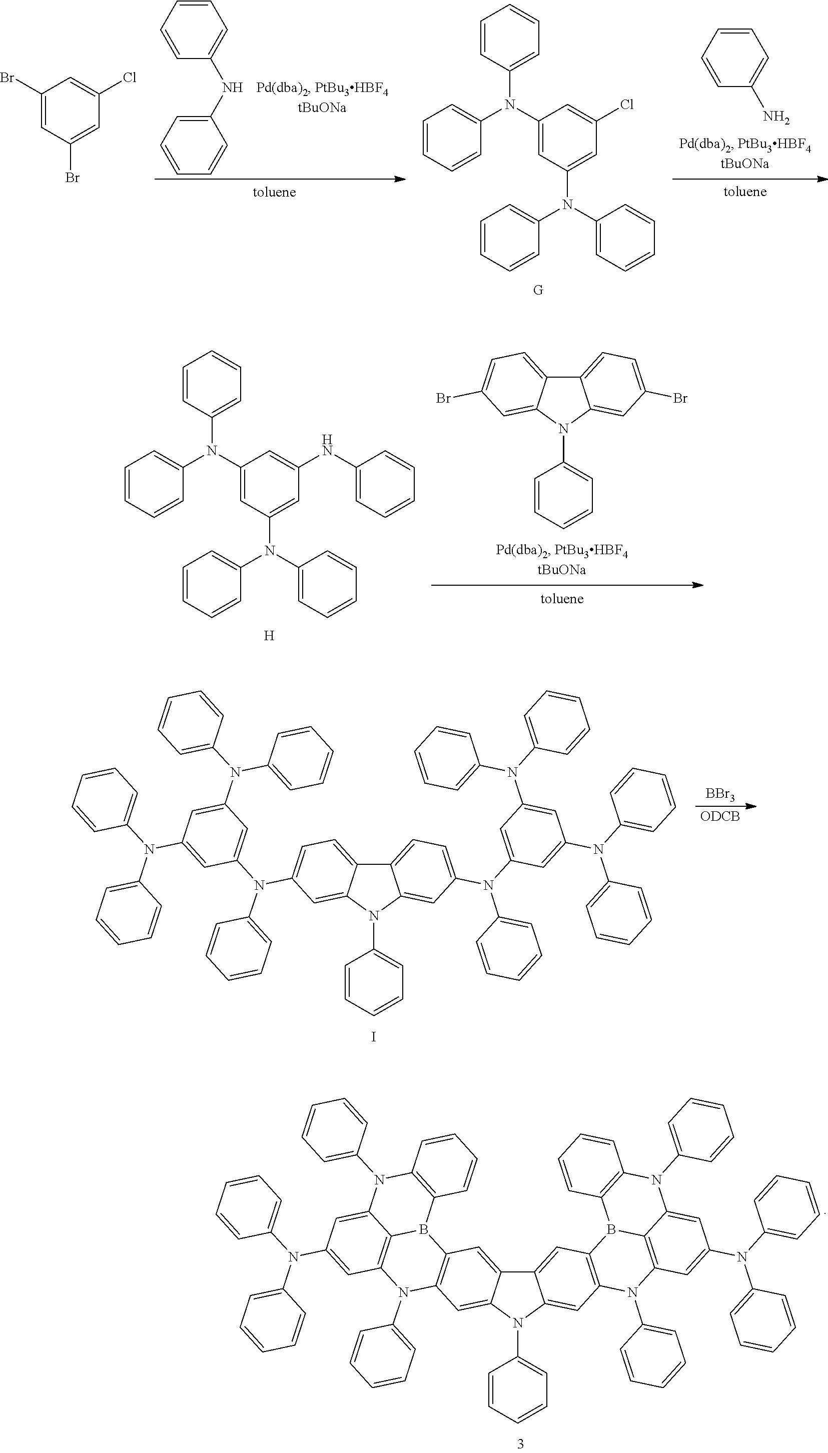

In an Ar atmosphere, 1,3-dibromo-5-dichlorobenzene (25.0 g, 92.5 mmol), diphenylamine (36.0 g, 213 mmol), Pd(dba)₂ (2.66 g, 4.62 mmol), HP(t-Bu)₃BF₄ (1.00 g, 5.55 mmol), and NaOt-Bu (28.4 g, 296 mmol) were added to 460 mL of toluene, and heated and stirred at 80° C. for 2 hours. After adding water, the resultant mixture was subjected to Celite filtering and liquid separation to concentrate an organic layer. The concentrated organic layer was purified by silica gel column chromatography to obtain G (33.1 g, yield 80%). The molecular weight of G measured was 447 as measured by FAB MS.

20.0 g (yield 67.8%) of Compound H was synthesized by substantially the same reaction except that Compound G (25.0 g, 55.9 mol) was used instead of Compound A. The molecular weight of Compound H was 504 as measured by FAB MS.

19.8 g (yield 75.0%) of Compound I was synthesized by substantially the same reaction except that Compound H (8.0 g, 15.9 mol) was used instead of Compound B. The molecular weight of Compound H was 247 as measured by FAB MS.

In an Ar atmosphere, I (14.4 g, 11.6 mmol) was dissolved in 1,2-dichlorobenzene (ortho-dichlorobenzene, “ODCB”, 120 mL), BBr₃ (11.6 g, 46.3 mmol) was added, and heated and stirred at 180° C. for 10 hours. After cooling to room temperature, triethylamine (35.2 g, 348 mmol) was added, water was added, and the resultant mixture was subjected to Celite filtering and liquid separation to concentrate an organic layer. The concentrated organic layer was purified by silica gel column chromatography to obtain Compound 3 (11.4 g, yield 78%). The molecular weight of Compound 3 was 1262 as measured by FAB MS. Sublimation purification (440° C., 9.2×10⁻³ Pa) was carried out and device evaluation was performed.

### 4. Synthesis of Compound 4

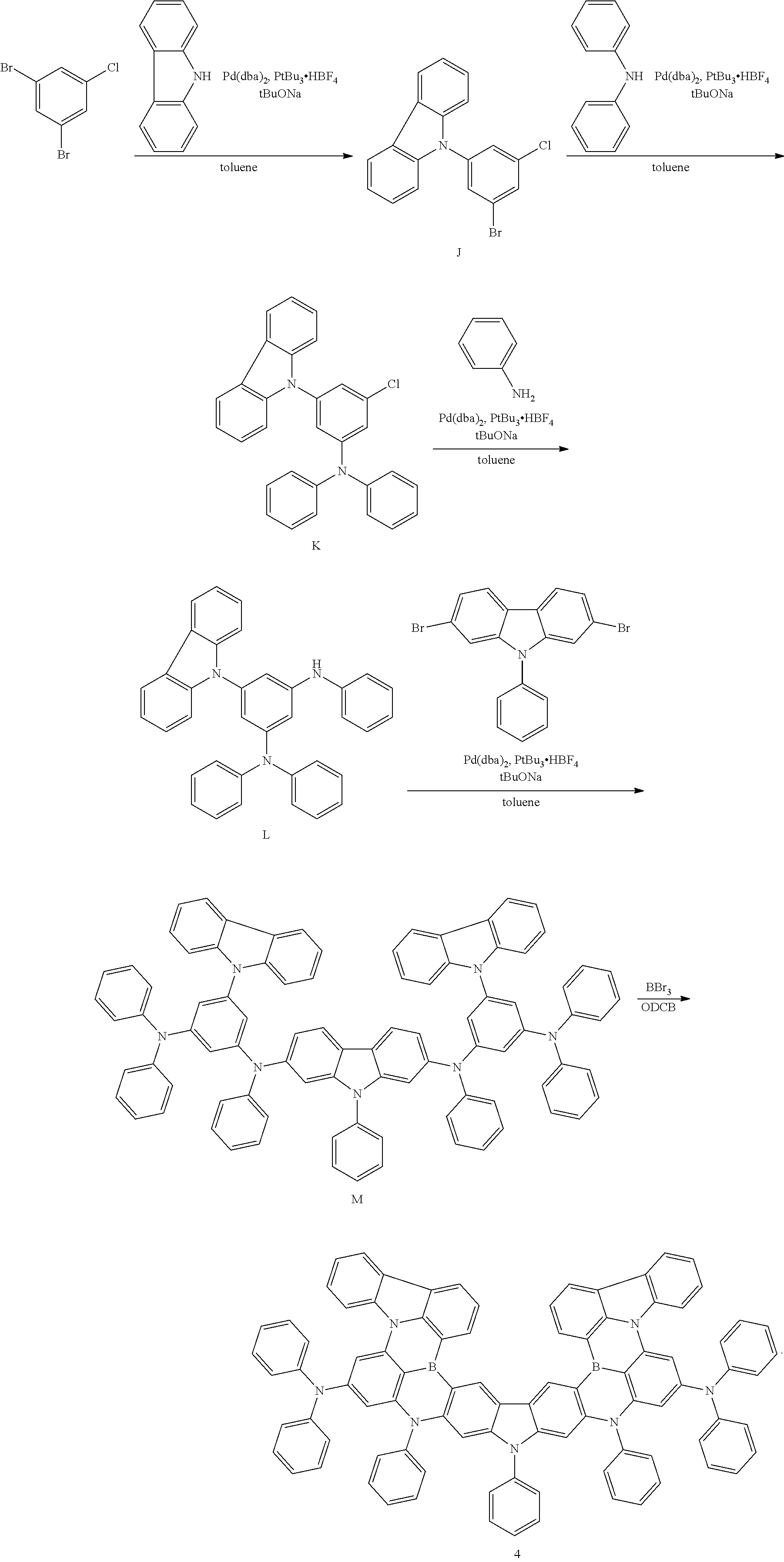

In an Ar atmosphere 1,3-dibromo-5-chlorobenzene (25 g, 92.5 mmol), carbazole (16.2 g, 97.10 mol), bis(dibenzylidene acetone)palladium(0) (Pd(dba)₂, 1.91 g, 3.32 mmol), tri-tert-butyl phosphonium tetrafluoro borate (HP(t-Bu)₃BF₄), 0.798 g, 4.43 mmol), and sodium tert-butoxide (NaOt-Bu, 16.0 g, 166 mmol) were added to 550 mL of toluene, and heated and stirred at 80° C. for 2 hours. After adding water, the resultant mixture was subjected to Celite filtering and liquid separation to concentrate an organic layer. The concentrated organic layer was purified by silica gel column chromatography to obtain J (26.3 g, yield 80%). The molecular weight of Compound J was 357 as measured by FAB MS.

Using J (25 g, 70.1 mmol), the synthesis of Compound K was performed in substantially the same manner as the synthesis of Compound A to obtain K (26.5 g, yield 85%). The molecular weight of Compound K was 445 as measured by FAB MS.

Using K (25.0 g, 56.0 mmol), the synthesis of Compound L was performed in substantially the same manner as the synthesis of Compound E to obtain L (20.3 g, 72% yield). The molecular weight of Compound L was 502 as measured by FAB MS.

Using L (20.0 g, 39.8 mmol), the synthesis of Compound M was performed in substantially the same manner as the synthesis of Compound I to obtain M (22.8 g, yield 92%). The molecular weight of Compound M was 1243 as measured by FAB MS.

Using M (21.0 g, 16.9 mmol), the synthesis of Compound 4 was performed in substantially the same manner as the synthesis of Compound 3 to obtain Compound 4 (16.4 g, yield 77%). The molecular weight of Compound 4 was 1259 as measured by FAB MS. Sublimation purification (440° C., 8.7×10⁻³ Pa) was carried out and device evaluation was performed.

### 5. Synthesis of Compound 5

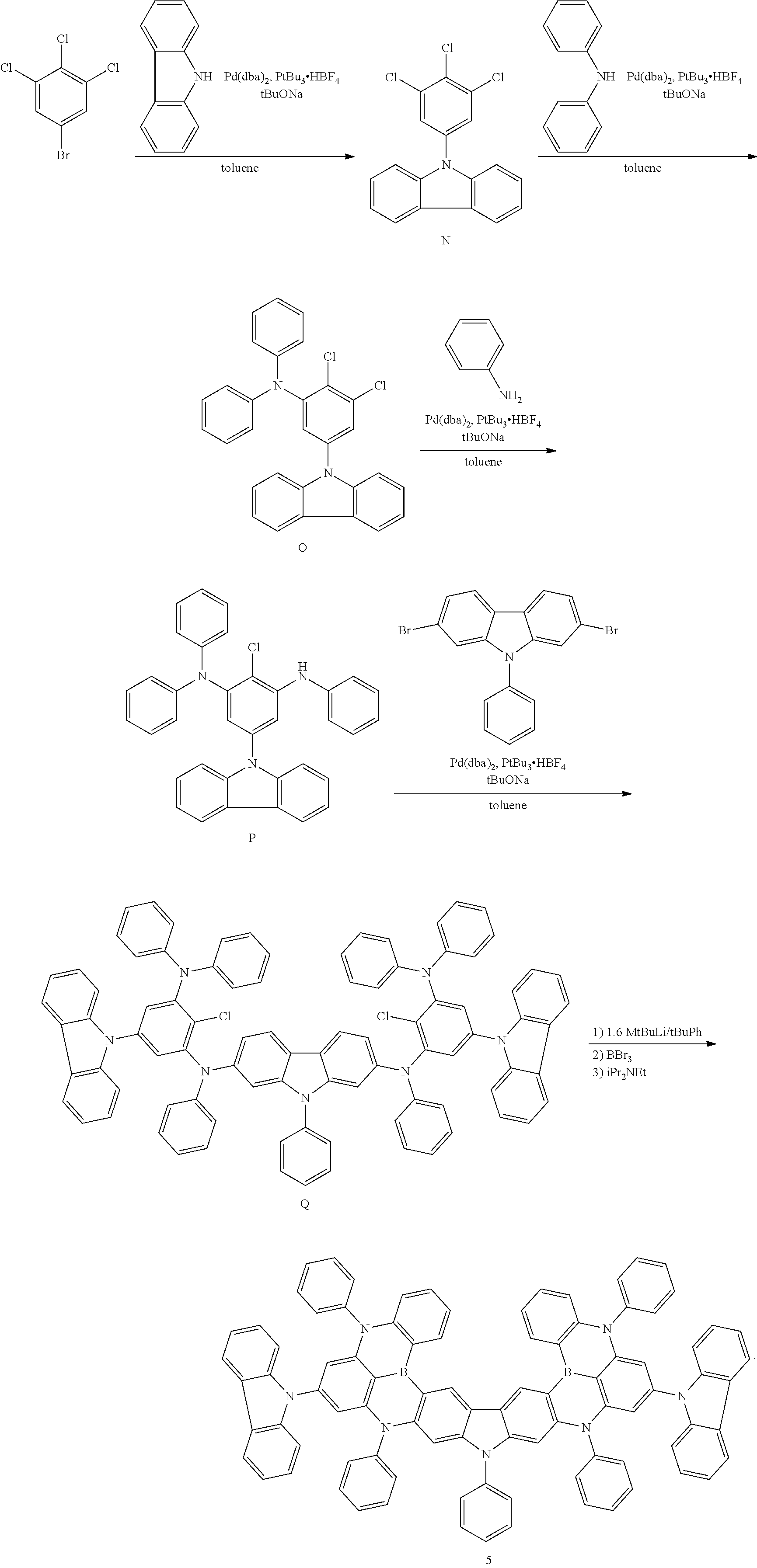

Using 5-bromo-1,2,3-trichlorobenzene (25.0 g, 96.0 mmol), the synthesis of Compound N was performed in substantially the same manner as the synthesis of Compound J to obtain Compound N (22.6 g, yield 68%). The molecular weight of Compound N was 347 as measured by FAB MS.

Using N (21.0 g, 60.6 mmol), the synthesis of Compound O was performed in substantially the same manner as the synthesis of Compound A to obtain Compound O (22.6 g, yield 84%). The molecular weight of Compound O was 480 as measured by FAB MS.

Using 0 (21.0 g, 47.1 mmol), the synthesis of Compound P was performed in substantially the same manner as the synthesis of Compound B to obtain Compound P (18.5 g, yield 78%). The molecular weight of Compound P was 537 as measured by FAB MS.

Using P (18.0 g, 35.8 mmol), the synthesis of Compound Q was performed in substantially the same manner as the synthesis of Compound C to obtain Compound Q (18.6 g, yield 79%). The molecular weight of Compound P was 1313 as measured by FAB MS.

Using Q (18.0 g, 13.7 mmol), the synthesis of Compound 5 was performed in substantially the same manner as the synthesis of Compound 1 to obtain Compound 5 (14.2 g, yield 82). The molecular weight of Compound 5 was 1259 as measured by FAB MS. Sublimation purification (430° C., 3.4×10⁻³ Pa) was carried out and device evaluation was performed.

### 6. Synthesis of Compound 28

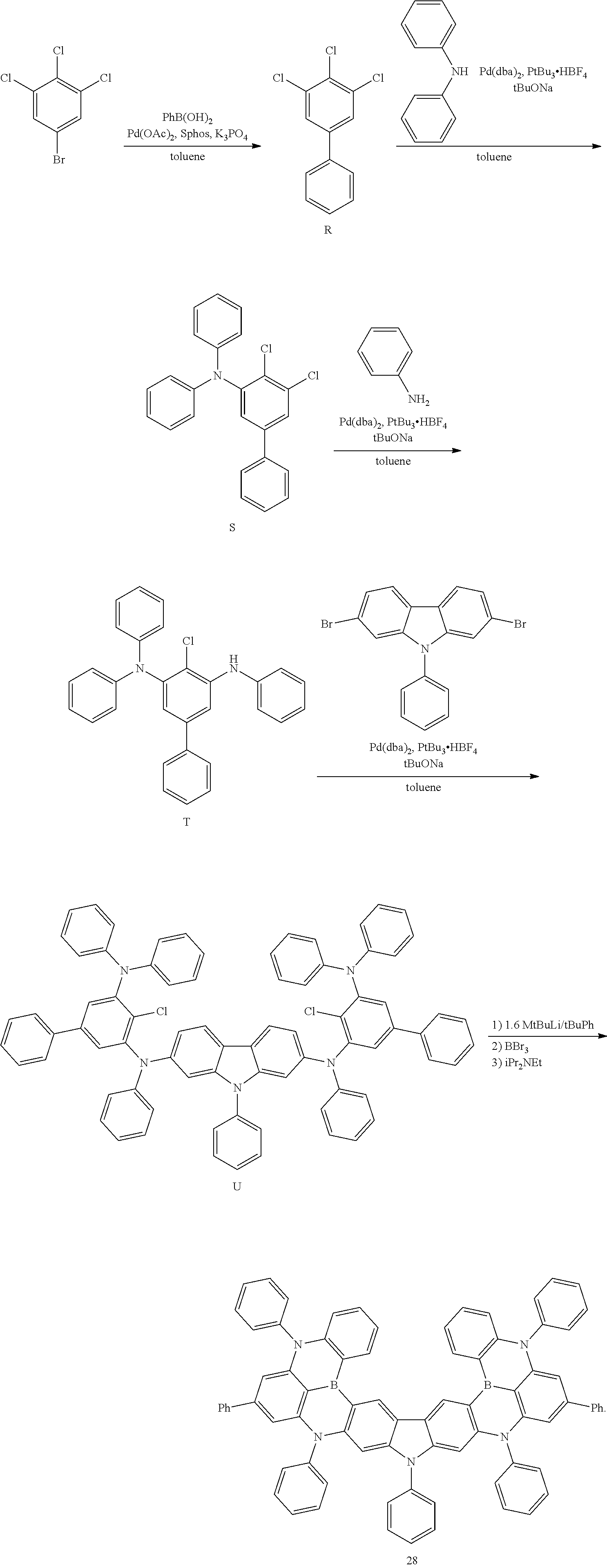

The synthesis of the compound R was performed by adding 5-bromo-1,2,3-trichlorobenzene (25.0 g, 96.0 mmol), PhB(OH)₂ (14.05 g, 115.0 mmol), Pd(OAc)₂ (0.647 g, 2.88 mmol), 2-dicyclohexylphosphino-2′,6′-dimethoxybiphenyl (“Sphos”, 2.37 g, 5.76 mmol), and K₃PO₄ (61.15 g, 0.288 mol) to 1 L of toluene, and heating and stirring the resultant mixture at 90° C. for 6 hours. 300 mL of water was added, the resultant mixture was subjected to Celite filtering, liquid separation, and concentration, and the resulting crystals were filtered and washed with toluene to obtain Compound R (15.5 g, yield 63%). The molecular weight of Compound R was 256 as measured by FAB MS.

Using R (15.0 g, 58.2 mmol), the synthesis of Compound S was performed in substantially the same manner as the synthesis of Compound A to obtain Compound S (19.1 g, yield 92%). The molecular weight of Compound S was 356 as measured by FAB MS.

Using S (18.5 g, 51.9 mmol), the synthesis of Compound T was performed in substantially the same manner as the synthesis of Compound B to obtain Compound T (16.3 g, yield 76%). The molecular weight of Compound T was 413 as measured by FAB MS.

Using T (16.0 g, 38.8 mmol), the synthesis of Compound U was performed in substantially the same manner as the synthesis of Compound C to obtain Compound U (18.5 g, yield 84%). The molecular weight of Compound U was 1134 as measured by FAB MS.

Using U (18.0 g, 15.9 mmol), the synthesis of Compound 28 was performed in substantially the same manner as the synthesis of Compound 1 to obtain Compound 28 (12.5 g, yield 73%). The molecular weight of Compound 28 was 1080 as measured by FAB MS. Sublimation purification (410° C., 8.8×10⁻³ Pa) was carried out and device evaluation was performed.

### 7. Synthesis of Compound 31

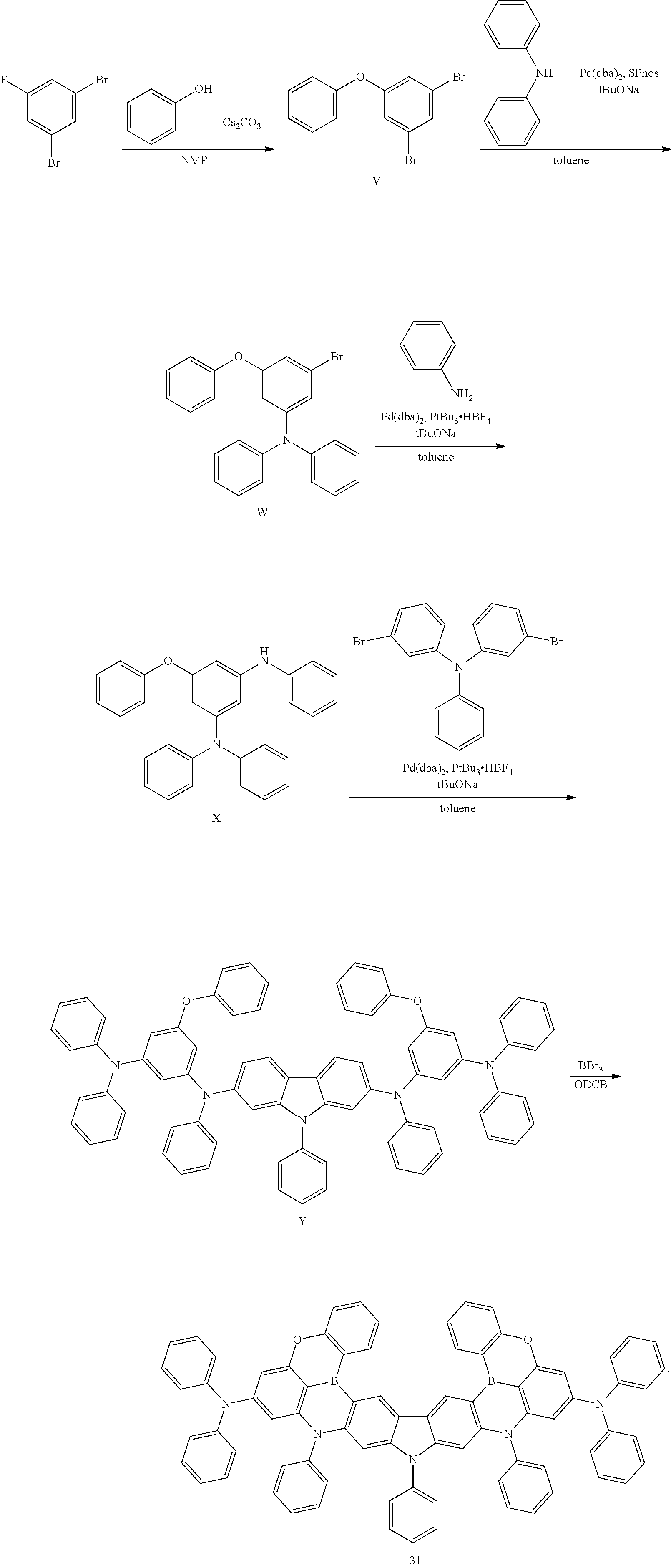

The synthesis of Compound V was performed by adding 1,3-dibromo-5-fluorobenzene (25.0 g, 98.5 mmol), phenol (11.12 g, 118 mmol), and CsCO₃ (16.6 g, 137 mmol) to 1-methyl-2-pyrrolidone (“NMP”, 500 mL), and heated and stirred at 160° C. for 24 hours. After concentrating, toluene and water were added and separated to concentrate an organic layer, hexane was added, filtering was performed and the resultant mixture was washed with toluene to obtain Compound V (28.2 g, yield 88%). The molecular weight of Compound V was 328 as measured by FAB MS.

Using V (25.0 g, 76.2 mmol), the synthesis of Compound W was performed in substantially the same manner as the synthesis of Compound A to obtain Compound W (28.9 g, yield 91%). The molecular weight of Compound W was 416 as measured by FAB MS.

Using W (28.0 g, 67.2 mmol), the synthesis of Compound X was performed in substantially the same manner as the synthesis of Compound B to obtain Compound X (21.6 g, yield 75%). The molecular weight of Compound X was 429 as measured by FAB MS.

Using X (21.0 g, 49.0 mmol), the synthesis of Compound Y was performed in substantially the same manner as the synthesis of Compound C to obtain Compound Y (21.5 g, yield 80%). The molecular weight of Compound Y was 1097 as measured by FAB MS.

Using Y (21.0 g, 19.2 mmol), the synthesis of Compound 31 was performed in substantially the same method as the synthesis of Compound 1 to obtain Compound 31 (17.5 g, yield 82%). The molecular weight of Compound 31 was 1112 as measured by FAB MS. Sublimation purification (420° C., 6.7×10⁻³ Pa) was carried out and device evaluation was performed.

### 8. Synthesis of Compound 33

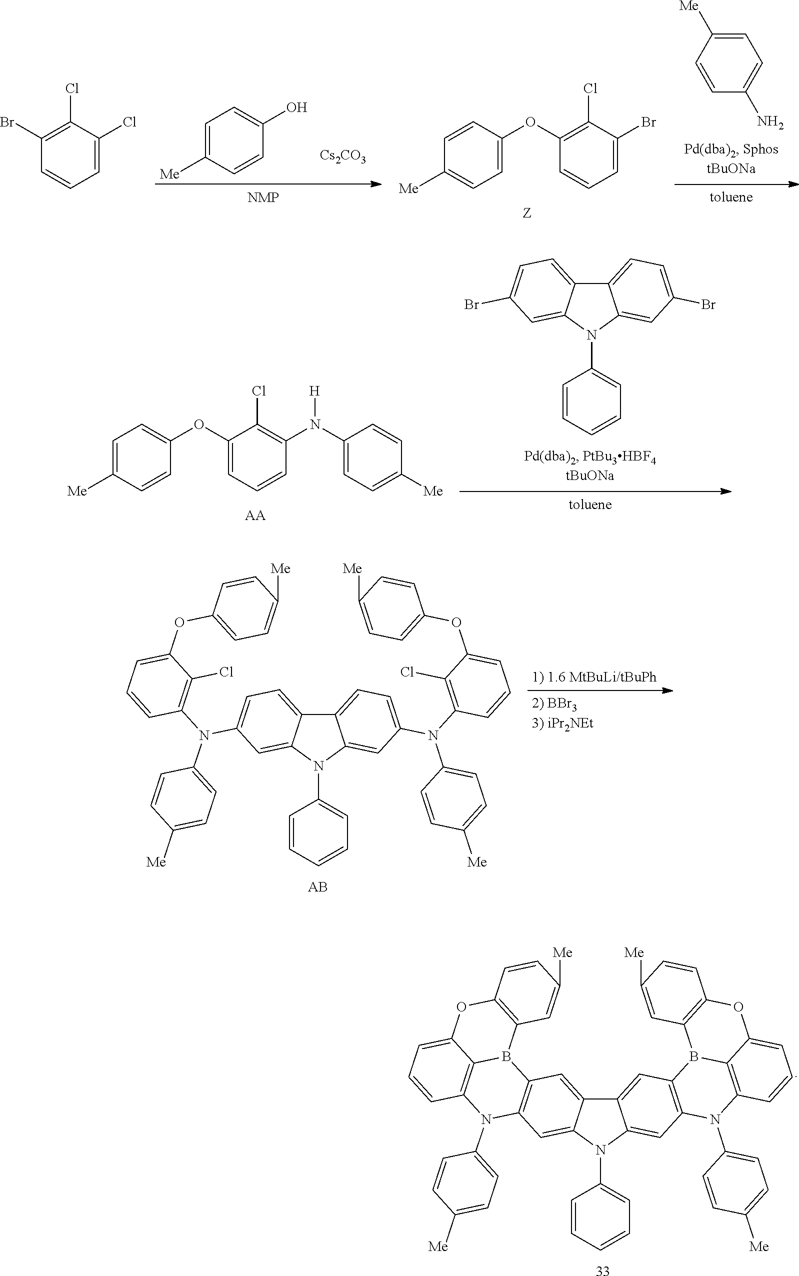

Using 1-bromo-2-chloro-3-fluorobenzene (25.0 g, 119 mmol), the synthesis of the Compound Z was performed in substantially the same manner as the synthesis of the Compound V to obtain Compound Z (25.9 g, yield 73%). The molecular weight of Compound Z was 296 as measured by FAB MS.

Using Z (25.0 g, 84.0 mmol), the synthesis of Compound AA was performed in substantially the same manner as Compound B to obtain Compound AA (20.9 g, yield 77%). The molecular weight of Compound AA was 324 as measured by FAB MS.

Using AA (20.0 g, 61.8 mmol), the synthesis of Compound AB was performed in substantially the same manner as Compound C to obtain Compound AB (19.2 g, yield 70%). The molecular weight of Compound AB was 886 as measured by FAB MS.

Using AB (18.5 g, 20.9 mmol), the synthesis of Compound 33 was performed in substantially the same manner as the synthesis of Compound 1 to obtain Compound 33 (3.48 g, yield 20%). The molecular weight of Compound 33 was 834 as measured by FAB MS. Sublimation purification (380° C., 8.5×10⁻³ Pa) were carried out and device evaluation was performed.

### 9. Synthesis of Compound 48

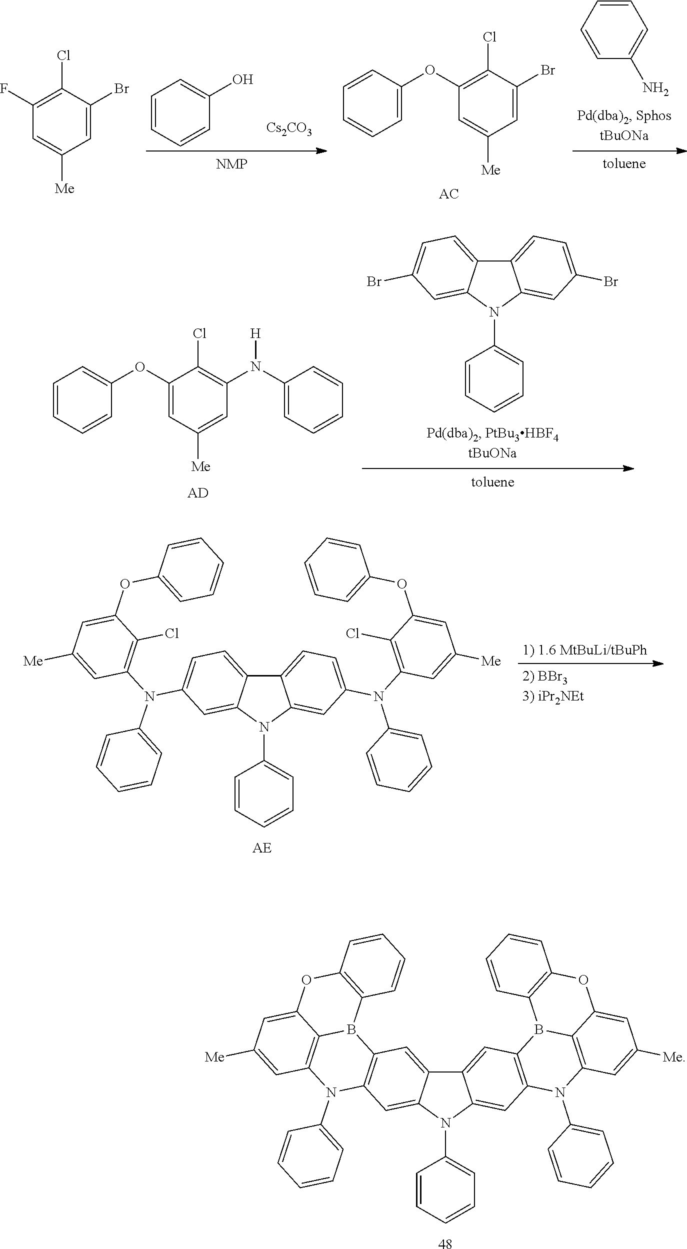

Using 1-bromo-2-chloro-3-fluoro-5-methylbenzene (25.0 g, 112 mmol), the synthesis of Compound AC was performed in substantially the same manner as the synthesis of Compound V to obtain Compound AC (23.3 g, yield 70%). The molecular weight of Compound AC was 296 as measured by FAB MS.

Using AC (22.0 g, 73.9 mmol), the synthesis of Compound AD was performed in the same manner as Compound B to obtain Compound AD (14.9 g, yield 65%). The molecular weight of Compound AD was 310 as measured by FAB MS.

Using AD (14.0 g, 45.2 mmol), the synthesis of Compound AE was performed in substantially the same manner as Compound C to obtain Compound AE (16.5 g, yield 85%). The molecular weight of Compound AE was 858 as measured by FAB MS.

Using AE (16.0 g, 18.6 mmol), the synthesis of Compound 48 was performed in substantially the same manner as the synthesis of Compound 1 to obtain Compound 48 (2.55 g, yield 17%). The molecular weight of Compound 48 was 806 as measured by FAB MS. Sublimation purification (370° C., 5.7×10⁻³ Pa) was carried out and device evaluation was performed.

### 10. Synthesis of Compound 54

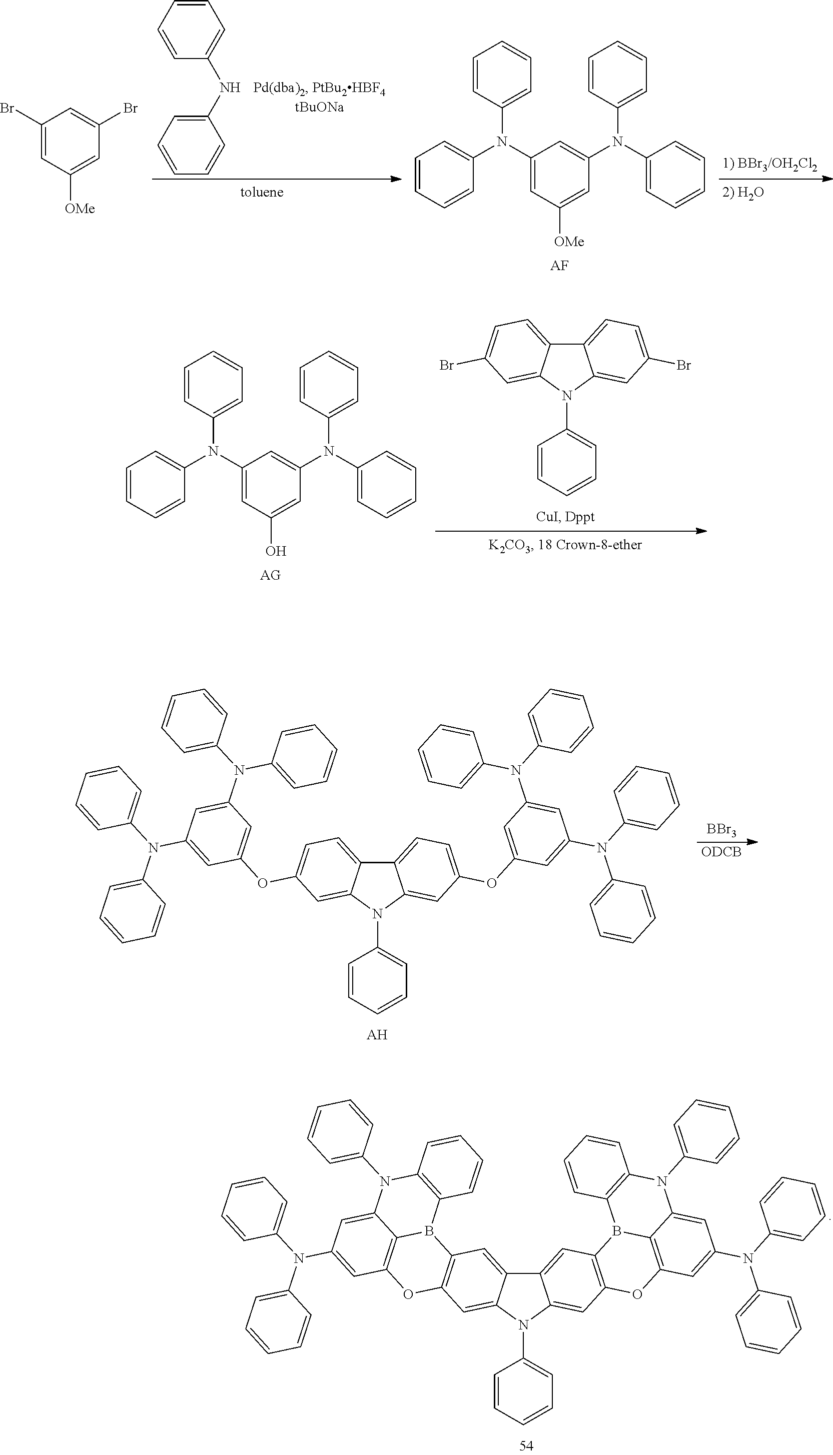

Using 1,3-dibromo-5-methoxybenzene (25.0 g, 94.0 mmol), the synthesis of Compound AF was performed in substantially the same manner as the synthesis of Compound A to obtain Compound AF (38.7 g, yield 93%). The molecular weight of Compound AF was 443 as measured by FAB MS.

The synthesis of Compound AG was carried out by dissolving Compound AF (20.0 g, 45.2 mmol) in CH₂Cl₂ (300 ml) and cooling to 0° C. BBr₃ (22.7 g, 90.5 mmol) was added dropwise at an internal temperature of 10° C. or less, and stirred at room temperature for 24 hours. The reaction solution was poured into iced water, separated, and the organic layer was concentrated and purified by silica gel column chromatography to obtain Compound AG (15.5 g, yield 80%). The molecular weight of Compound AG was 429 as measured by FAB MS.

The synthesis of Compound AH was carried out by adding 2,7-dibromo-9-phenyl-9H-carbazole (8.0 g, 20 mmol) and a compound including AG (17.17 g, 40.1 mmol), Cul (0.19 g, 1.0 mmol), tris(2,4-pentanedionato)iron(III) (Fe(III)(acac)₃, 0.71 g, 2.0 mmol), and K₂CO₃ (18.5 g, 80 mmol) to NMP (400 mL), and heated and stirred at 180° C. for 12 hours. The resultant mixture was concentrated, dissolved in CH₂Cl₂, and subjected to Celite filtering by adding water and liquid separation to concentrate an organic layer. The concentrated organic layer was purified by silica gel column chromatography to obtain Compound AH (14.3 g, yield 65%). The molecular weight of Compound AH was 1096 as measured by FAB MS.

Using AH (14.0 g, 12.8 mmol), the synthesis of Compound 54 was performed in substantially the same manner as the synthesis of Compound 1 to obtain Compound 54 (2.13 g, yield 15%). The molecular weight of Compound 33 was 834 as measured by FAB MS. Sublimation purification (380° C., 8.5×10⁻³ Pa) was carried out and device evaluation was performed.

### 11. Synthesis of Compound 64

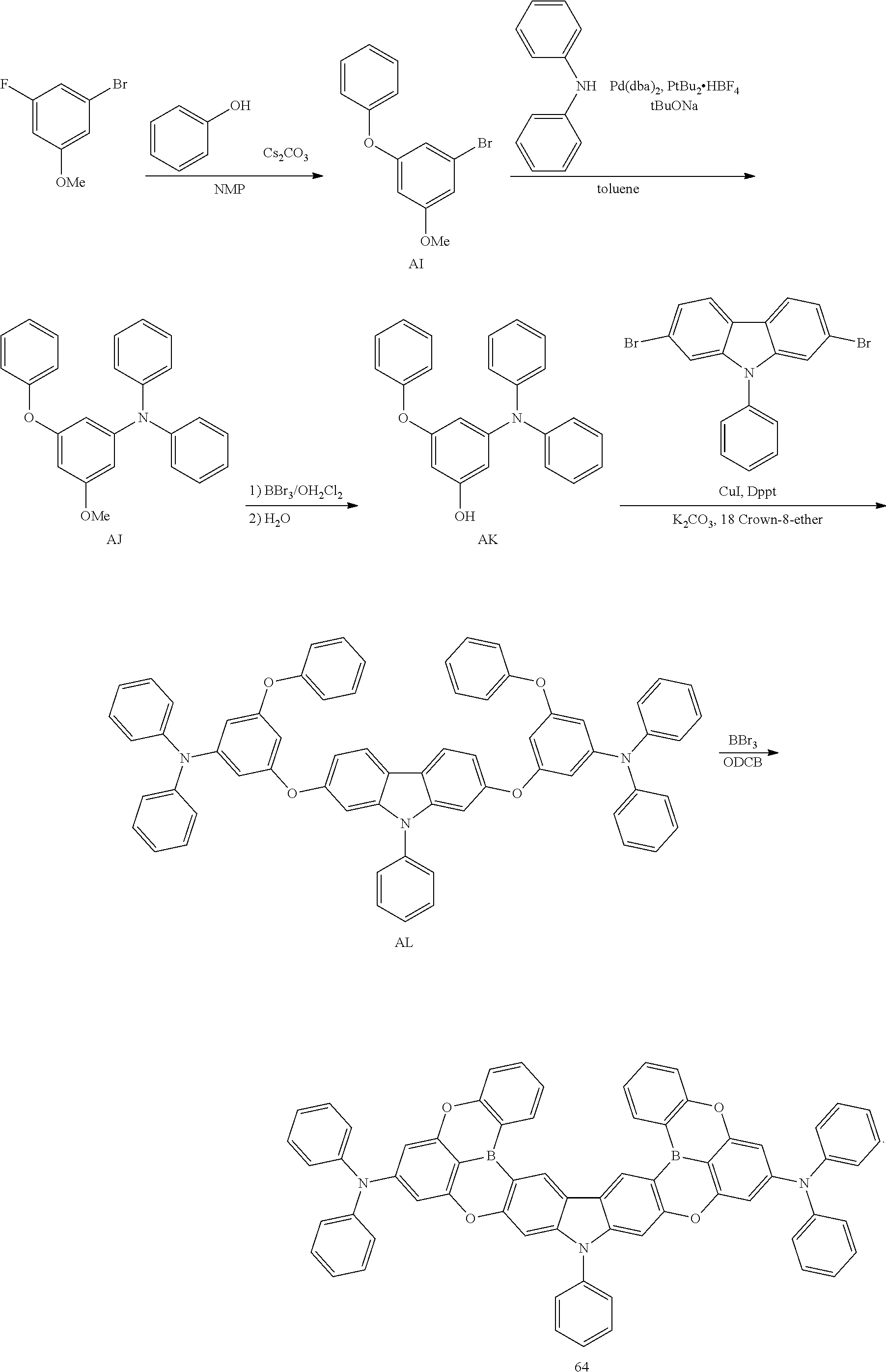

Using 1-bromo-3-fluoro-5-methoxybenzene (25.0 g, 122 mmol), the synthesis of Compound AI was carried out in substantially the same manner as the synthesis of Compound V to obtain Compound AI (22.1 g, yield 65%). The molecular weight of Compound AI was 280 as measured by FAB MS.

Using AI (21.0 g, 57.2 mmol), the synthesis of Compound AJ was performed in substantially the same manner as Compound B to obtain Compound AJ (24.9 g, yield 90%). The molecular weight of Compound AJ was 368 as measured by FAB MS.

Using AJ (24.0 g, 65.3 mmol), the synthesis of Compound AK was performed in substantially the same manner as Compound AG to obtain Compound AK (13.9 g, yield 60%). The molecular weight of Compound AK was 354 as measured by FAB MS.

Using AK (13.0 g, 36.8 mmol), the synthesis of compound AL was performed in substantially the same manner as Compound C to obtain Compound AL (14.8 g, yield 85%). The molecular weight of Compound AL was 946 as measured by FAB MS.

Using AL (14.0 g, 14.8 mmol), the synthesis of Compound 64 was performed in substantially the same manner as the synthesis of Compound 3 to obtain Compound 64 (9.96 g, yield 70%). The molecular weight of Compound 64 was 962 as measured by FAB MS. Sublimation purification (400° C., 8.8×10⁻³ Pa) was carried out and device evaluation was performed.

### 12. Synthesis of Compound 75

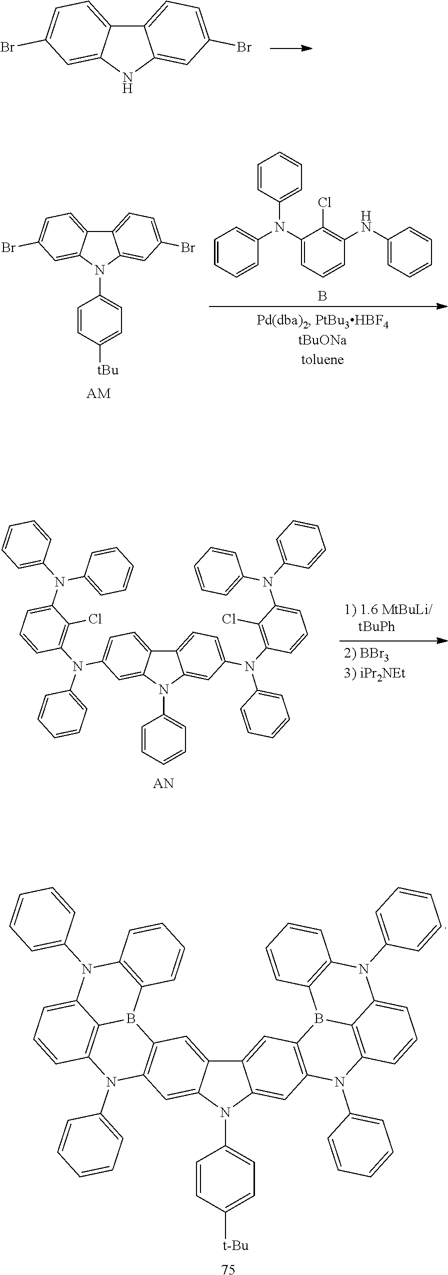

The synthesis of Compound AM was performed by adding 60% NaH (6.2 g, 155 mmol) to a solution of 2,7-dibromo-9H-carbazole (25.0 g, 77.4 mmol) in 160 mL NMP under ice-cooling, and stirring for 1 hour. After adding 1-(tert-butyl)-4-fluorobenzene (17.7 g, 116 mmol) and stirring at room temperature for 1 hour, it was heated and stirred at 60° C. for 24 hours. Water was added, extraction was performed with CH₂Cl₂, and an organic layer was concentrated and purified by silica gel column chromatography to obtain Compound AM (21.4 g, yield 60%). The molecular weight of Compound X was 457 as measured by FAB MS.

Using AM (21.0 g, 45.9 mmol), the synthesis of Compound AN was performed in substantially the same manner as Compound C to obtain Compound AN (19.8 g, yield 88%). The molecular weight of Compound AN was 1038 as measured by FAB MS.

Using AN (19.0 g, 19.4 mmol), the synthesis of Compound 75 was performed in substantially the same manner as the synthesis of Compound 1 to obtain Compound 75 (2.28 g, yield 12%). The molecular weight of Compound 75 was 984 as measured by FAB MS. Sublimation purification (370° C., 5.7×10⁻³ Pa) was carried out and device evaluation was performed.

### Manufacture of Organic Electroluminescence Device

Example organic electroluminescence devices of Examples 1 to 12 were manufactured using the above-described Compounds 1, 2, 3, 4, 5, 28, 31, 33, 48, 54, 64, and 75 as emission layer materials.

### Example Compounds

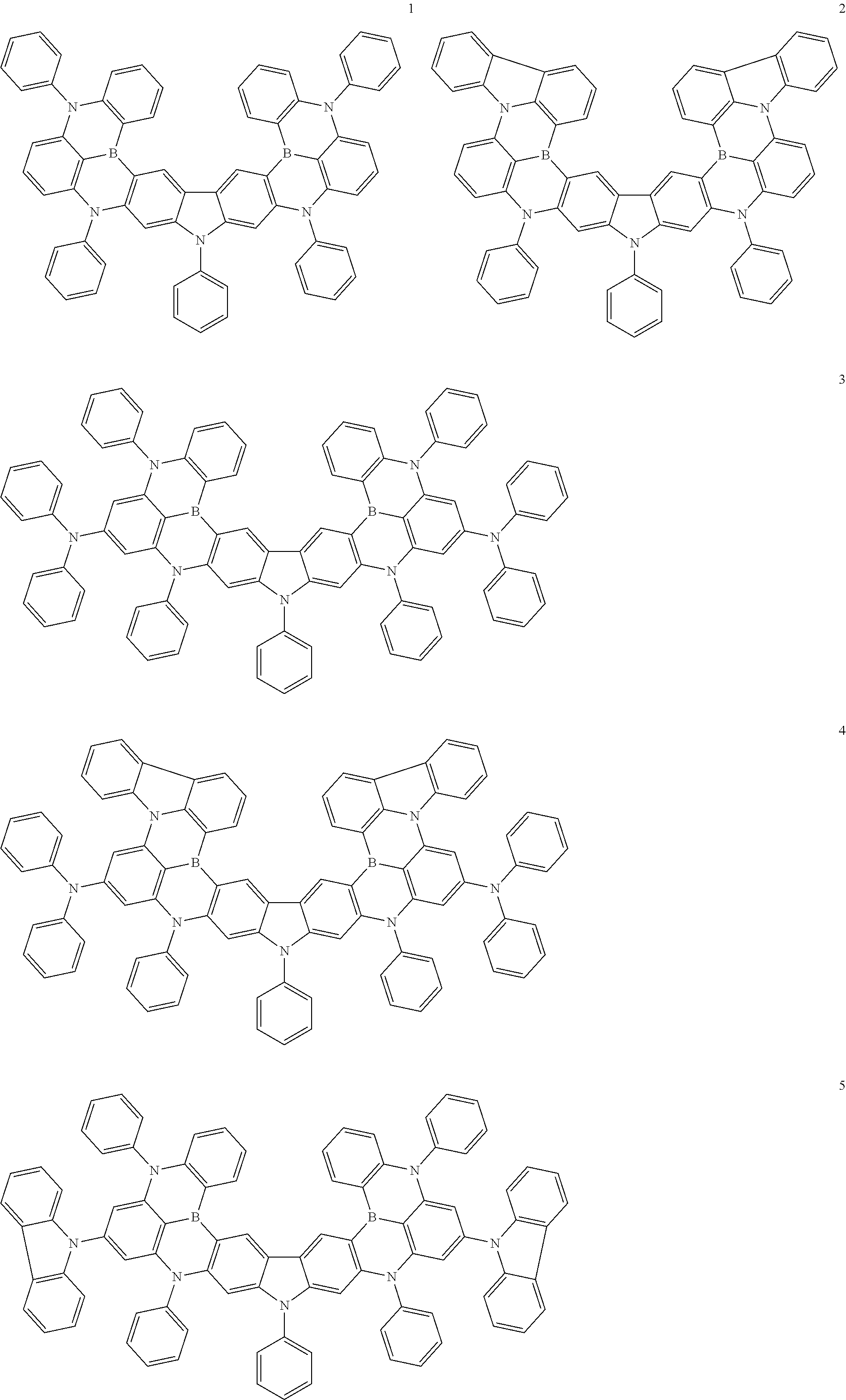

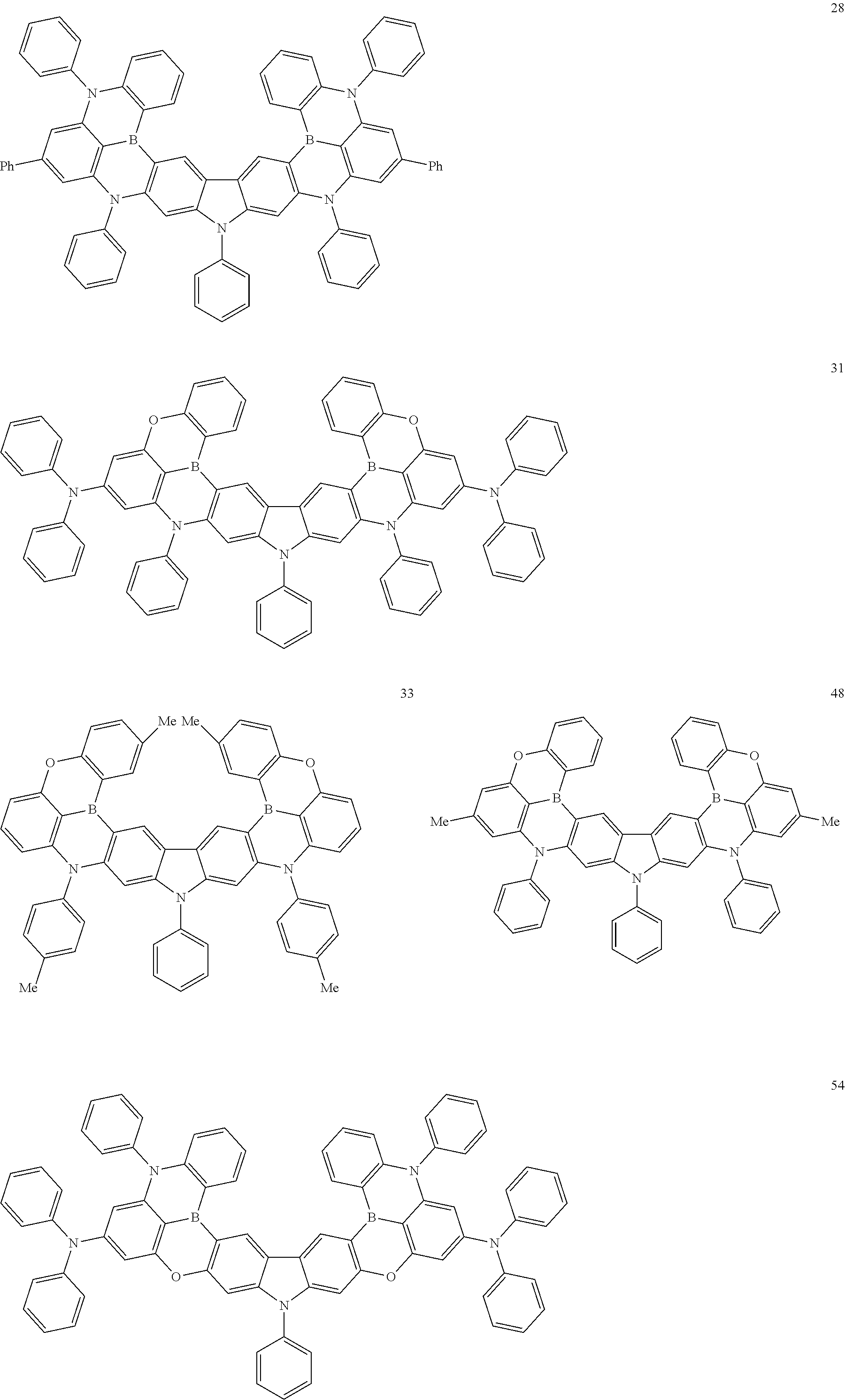

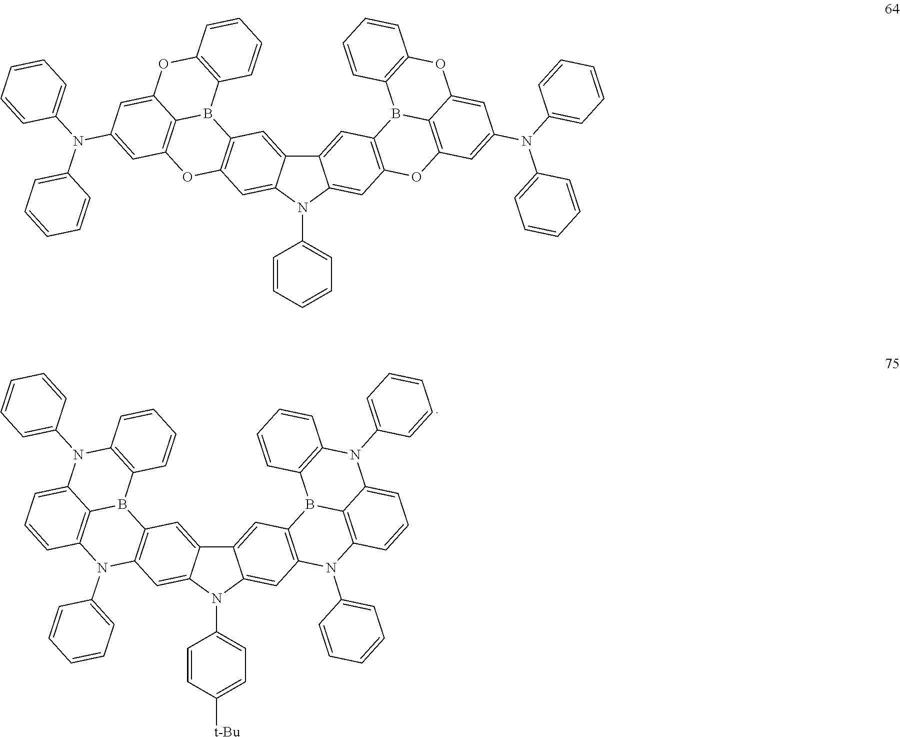 [SMILES: c1ccc(N(c2ccccc2)c2cc3c4c(c2)Oc2cc5c(cc2B4c2ccccc2O3)c2cc3c(cc2n5-c2ccccc2)Oc2cc(N(c4ccccc4)c4ccccc4)cc4c2B3c2ccccc2O4)cc1 ; CC(C)(C)c1ccc(-n2c3cc4c(cc3c3cc5c(cc32)N(c2ccccc2)c2cccc3c2B5c2ccccc2N3c2ccccc2)B2c3ccccc3N(c3ccccc3)c3cccc(c32)N4c2ccccc2)cc1]

Example organic electroluminescence devices of Comparative Examples 1 to 8 were manufactured using Comparative Example Compounds X-1 to X-8 as emission layer materials.

### Comparative Example Compounds

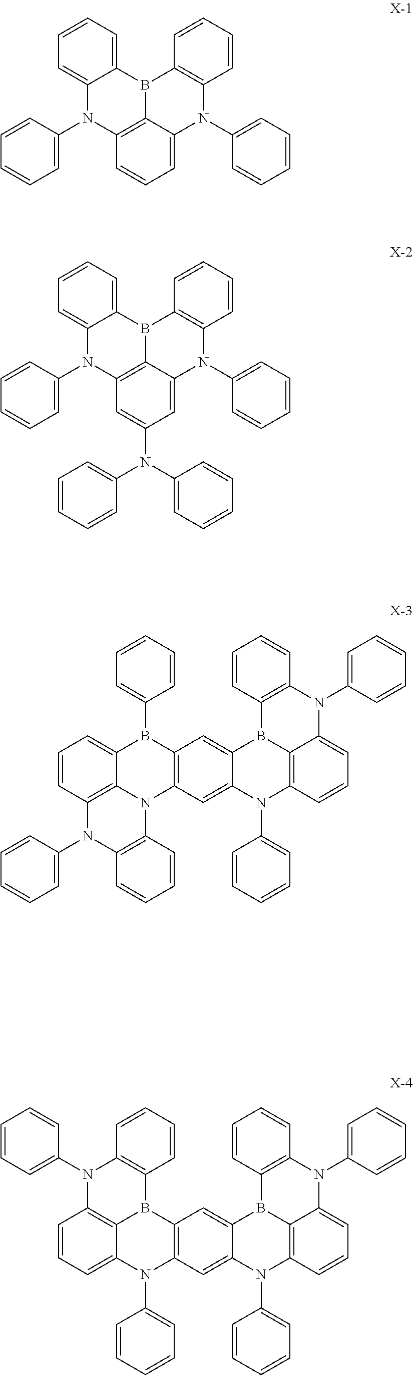 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(B2c3cc4c(cc3N3c5ccccc5N(c5ccccc5)c5cccc2c53)N(c2ccccc2)c2cccc3c2B4c2ccccc2N3c2ccccc2)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1]

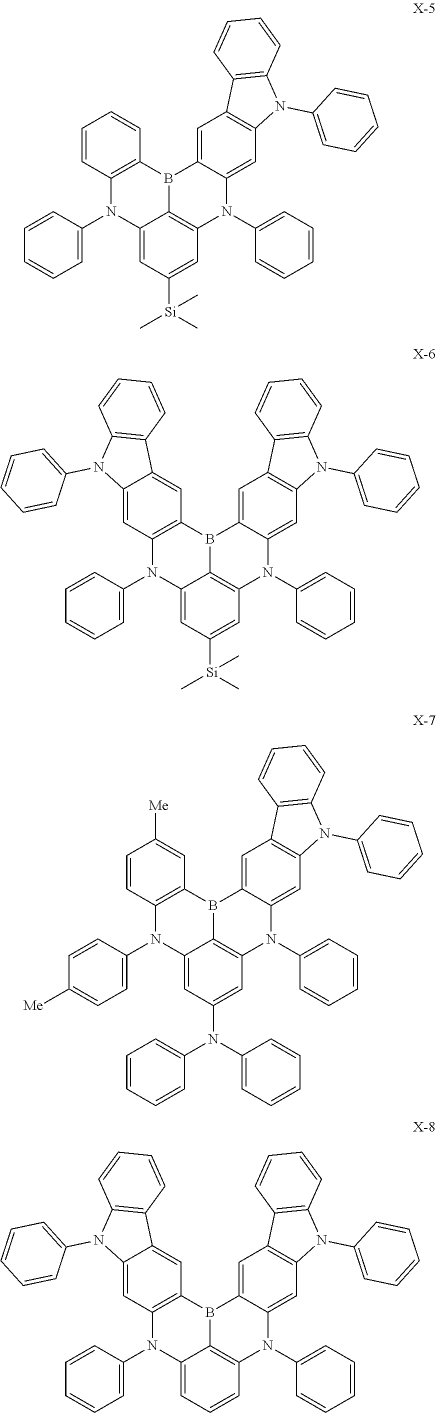 [SMILES: C[Si](C)(C)c1cc2c3c(c1)N(c1ccccc1)c1cc4c(cc1B3c1ccccc1N2c1ccccc1)c1ccccc1n4-c1ccccc1 ; C[Si](C)(C)c1cc2c3c(c1)N(c1ccccc1)c1cc4c(cc1B3c1cc3c5ccccc5n(-c5ccccc5)c3cc1N2c1ccccc1)c1ccccc1n4-c1ccccc1 ; Cc1ccc(N2c3ccc(C)cc3B3c4cc5c6ccccc6n(-c6ccccc6)c5cc4N(c4ccccc4)c4cc(N(c5ccccc5)c5ccccc5)cc2c43)cc1 ; c1ccc(N2c3cc4c(cc3B3c5cc6c7ccccc7n(-c7ccccc7)c6cc5N(c5ccccc5)c5cccc2c53)c2ccccc2n4-c2ccccc2)cc1]

The organic electroluminescence devices of Examples and Comparative Examples were manufactured by the following method. An ITO layer having a thickness of 1500 Å was patterned on a glass substrate, washed with ultrapure water, and UV ozone-treated for 10 minutes. Thereafter, HAT-CN was deposited to a thickness of 100 Å, α-NPD was deposited to a thickness of 800 Å, and mCP was deposited to a thickness of 50 Å to form a hole transport region.

Next, in the forming of an emission layer, a polycyclic compound of an embodiment or a comparative compound were co-deposited with mCBP at 10:90 to form a layer having a thickness of 200 Å.

A 300 Å-thick layer was formed on the emission layer with TPBi and a 5 Å-thick layer was formed with LiF to form an electron transport region. Next, a second electrode having a thickness of 1000 Å was formed with aluminum (Al).

In an embodiment, the hole transport region, the emission layer, the electron transport region, and the second electrode were formed using a vacuum deposition apparatus.

### Evaluation of Organic Electroluminescence Device Characteristics

For the evaluation of the characteristics of an organic electroluminescence device according to the Examples and Comparative Examples, the maximum emission wavelength (nm), the maximum external quantum yield (%), and the external quantum efficiency (%) at a luminance of 1000 cd/m² were measured using a C9920-11 luminance alignment measuring apparatus (HAMAMATSU Photonics).

TABLE 1

| | | Maxi- | Maxi- | |
|---|---|---|---|---|
| | | mum | mum | |
| | | emission | external | External |
| | Emission | wave- | quantum | quantum |
| | layer | length | yield | efficiency |
| | dopant | (nm) | (%) | (%) |
| Example 1 | Example | 464 | 25.5 | 20.1 |
| | Compound 1 | | | |
| Example 2 | Example | 470 | 27.2 | 23.3 |
| | Compound 2 | | | |
| Example 3 | Example | 456 | 22.3 | 19.4 |
| | Compound 3 | | | |
| Example 4 | Example | 450 | 22.1 | 19.0 |
| | Compound 4 | | | |
| Example 5 | Example | 463 | 25.3 | 20.0 |
| | Compound 5 | | | |
| Example 6 | Example | 468 | 27.0 | 23.2 |
| | Compound 28 | | | |
| Example 7 | Example | 446 | 19.2 | 18.3 |
| | Compound 31 | | | |
| Example 8 | Example | 448 | 18.9 | 15.4 |
| | Compound 33 | | | |
| Example 9 | Example | 444 | 18.3 | 17.2 |
| | Compound 48 | | | |
| Example 10 | Example | 440 | 18.2 | 16.3 |
| | Compound 54 | | | |
| Example 11 | Example | 430 | 17.5 | 16.7 |
| | Compound 64 | | | |
| Example 12 | Example | 460 | 22.3 | 21.0 |
| | Compound 75 | | | |
| Comparative | Comparative | 459 | 13.2 | 5.4 |
| Example 1 | Example | | | |
| | Compound X-1 | | | |
| Comparative | Comparative | 446 | 14.2 | 6.4 |
| Example 2 | Example | | | |
| | Compound X-2 | | | |
| Comparative | Comparative | 520 | 15.2 | 5.4 |
| Example 3 | Example | | | |
| | Compound X-3 | | | |
| Comparative | Comparative | 465 | 16.5 | 11.2 |
| Example 4 | Example | | | |
| | Compound X-4 | | | |
| Comparative | Comparative | 456 | 11.0 | 5.3 |
| Example 5 | Example | | | |
| | Compound X-5 | | | |
| Comparative | Comparative | 459 | 11.6 | 7.3 |
| Example 6 | Example | | | |
| | Compound X-6 | | | |
| Comparative | Comparative | 456 | 11.8 | 8.9 |
| Example 7 | Example | | | |
| | Compound X-7 | | | |
| Comparative | Comparative | 462 | 11.4 | 5.9 |
| Example 8 | Example | | | |
| | Compound X-8 | | | |

Referring to the results of Table 1, when the polycyclic compound according to an embodiment is included in the emission layer, it is confirmed that the external quantum efficiency was improved compared devices including the Comparative Examples. Without being bound by the correctness of any explanation or theory, it is thought that in the polycyclic compounds of Examples 1 to 12, nitrogen atoms may be disposed in the conjugate plane to thereby improve resonance effects and increase vibrator strength (f). Accordingly, it is believed that the external quantum efficiency (EQE) was improved by the reduced half-width and roll-off of the emitted light spectrum, while maintaining deep blue light emission. In addition, the light extraction efficiency is believed to be improved by increasing the planarity of molecules.

The organic electroluminescence device of an embodiment is capable of achieving high luminous efficiency in a blue light wavelength region by using the polycyclic compound represented by Formula 1 as an emission layer material.

The organic electroluminescence device according to an embodiment of the present disclosure may obtain high efficiency and long life.

The polycyclic compound according to an embodiment of the present disclosure may improve the life and efficiency of an organic electroluminescence device.

As used herein, the terms “substantially”, “about”, and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Although the present disclosure has been described with reference to embodiments of the present disclosure, it will be understood that the present disclosure should not be limited to these embodiments, but that various changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. An organic electroluminescence device, comprising:
a first electrode;
a hole transport region on the first electrode;
an emission layer on the hole transport region;
an electron transport region on the emission layer; and
a second electrode on the electron transport region,
wherein the first electrode and the second electrode each independently comprise at least one selected from Ag, Mg, Cu, Al, Pt, Pd, Au, Ni, Nd, Ir, Cr, Li, Ca, LiF/Ca, LiF/Al, Mo, Ti, In, Sn, and Zn, a compound of two or more thereof, a mixture of two or more thereof, and an oxide thereof, and
wherein the emission layer comprises a polycyclic compound represented by Formula 1: 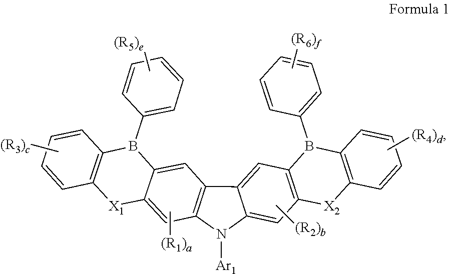
wherein in Formula 1,
X₁ and X₂ are each independently NAr₂, O, or S,
Ar₁ and Ar₂ are each independently a substituted or unsubstituted aryl group having 6 to 30 ring-forming carbon atoms, or a substituted or unsubstituted heteroaryl group having 2 to 30 ring-forming carbon atoms,
R₁ to R₆ are each independently a hydrogen atom, a deuterium atom, a halogen atom, a substituted or unsubstituted amine group, a substituted or unsubstituted thiol group, a substituted or unsubstituted alkoxy group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
a and b are each independently an integer of 0 to 2,
c and d are each independently an integer of 0 to 4, and
e and f are each independently an integer of 0 to 5.

2. The organic electroluminescence device of claim 1, wherein the emission layer is to emit delayed fluorescence.

3. The organic electroluminescence device of claim 1, wherein the emission layer is a delayed fluorescence emission layer comprising a host and a dopant, and the dopant comprises the polycyclic compound.

4. The organic electroluminescence device of claim 1, wherein the emission layer is a thermally activated delayed fluorescence emission layer to emit blue light.

5. The organic electroluminescence device of claim 1, wherein the polycyclic compound represented by Formula 1 is represented by Formula 2: 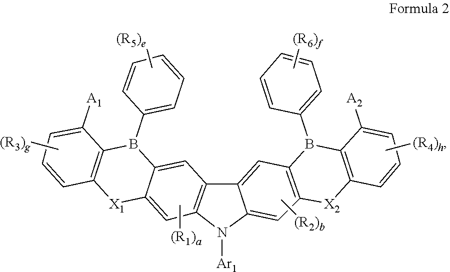
wherein in Formula 2,
A₁ and A₂ are each independently NR₇R₈, OR₉, SR₁₀, or bonded to an adjacent group to form a ring,
R₇ to R₁₀ are each independently a hydrogen atom, a deuterium atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
g and h are each independently an integer of 0 to 3, and
X₁, X₂, Ar₁, R₁ to R₆, a, b, e and f are each independently the same as defined in Formula 1.

6. The organic electroluminescence device of claim 5, wherein the polycyclic compound represented by Formula 2 is represented by Formula 3: 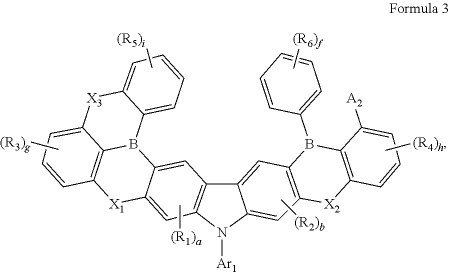
In Formula 3,
X₃ is NAr₃, O, or S,
Ar₃ is a substituted or unsubstituted aryl group having 6 to 30 ring-forming carbon atoms, or a substituted or unsubstituted heteroaryl group having 2 to 30 ring-form ing carbon atoms,
i is an integer of 0 to 4, and
A₂, X₁, X₂, Ar₁, R₁ to R₆, a, b, f, g and h are each independently the same as defined in Formula 2.

7. The organic electroluminescence device of claim 5, wherein the polycyclic compound represented by Formula 2 is represented by Formula 4: 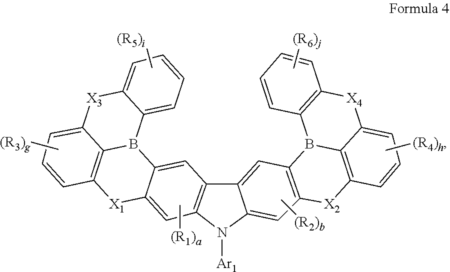
wherein in Formula 4,
X₃ and X₄ are each independently NAr₃, O, or S,
Ar₃ is a substituted or unsubstituted aryl group having 6 to 30 ring-forming carbon atoms, or a substituted or unsubstituted heteroaryl group having 2 to 30 ring-form ing carbon atoms,
i and j are each independently an integer of 0 to 4, and
X₁, X₂, Ar₁, R₁ to R₆, a, b, g and h are each independently the same as defined in Formula 2.

8. The organic electroluminescence device of claim 7, wherein X₁ to X₄ are each independently NAr₃ or O, and Ar₃ is a substituted or unsubstituted aryl group having 6 to 30 ring-forming carbon atoms.

9. The organic electroluminescence device of claim 7, wherein Ar₁ is represented by Formula 5: 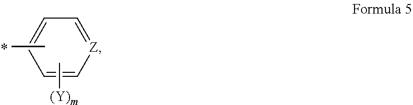
wherein in Formula 5,
Z is CA₁ or N,
A₁ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Y is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
m is an integer of 0 to 4.

10. The organic electroluminescence device of claim 7, wherein R₅ and R₆ are each independently a hydrogen atom, a deuterium atom, a substituted or unsubstituted alkyl group having 1 to 20 carbon atoms, or bonded to an adjacent group to form a ring.

11. The organic electroluminescence device of claim 7, wherein X₁ and X₂ are each independently NAr₂, and
X₃ and X₄ are each independently NAr₃.

12. The organic electroluminescence device of claim 7, wherein X₁ and X₂ are each independently NAr₂, and
X₃ and X₄ are each independently O.

13. The organic electroluminescence device of claim 7, wherein X₁ and X₂ are each independently O, and
X₃ and X₄ are each independently NAr₃.

14. The organic electroluminescence device of claim 7, wherein X₁ to X₄ are each independently O.

15. The organic electroluminescence device of claim 1, wherein the polycyclic compound represented by Formula 1 is any one of the compounds represented by Compound Group 1:

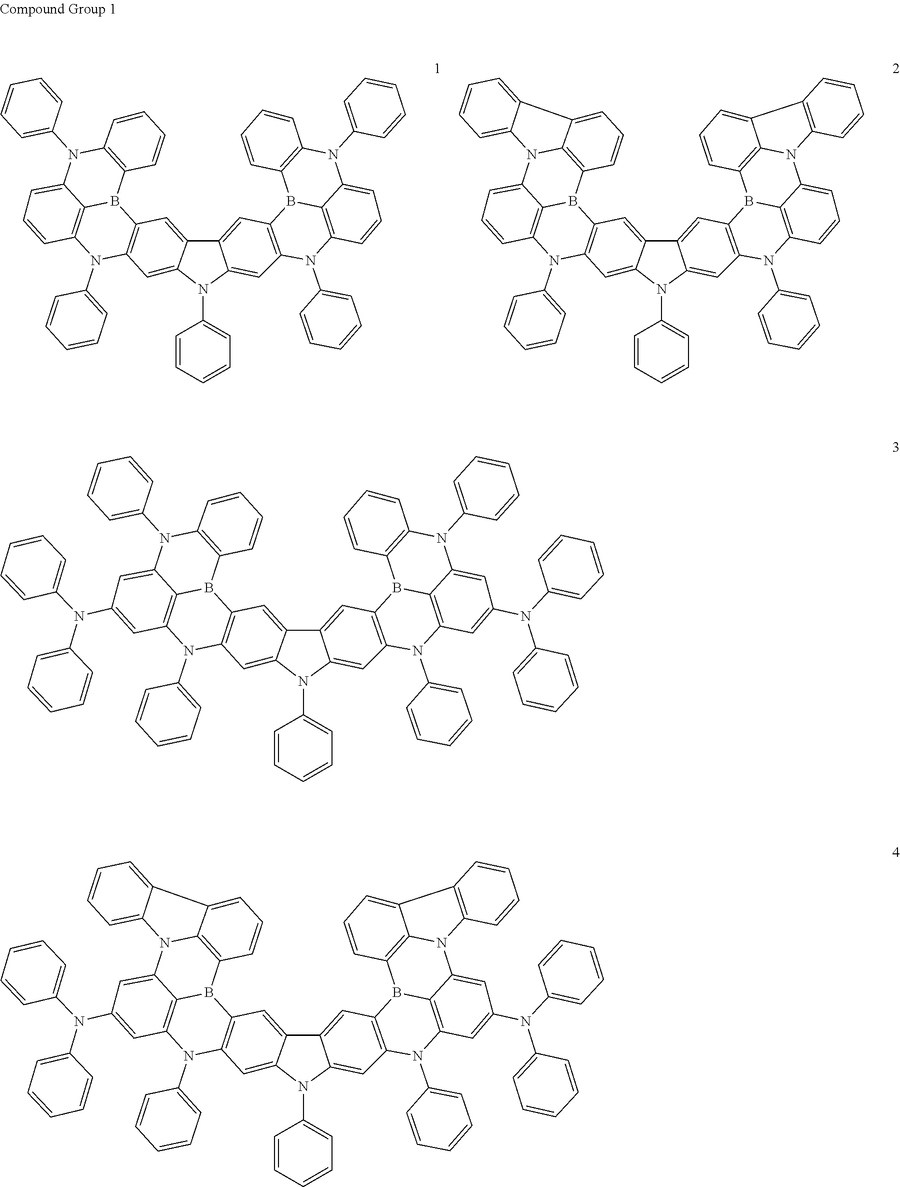

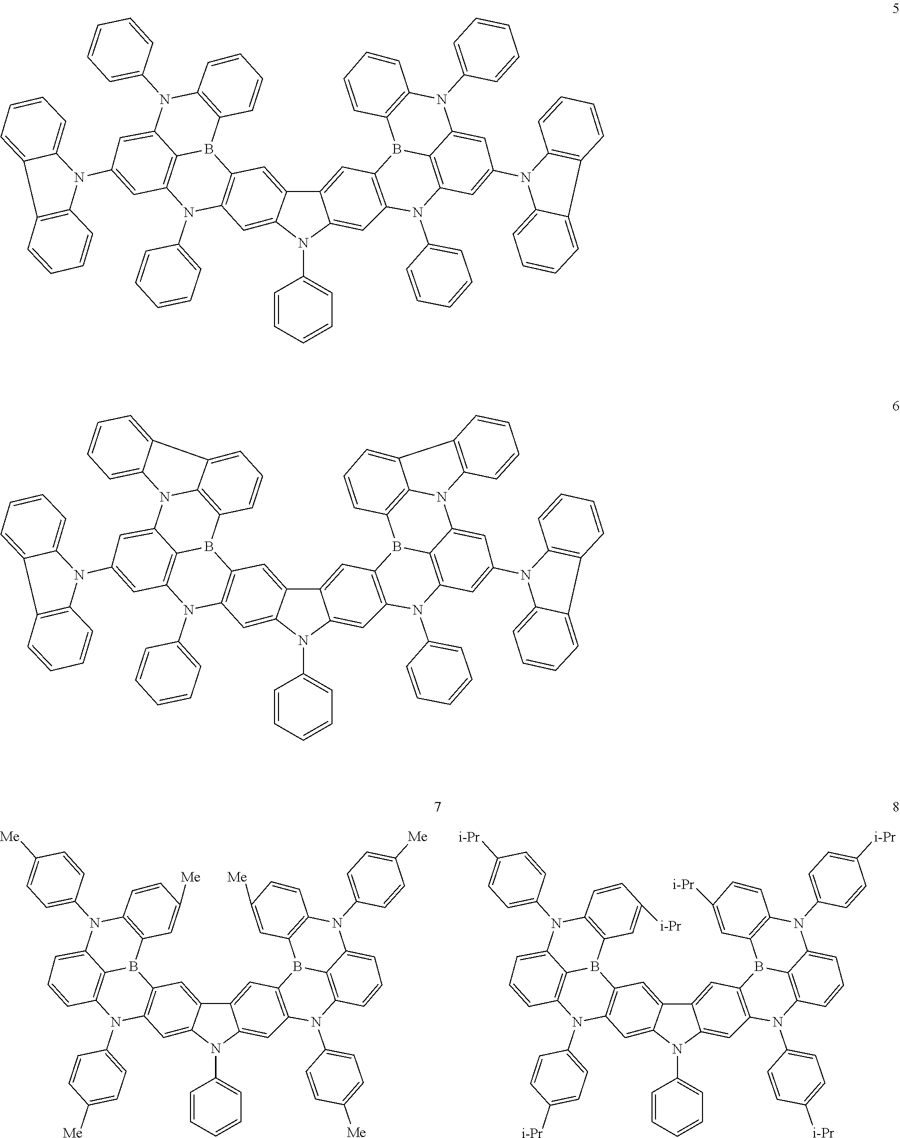

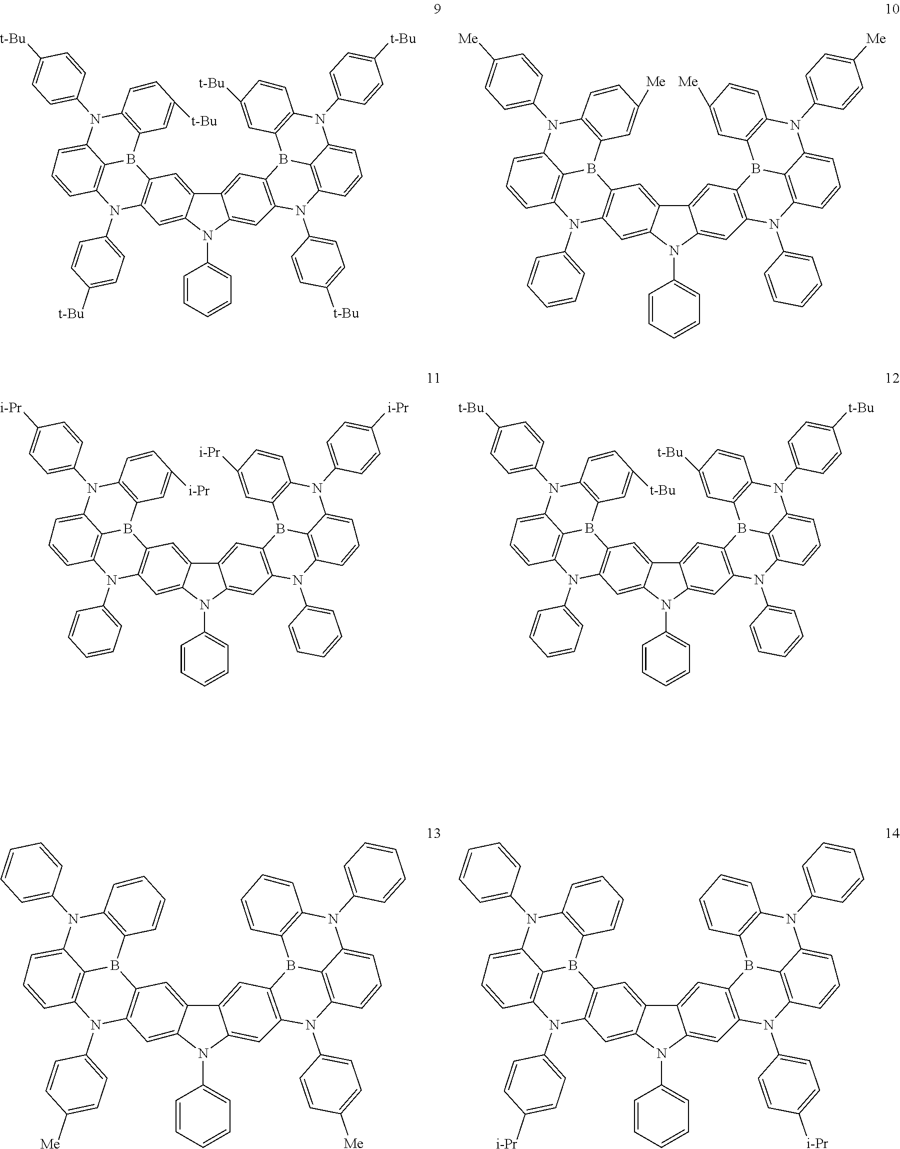

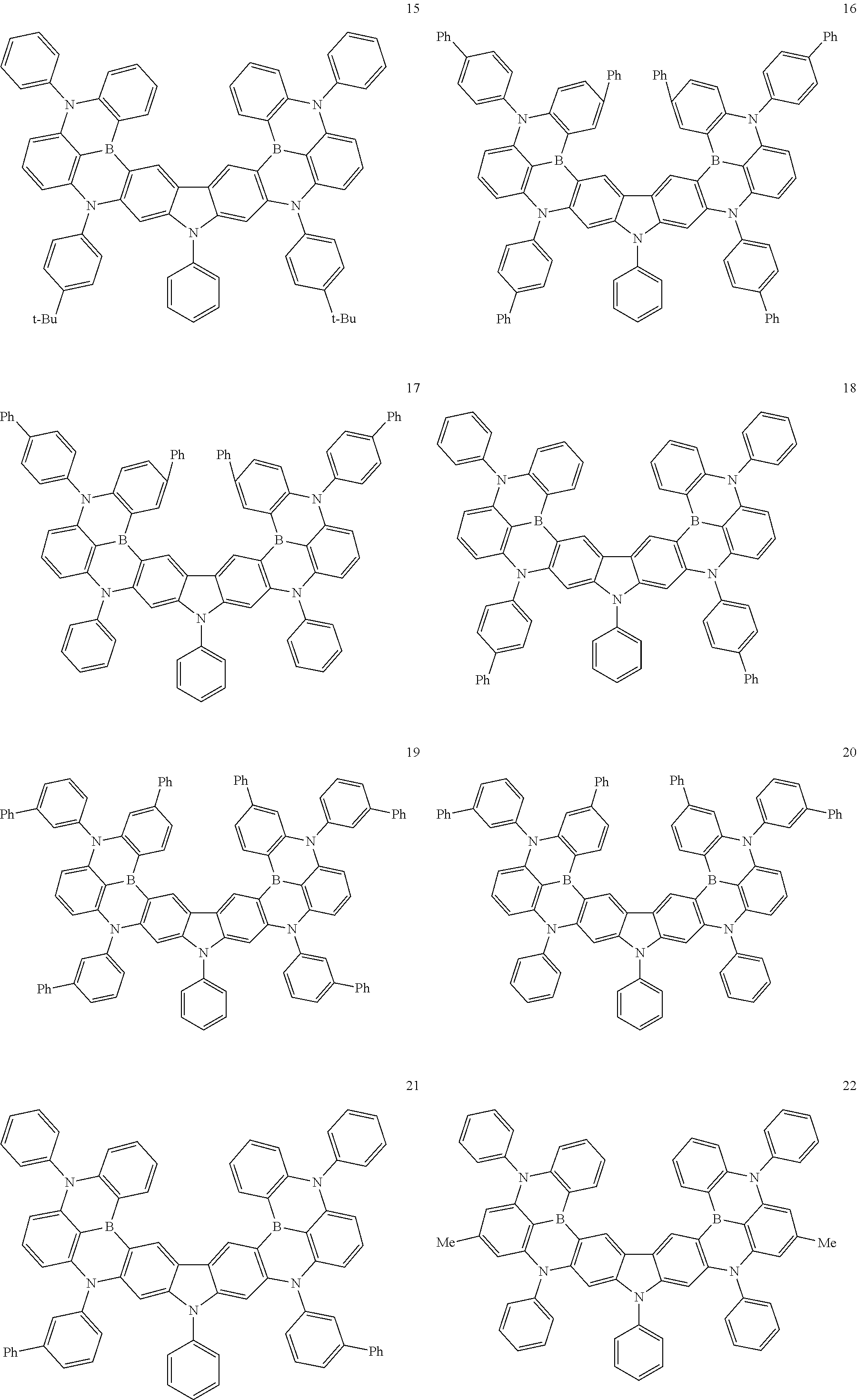

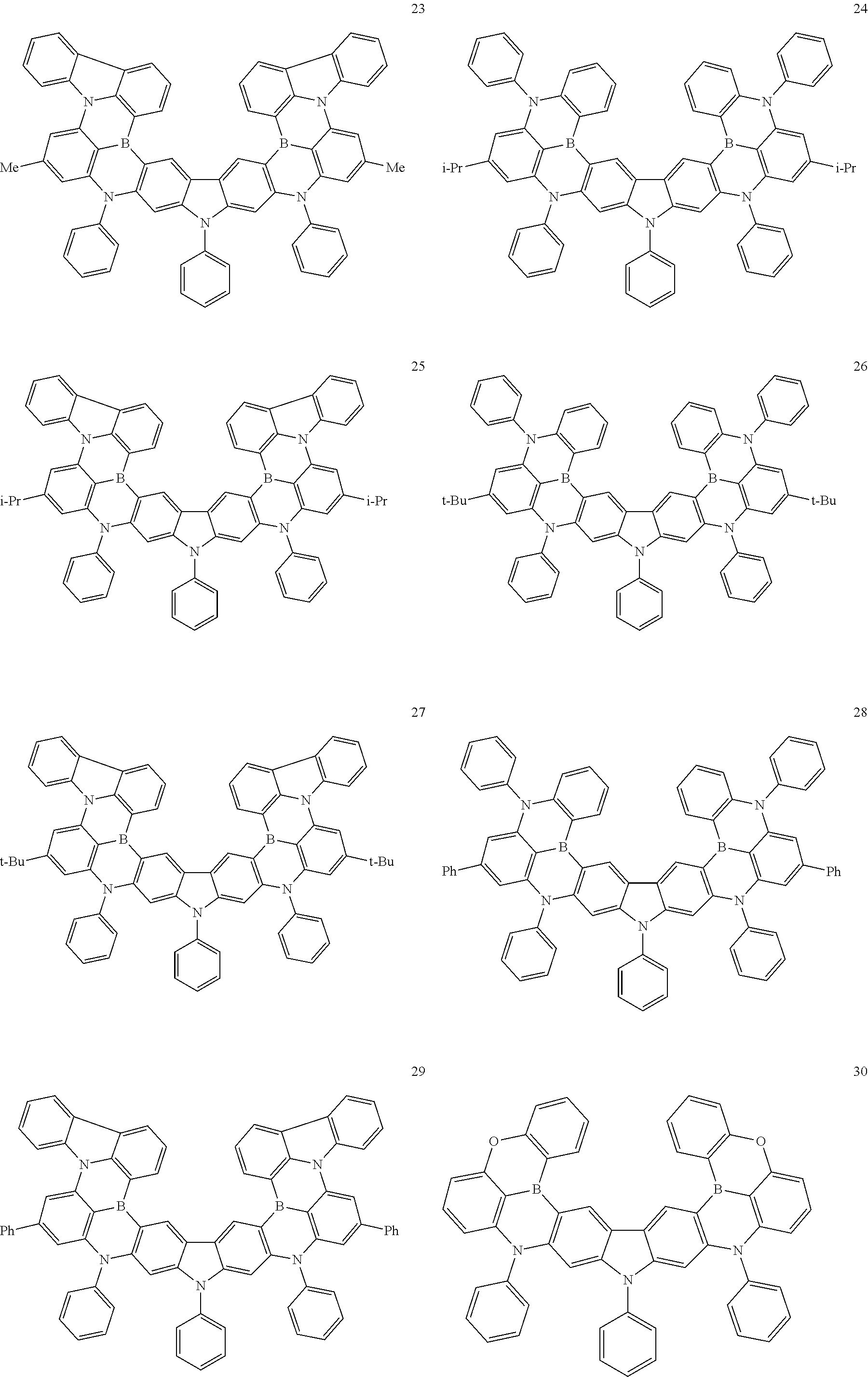

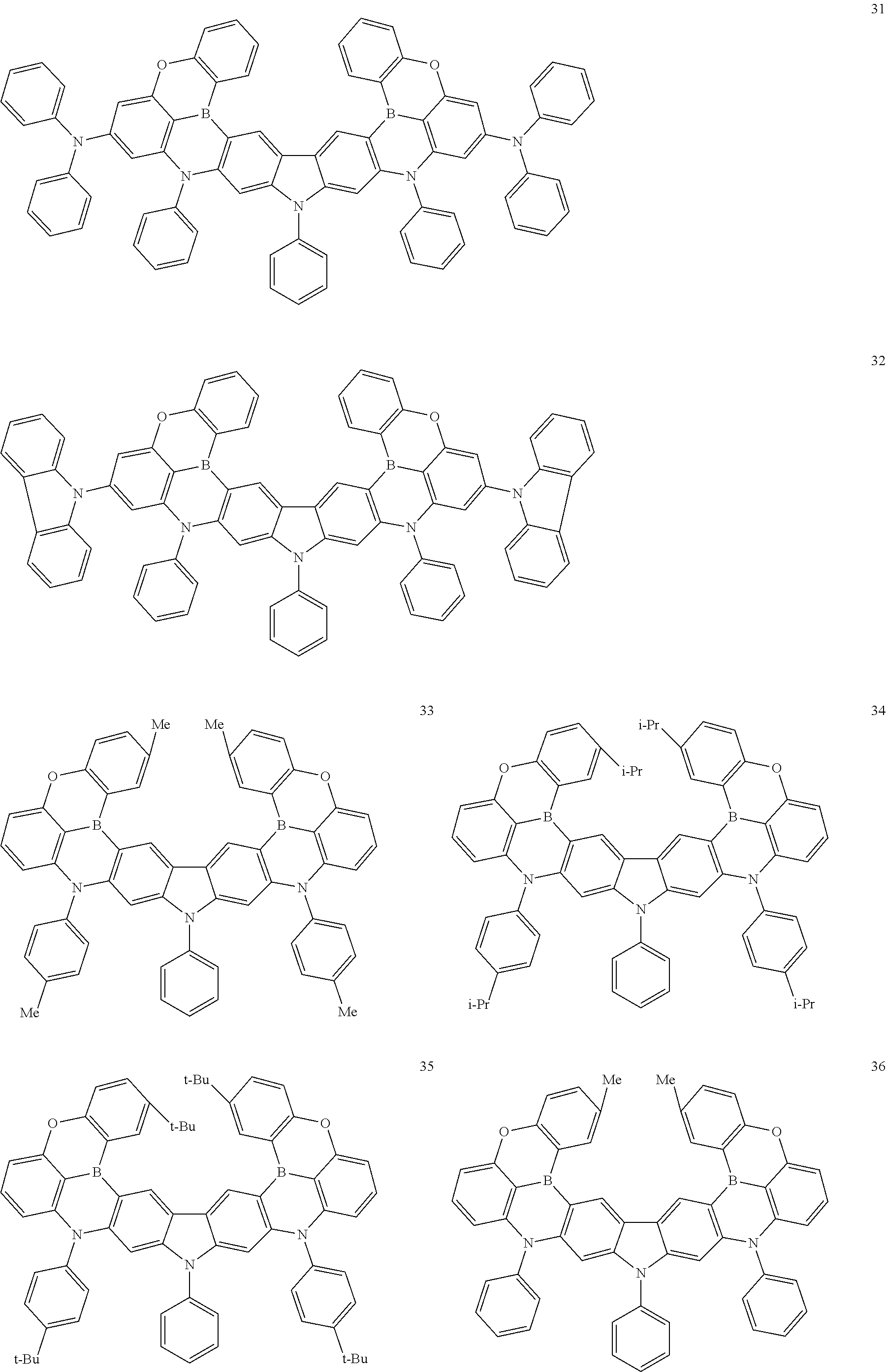

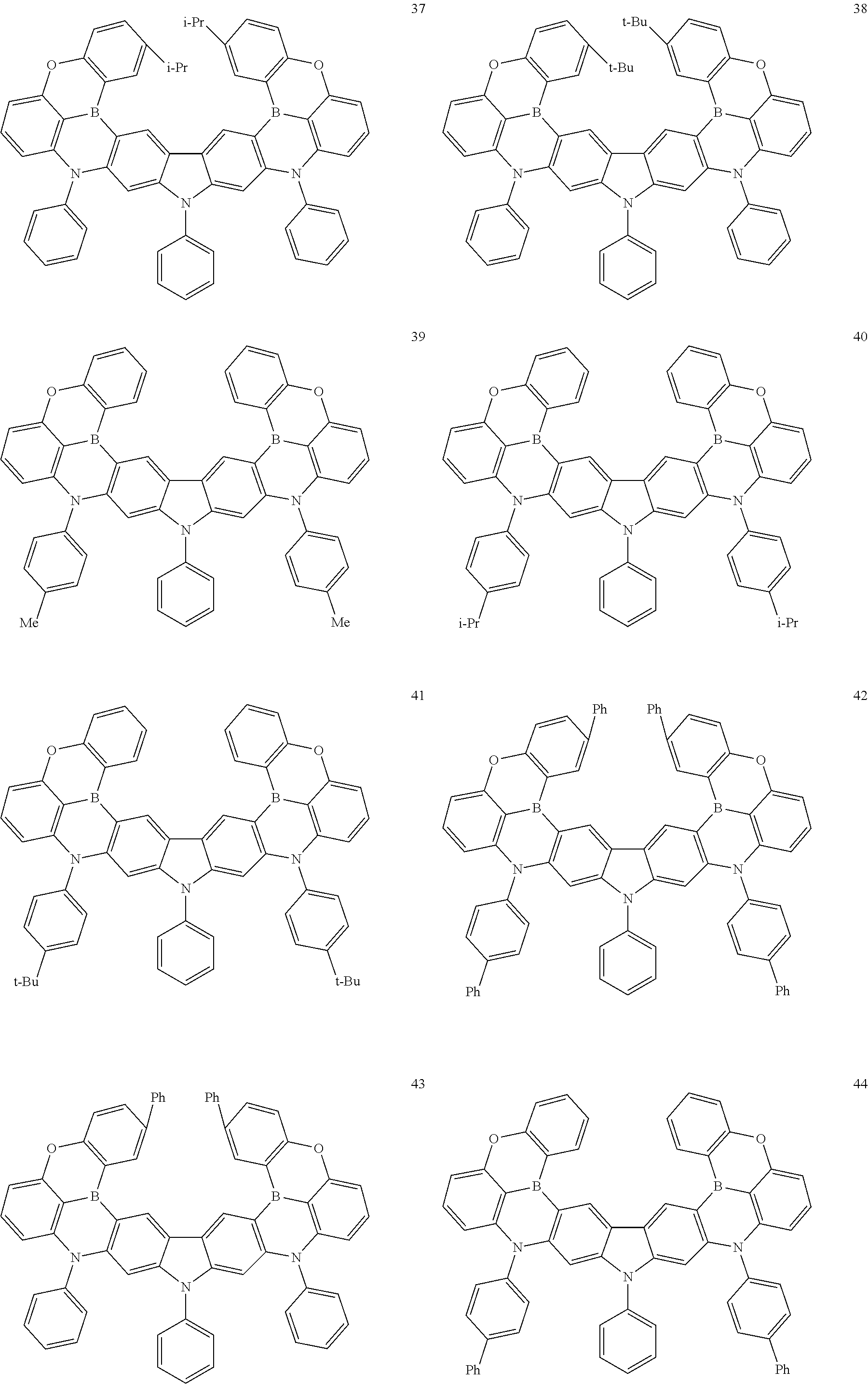

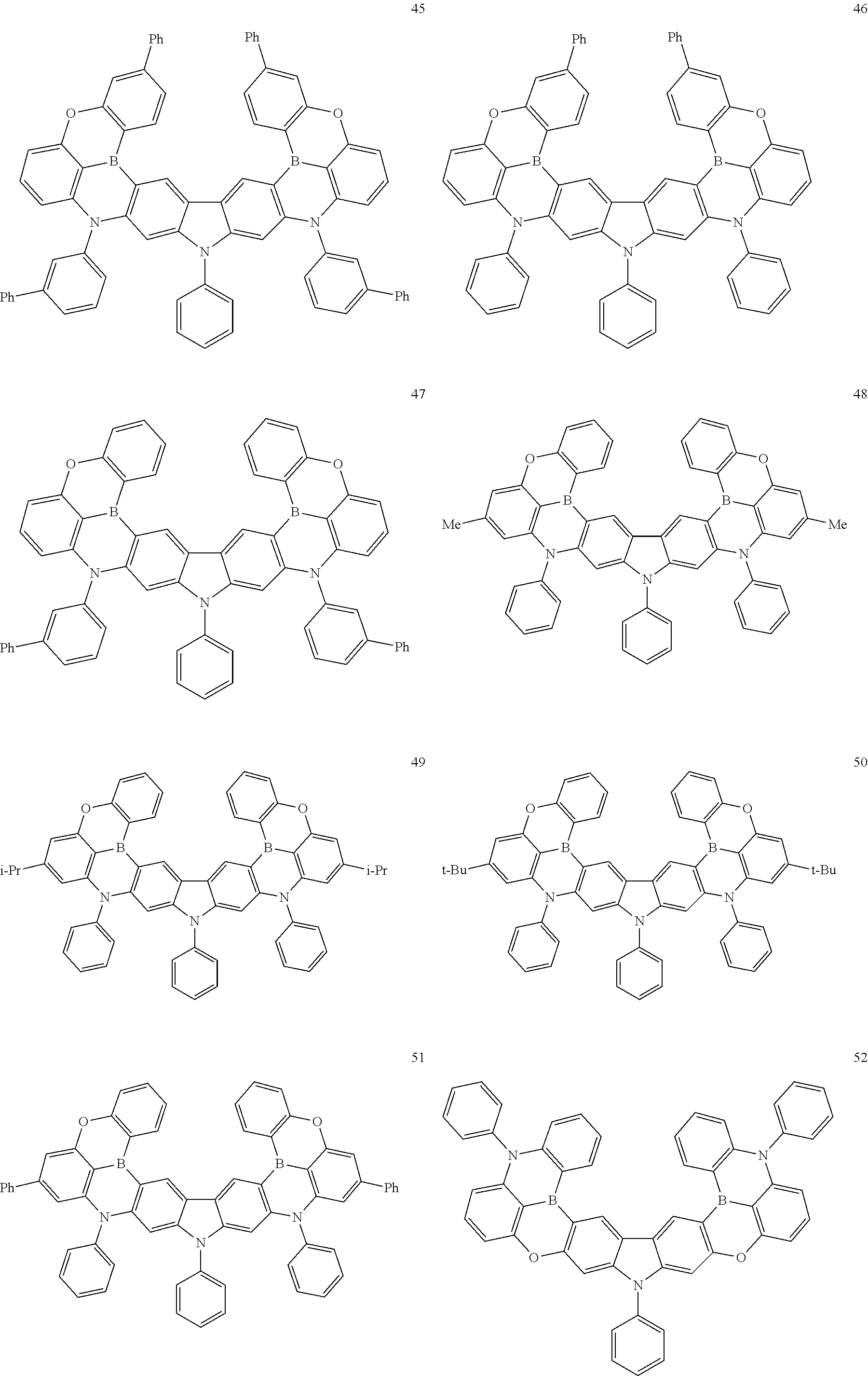

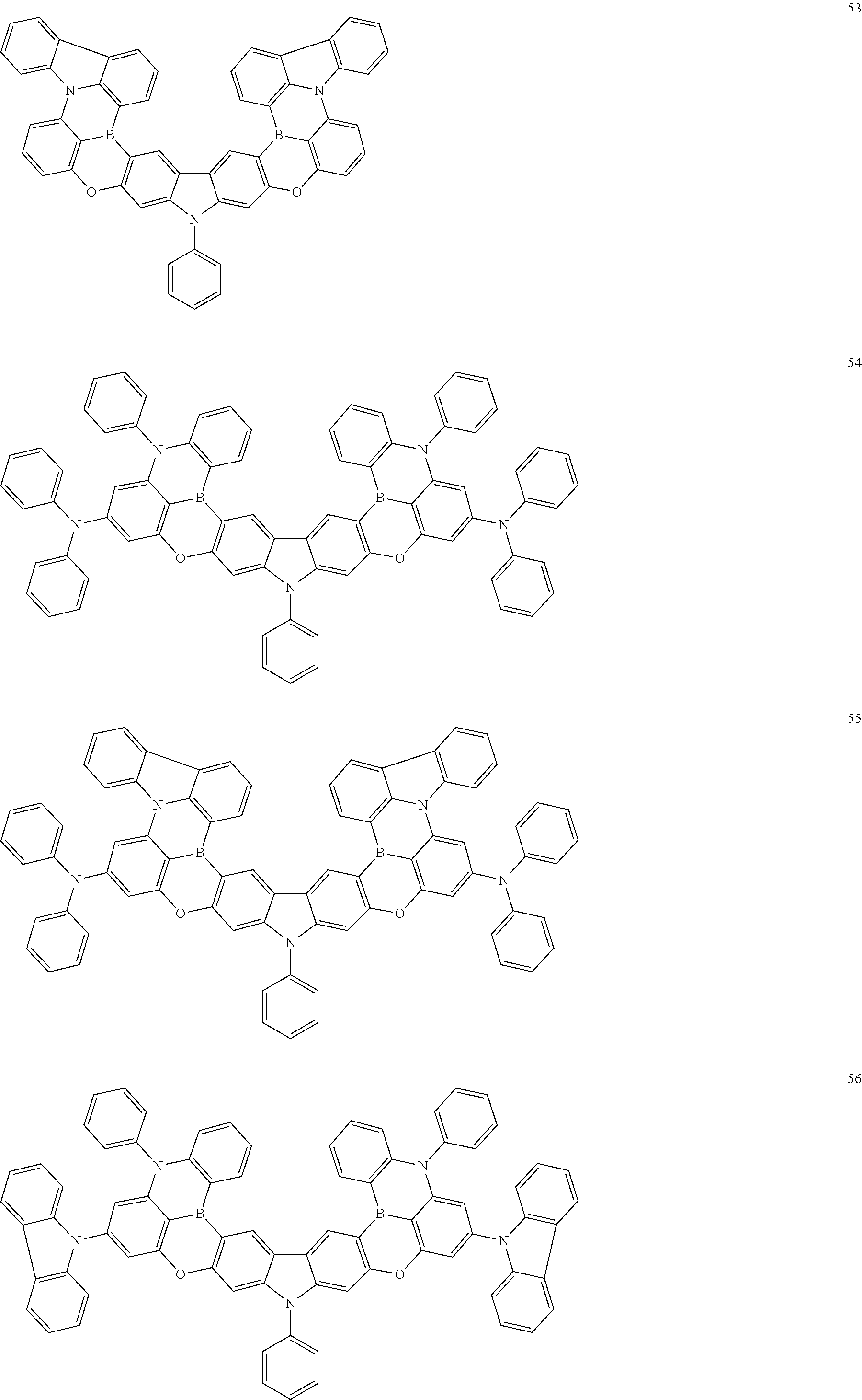

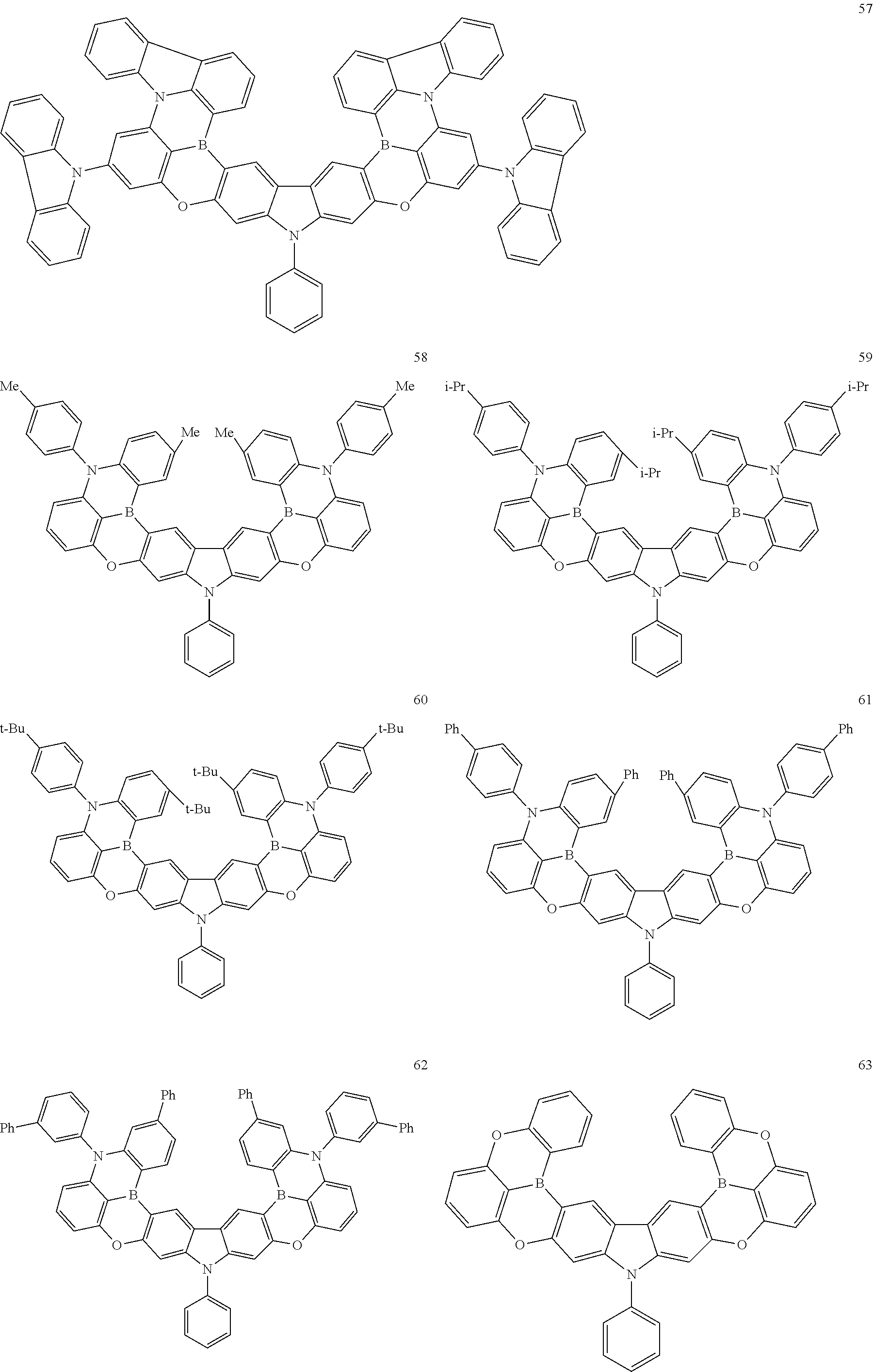

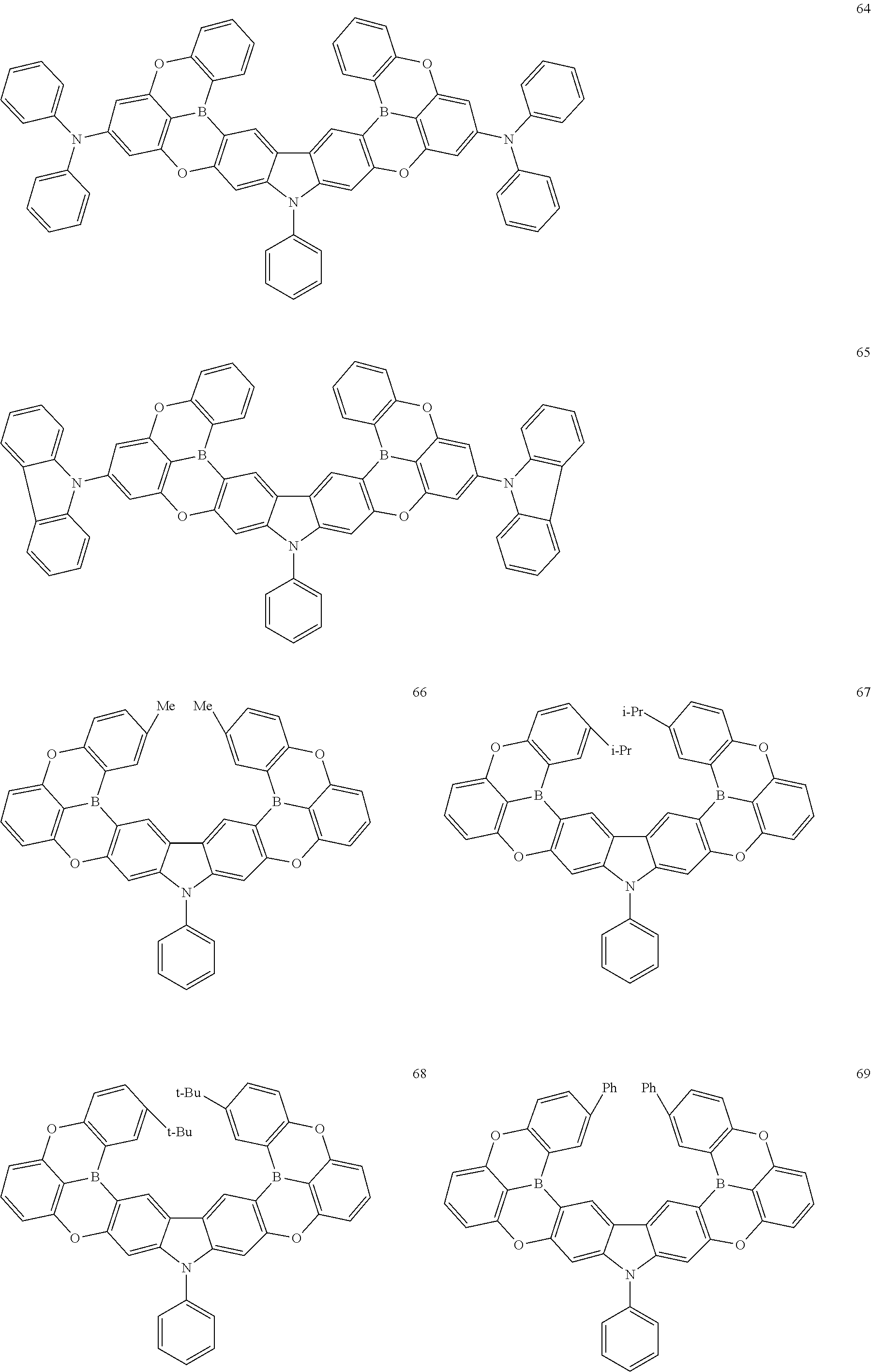

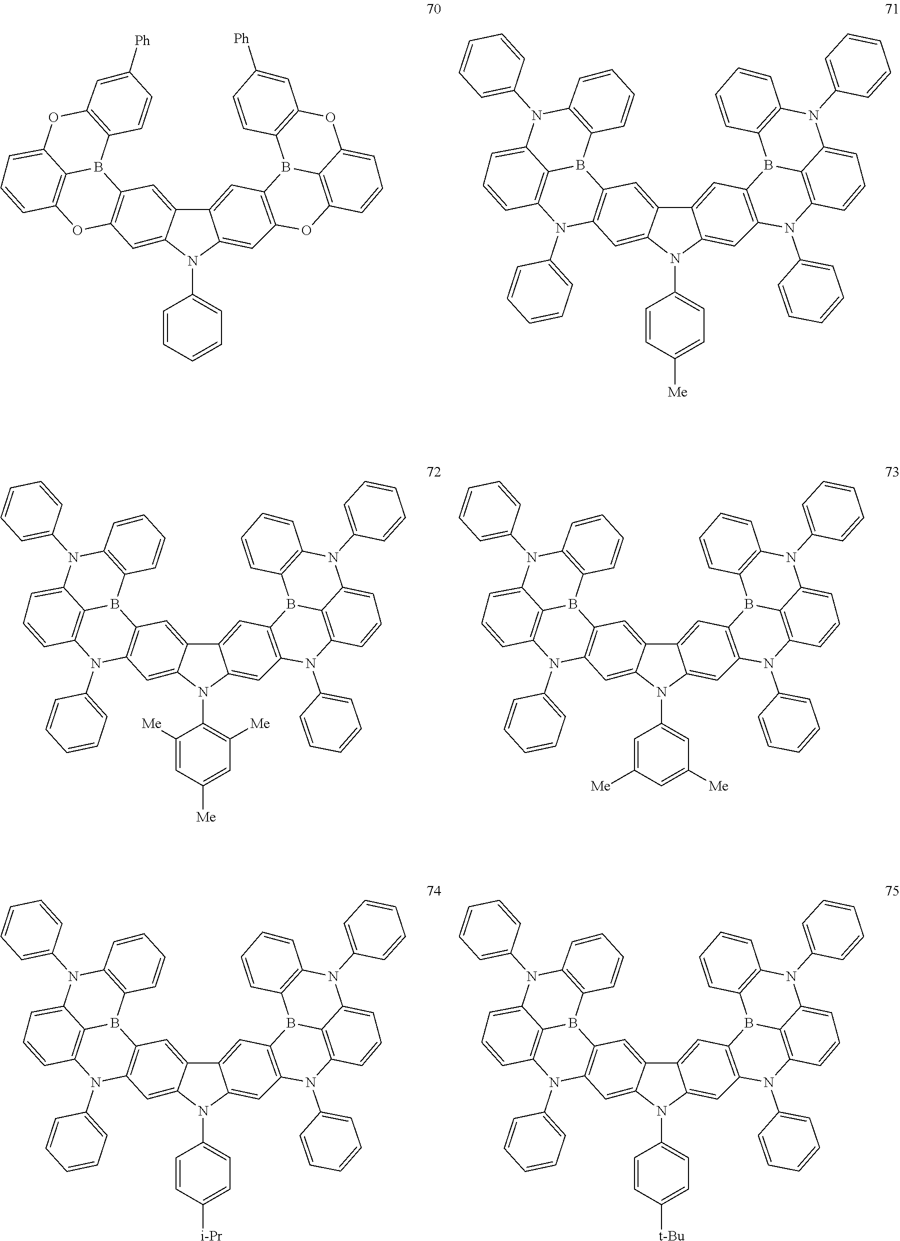

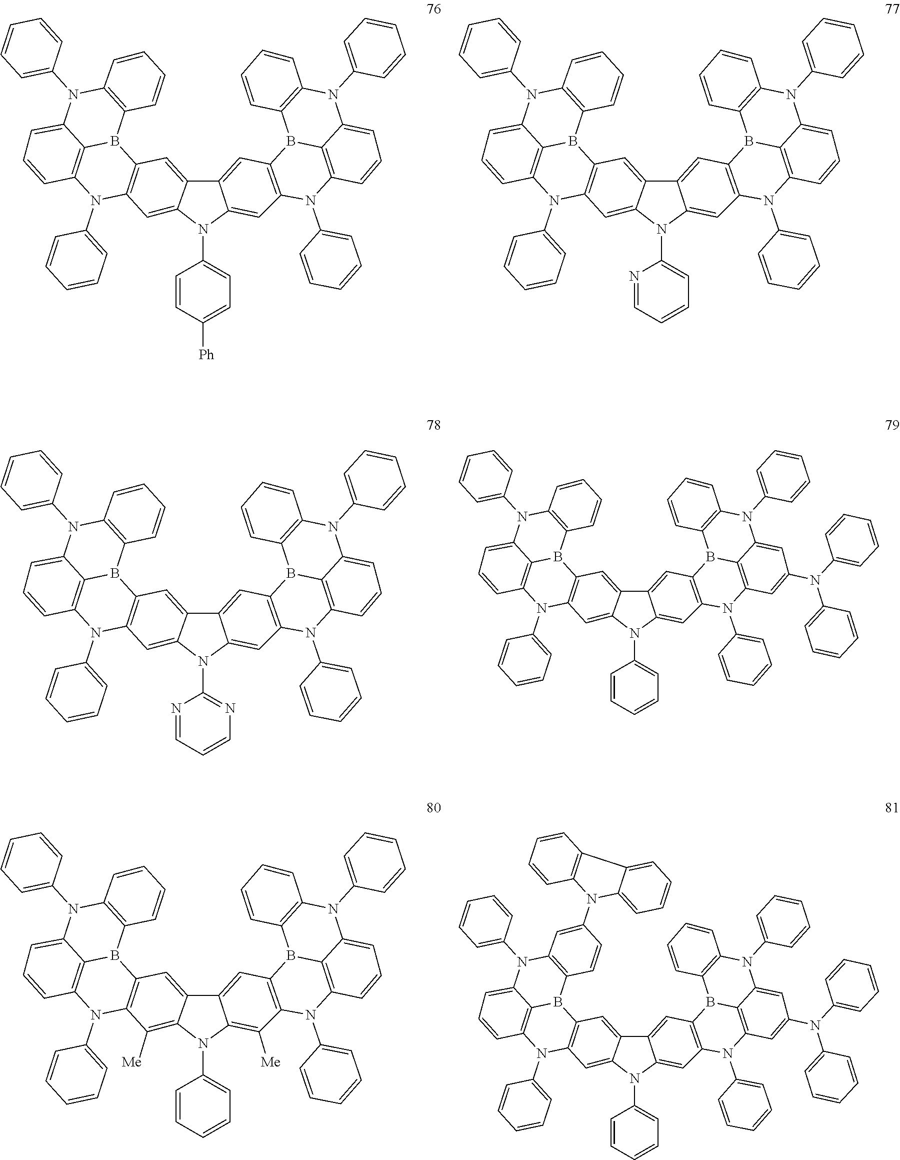

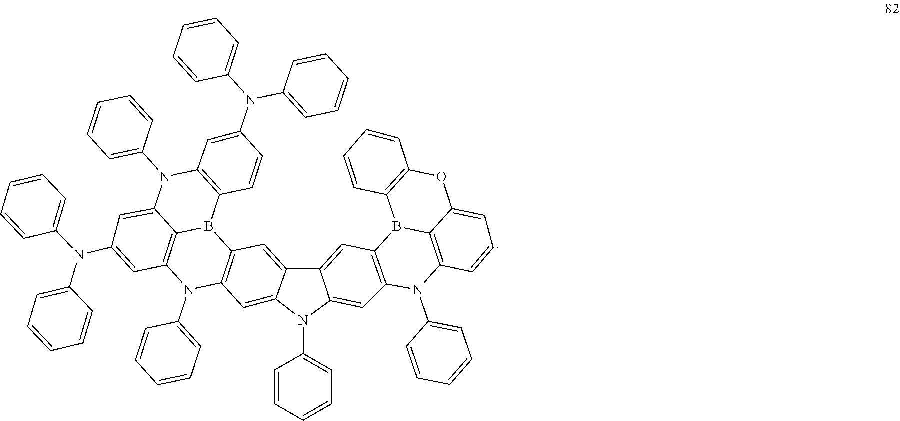 [SMILES: c1ccc(N(c2ccccc2)c2ccc3c(c2)N(c2ccccc2)c2cc(N(c4ccccc4)c4ccccc4)cc4c2B3c2cc3c5cc6c(cc5n(-c5ccccc5)c3cc2N4c2ccccc2)N(c2ccccc2)c2cccc3c2B6c2ccccc2O3)cc1]

16. A polycyclic compound represented by Formula 1: 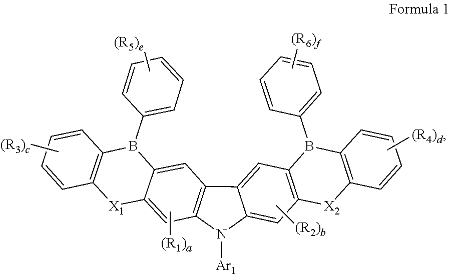
wherein in Formula 1,
X₁ and X₂ are each independently NAr₂, O, or S,
Ar₁ and Ar₂ are each independently a substituted or unsubstituted aryl group having 6 to 30 ring-forming carbon atoms or a substituted or unsubstituted heteroaryl group having 2 to 30 ring-forming carbon atoms,
R₁ to R₆ are each independently a hydrogen atom, a deuterium atom, a halogen atom, a substituted or unsubstituted amine group, a substituted or unsubstituted thiol group, a substituted or unsubstituted alkoxy group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring,
a and b are each independently an integer of 0 to 2,
c and d are each independently an integer of 0 to 4, and
e and f are each independently an integer of 0 to 5.

17. The polycyclic compound of claim 16, wherein the polycyclic compound represented by Formula 1 is represented by Formula 2: 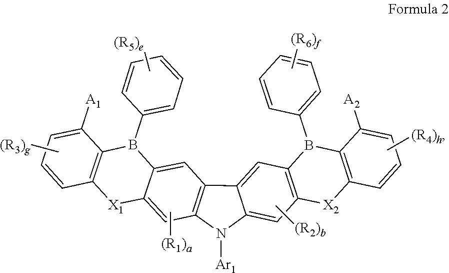
wherein in Formula 2,
A₁ and A₂ are each independently NR₇R₈, OR₉, SR₁₀, or bonded to an adjacent group to form a ring,
R₇ to R₁₀ are each independently a hydrogen atom, a deuterium atom, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 carbon atoms, or bonded to an adjacent group to form a ring,
g and h are each independently an integer of 0 to 3, and
X₁, X₂, Ar₁, R₁ to R₆, a, b, e and f are each independently the same as defined in Formula 1.

18. The polycyclic compound of claim 17, wherein the polycyclic compound represented by Formula 2 is represented by Formula 3: 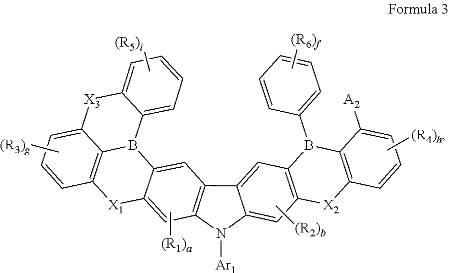
wherein in Formula 3,
X₃ is NAr₃, O, or S,
Ar₃ is a substituted or unsubstituted aryl group having 6 to 30 ring-forming carbon atoms or a substituted or unsubstituted heteroaryl group having 2 to 30 ring-form ing carbon atoms,
i is an integer of 0 to 4, and
A₂, X₁, X₂, Ar₁, R₁ to R₆, a, b, f, g and h are each independently the same as defined in Formula 2.

19. The polycyclic compound of claim 17, wherein the polycyclic compound represented by Formula 2 is represented by Formula 4: 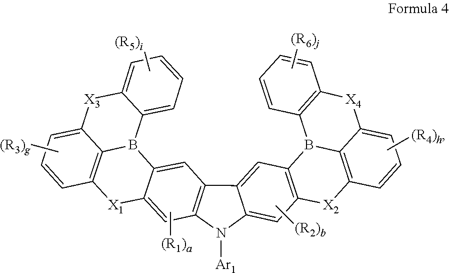
wherein in Formula 4,
X₃ and X₄ are each independently NAr₃, O, or S,
Ara is a substituted or unsubstituted aryl group having 6 to 30 ring-forming carbon atoms or a substituted or unsubstituted heteroaryl group having 2 to 30 ring-form ing carbon atoms,
i and j are each independently an integer of 0 to 4, and
X₁, X₂, Ar₁, R₁ to R₆, a, b, g and h are each independently the same as defined in Formula 2.

20. The polycyclic compound of claim 16, wherein the polycyclic compound represented by Formula 1 is any one of the compounds represented by Compound Group 1: 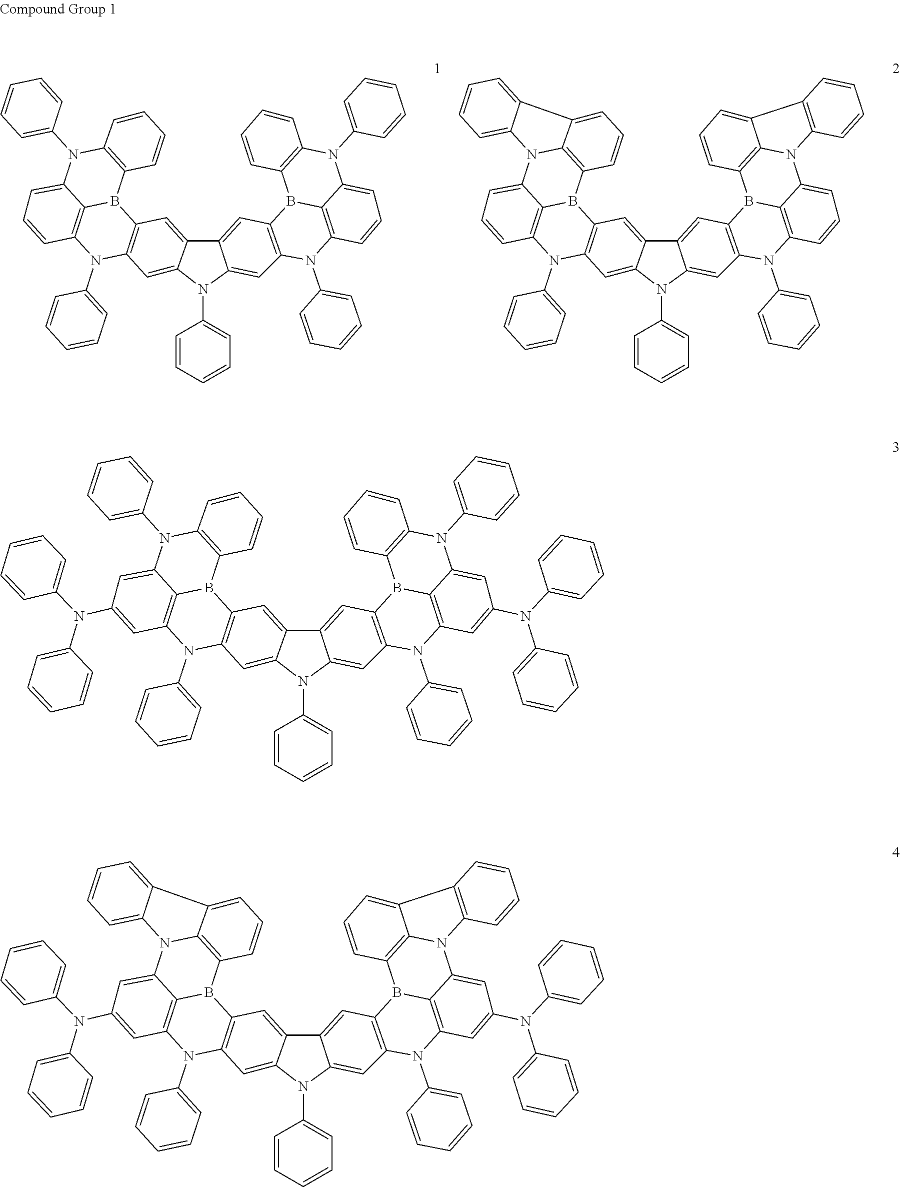 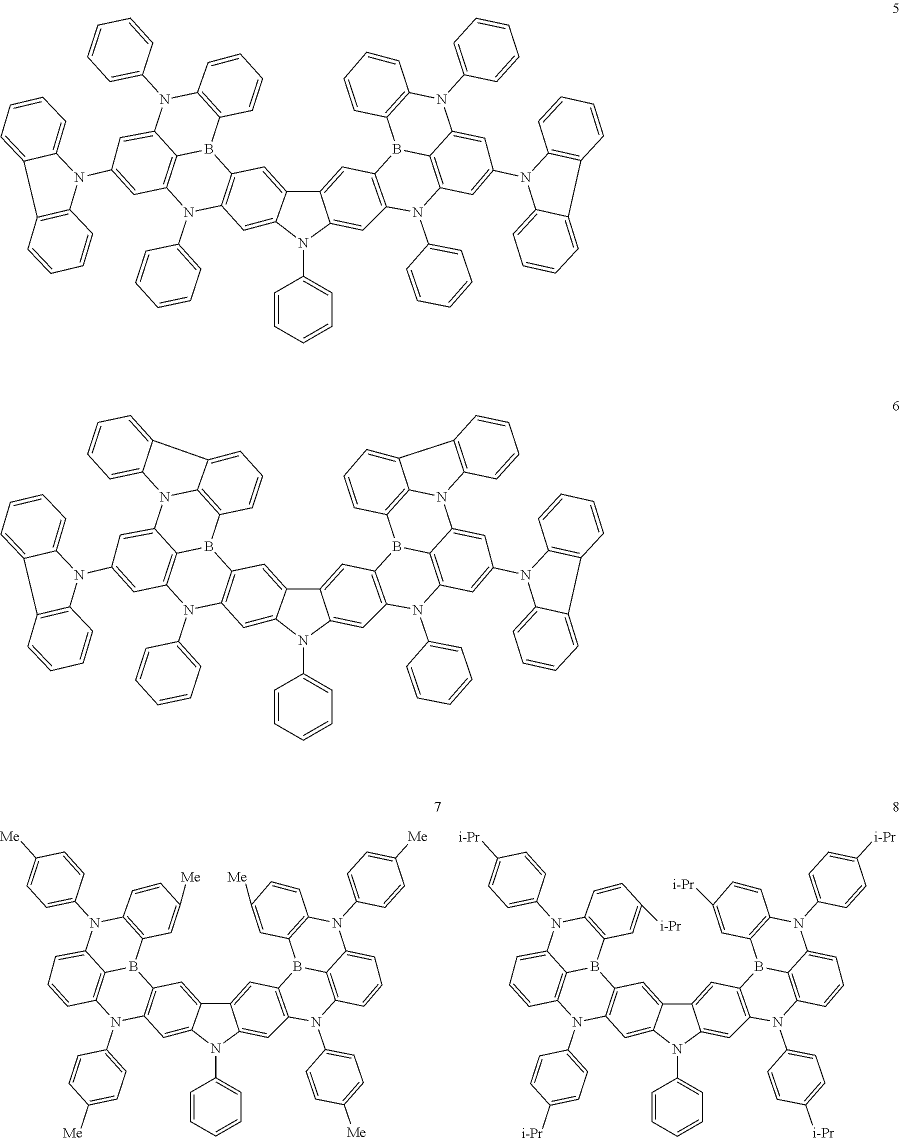 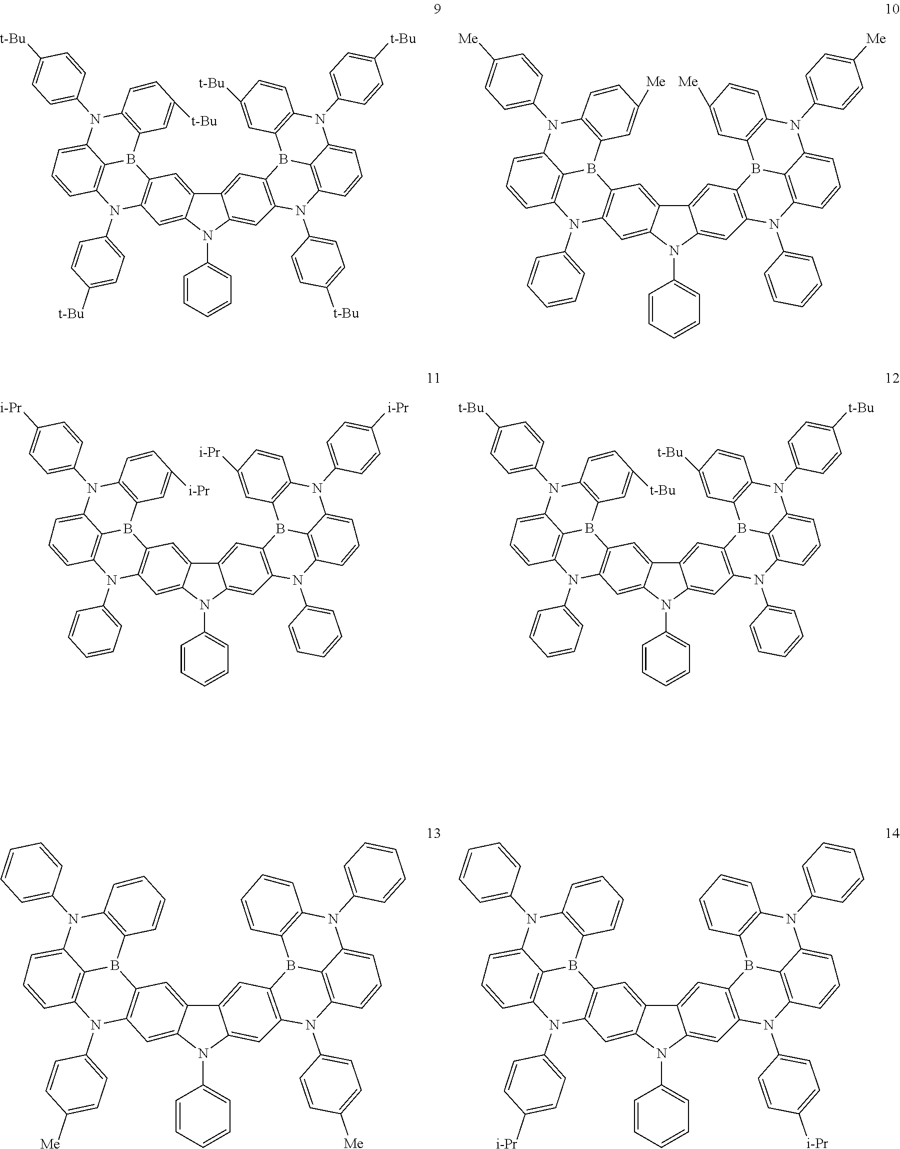 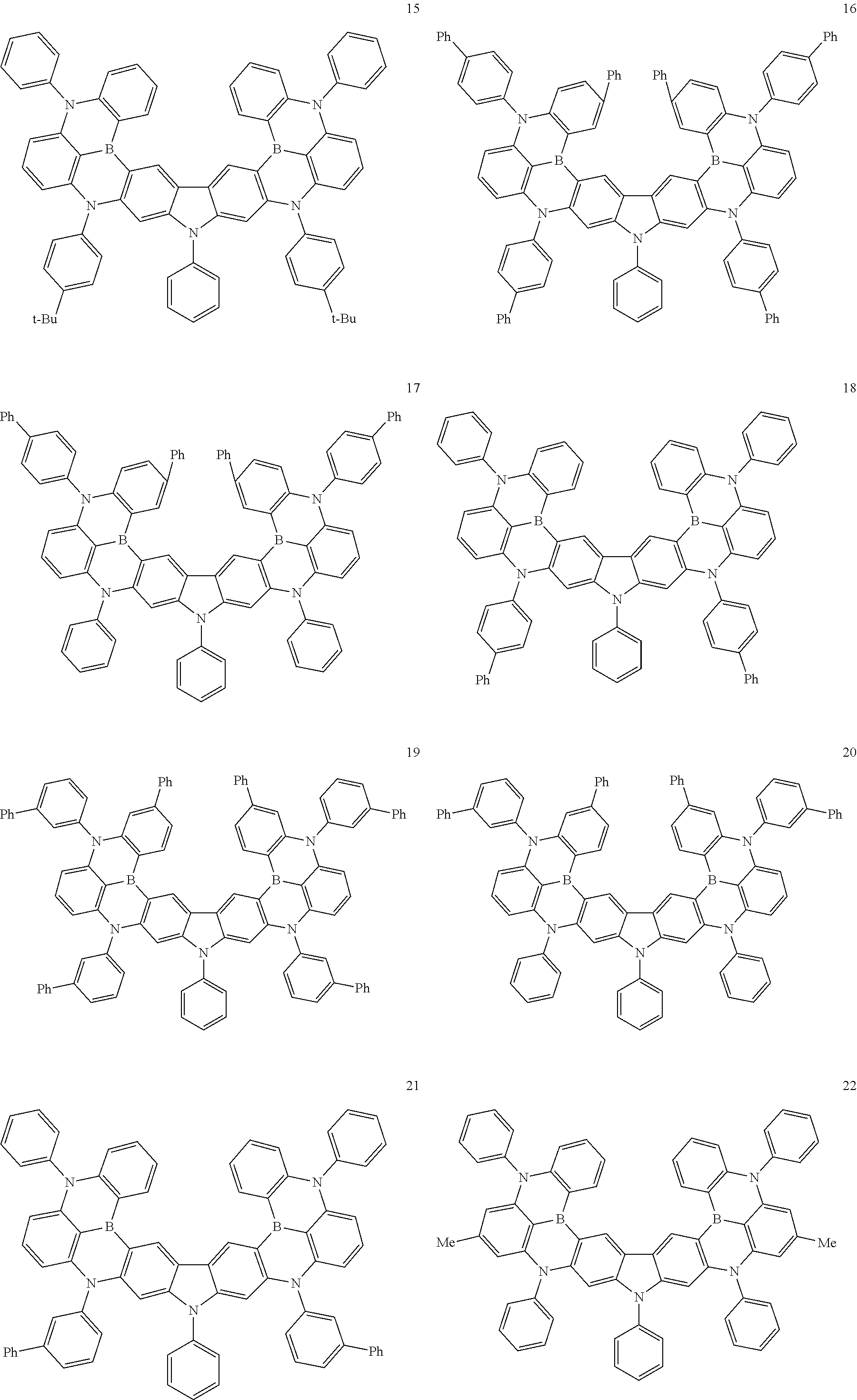 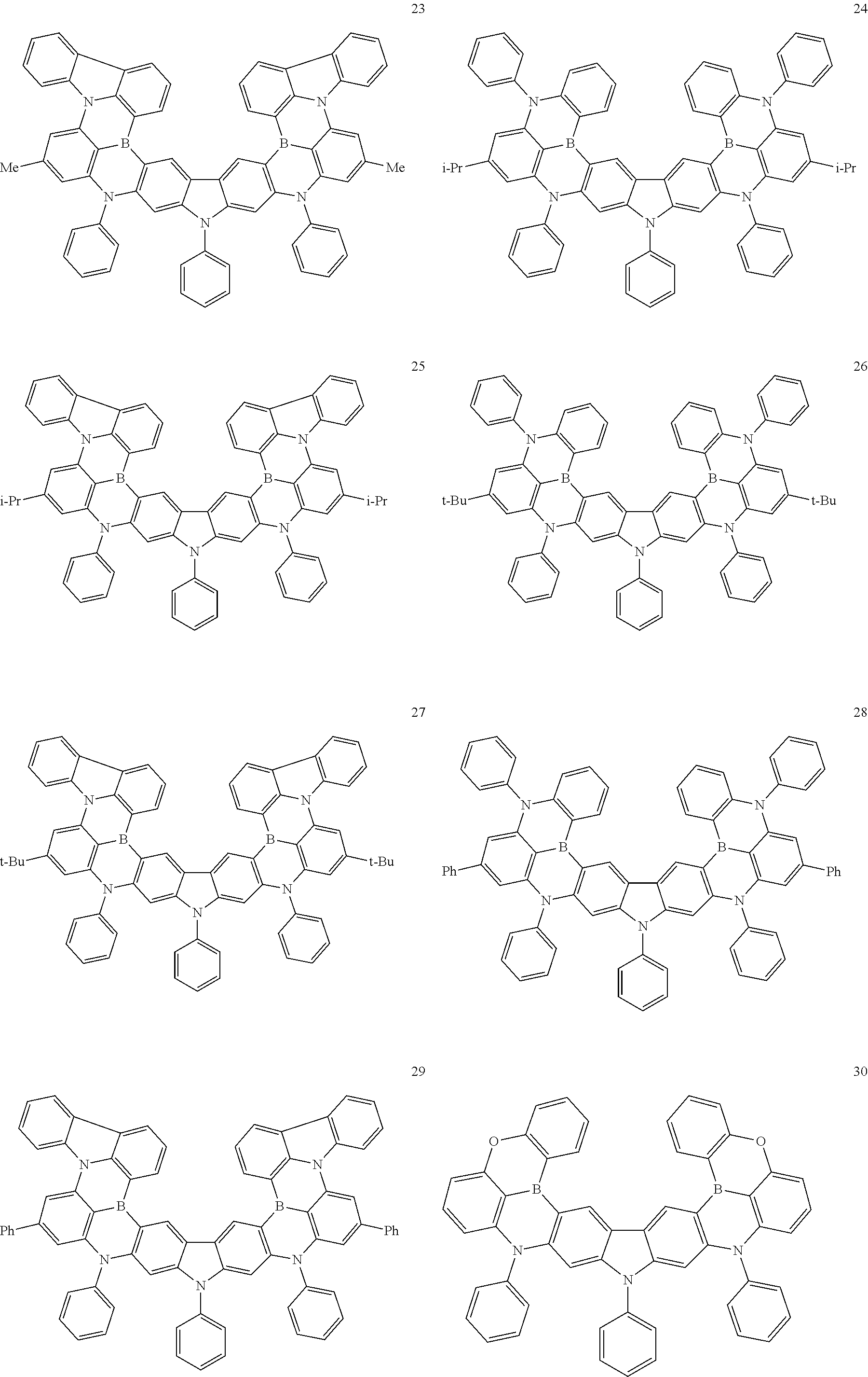 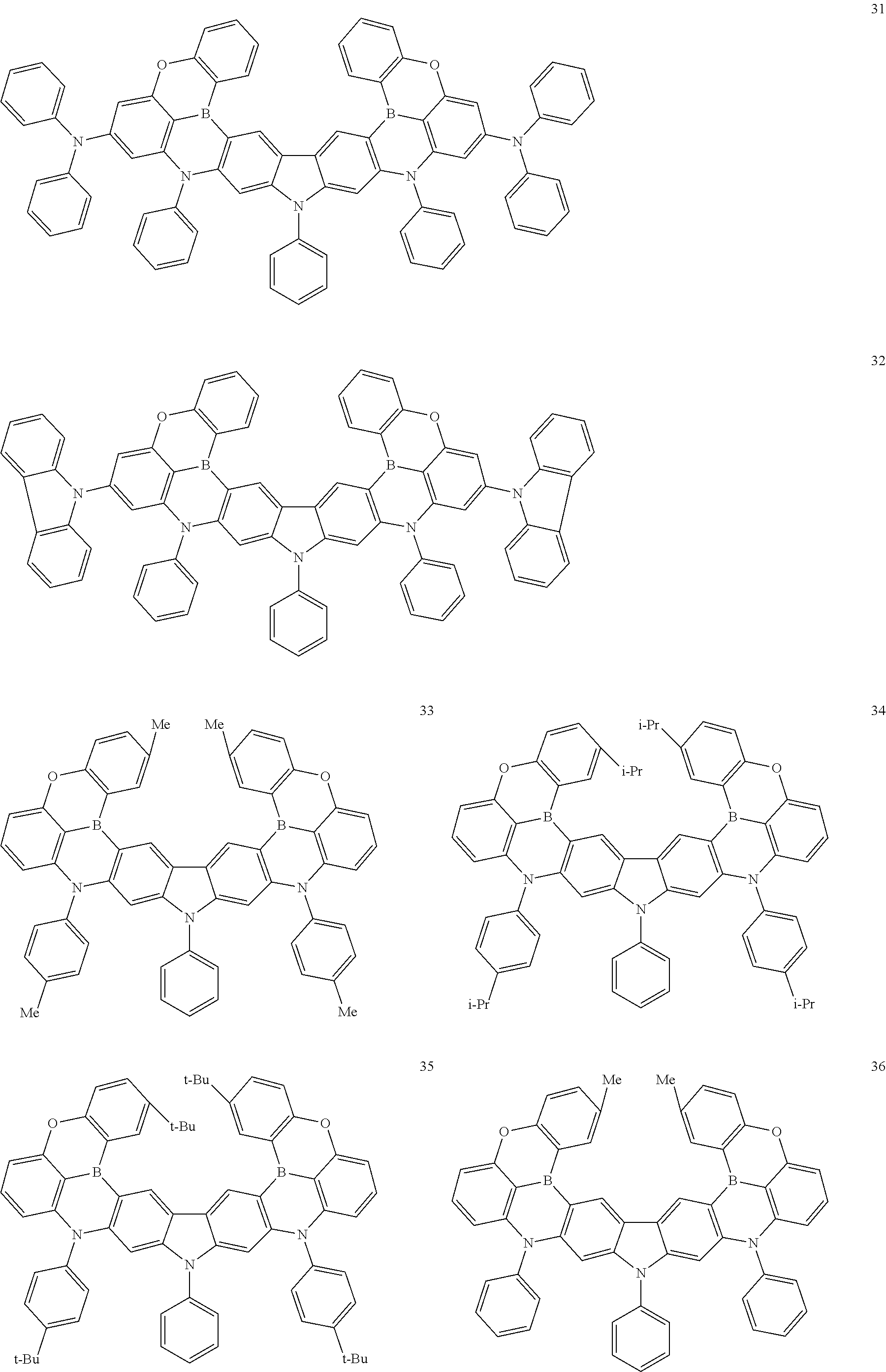 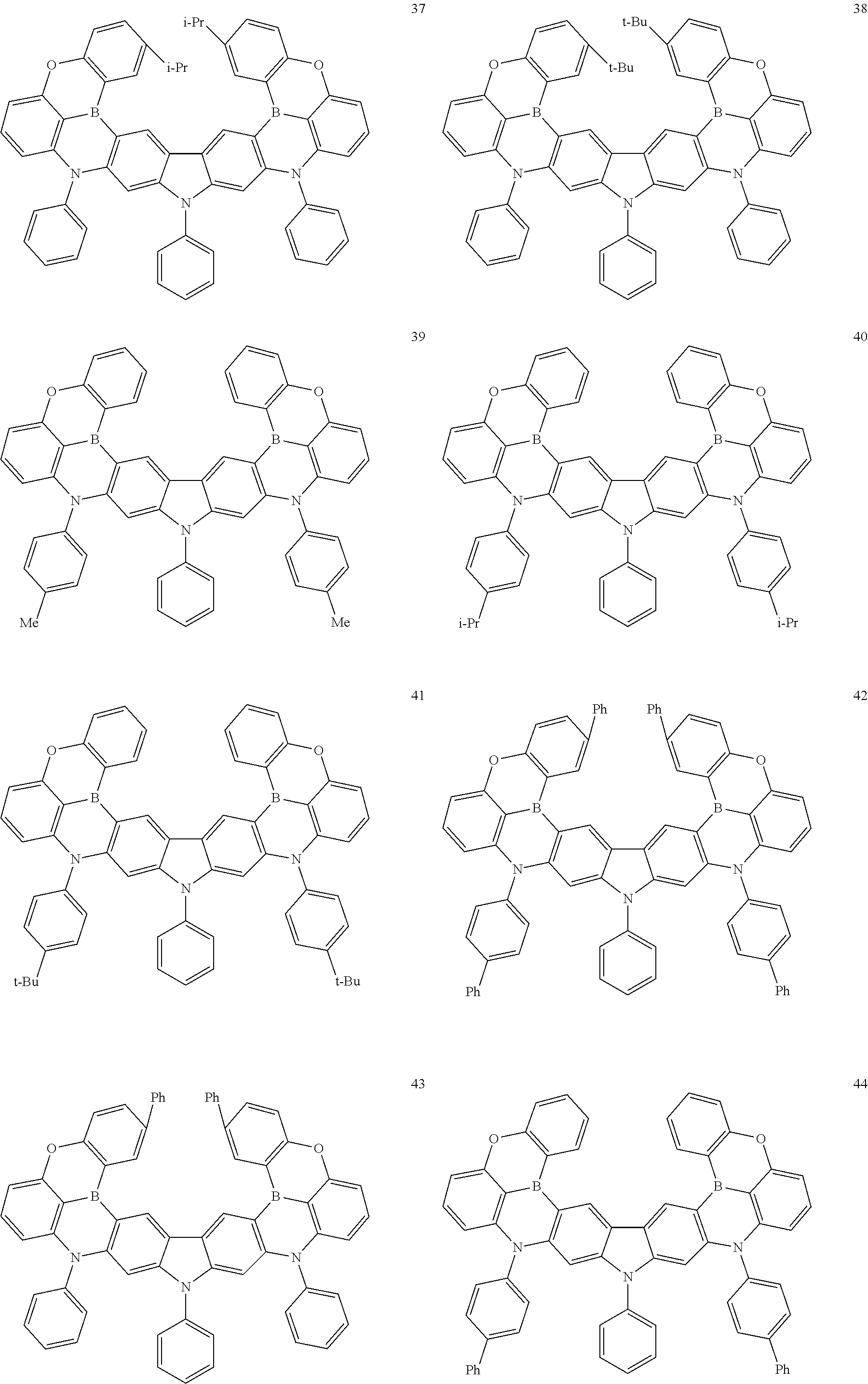 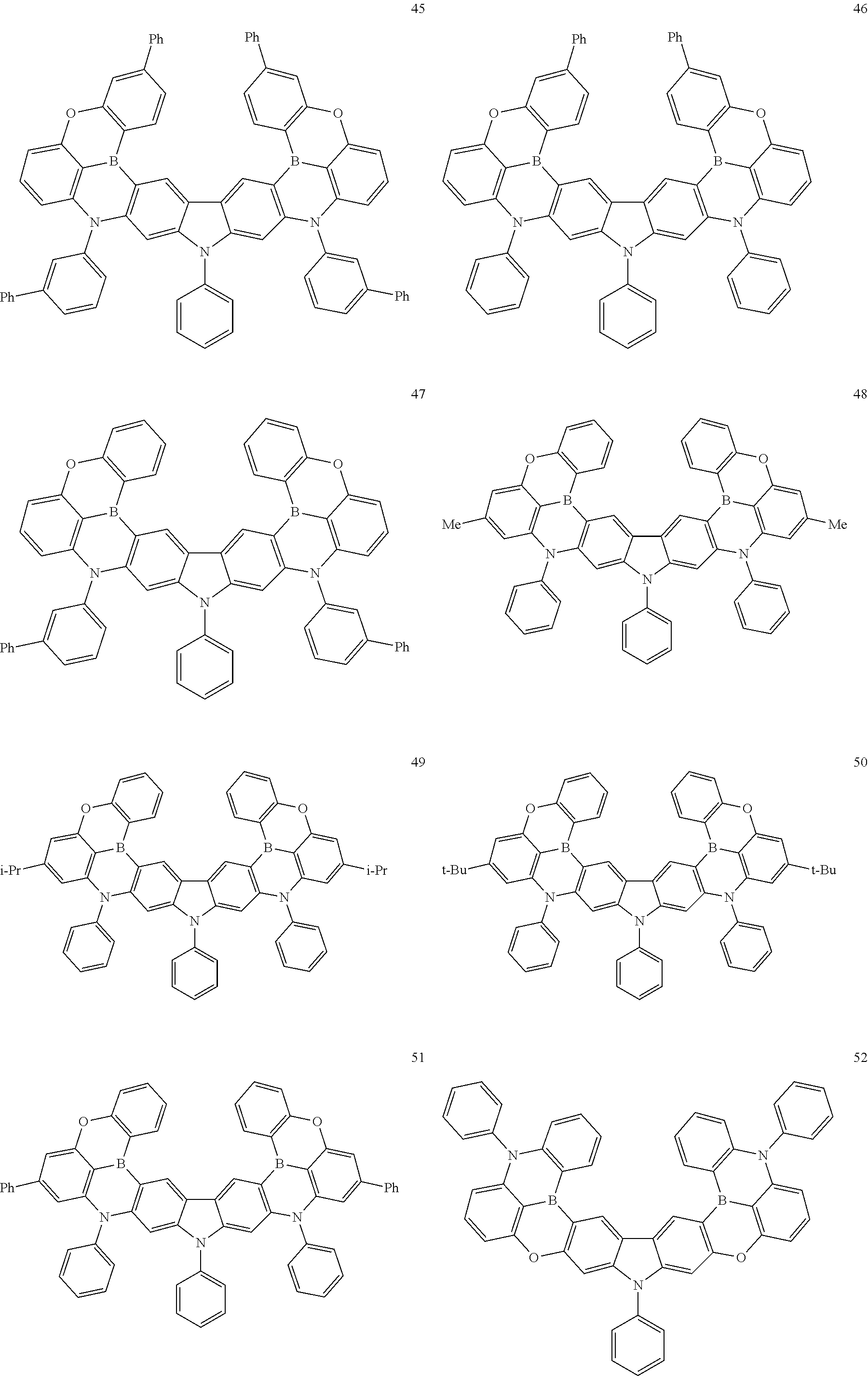 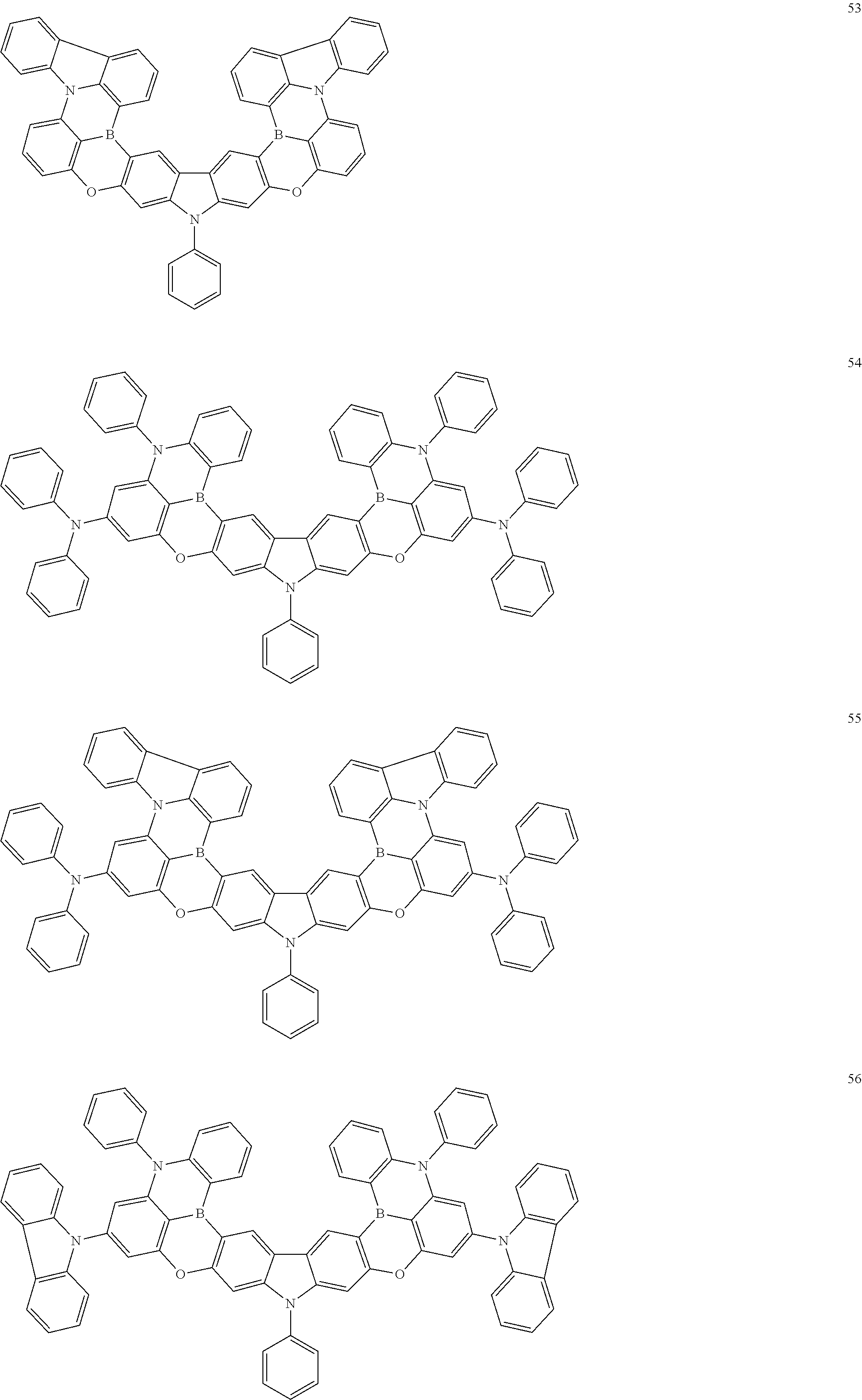 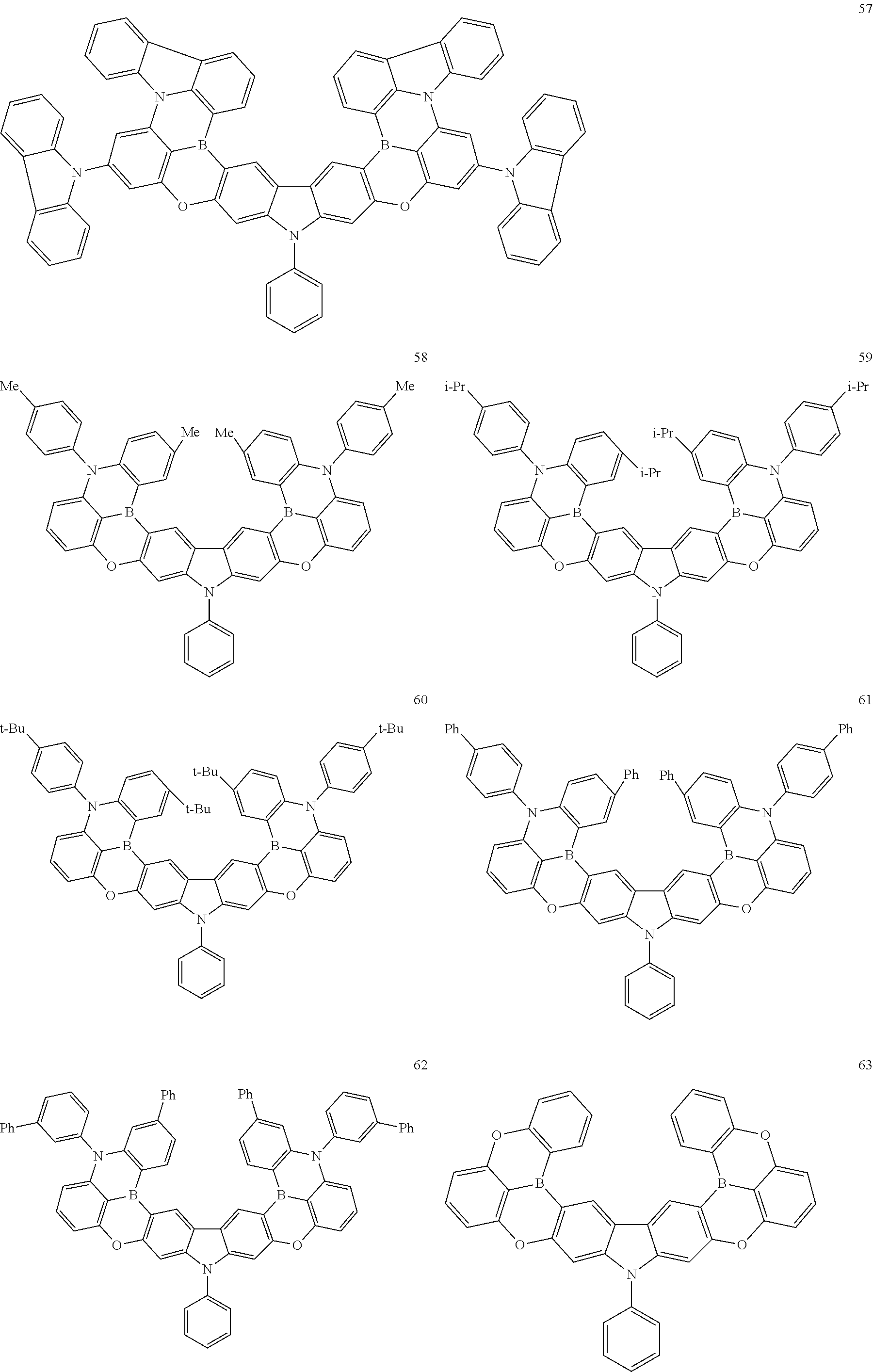 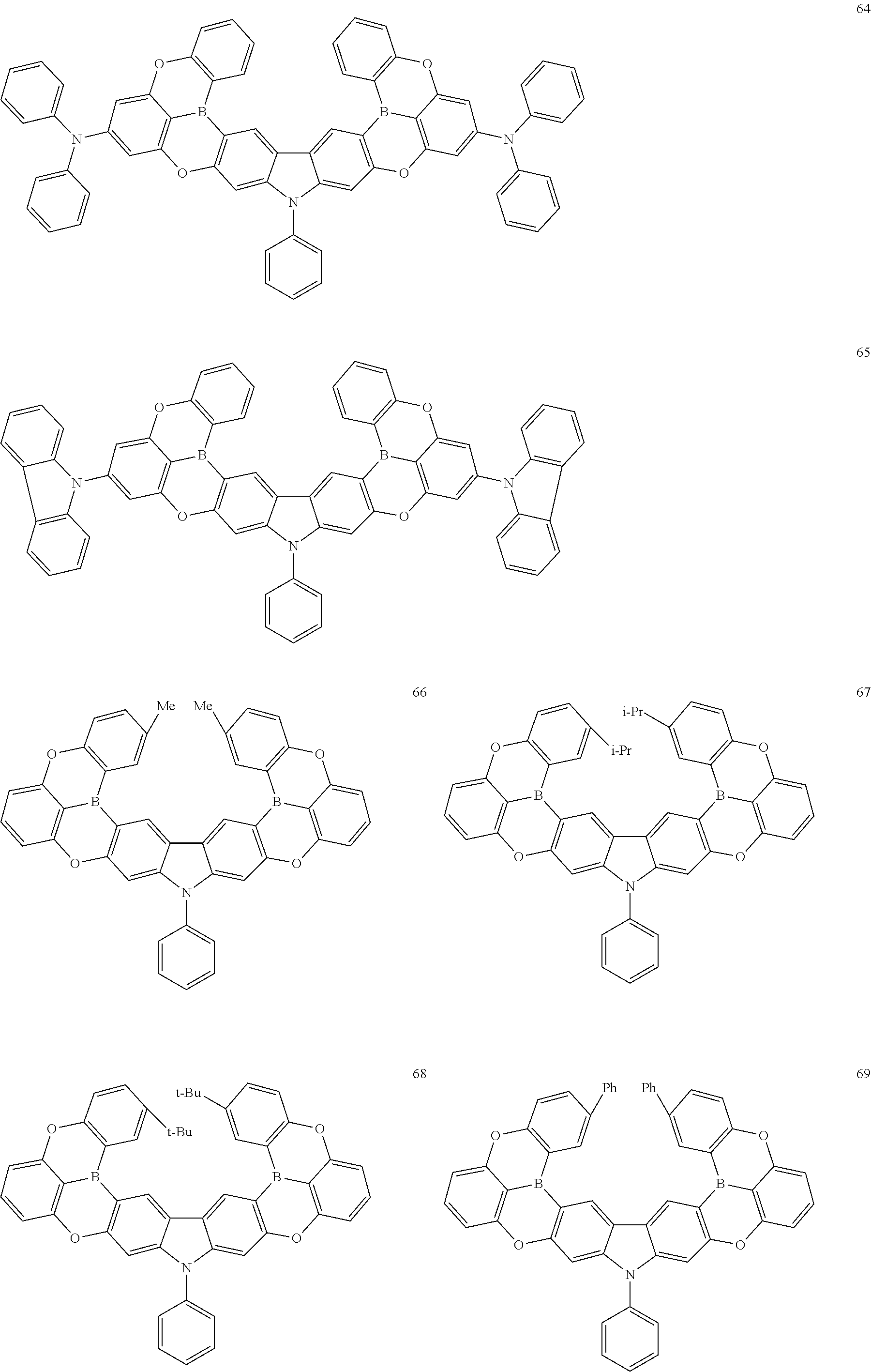 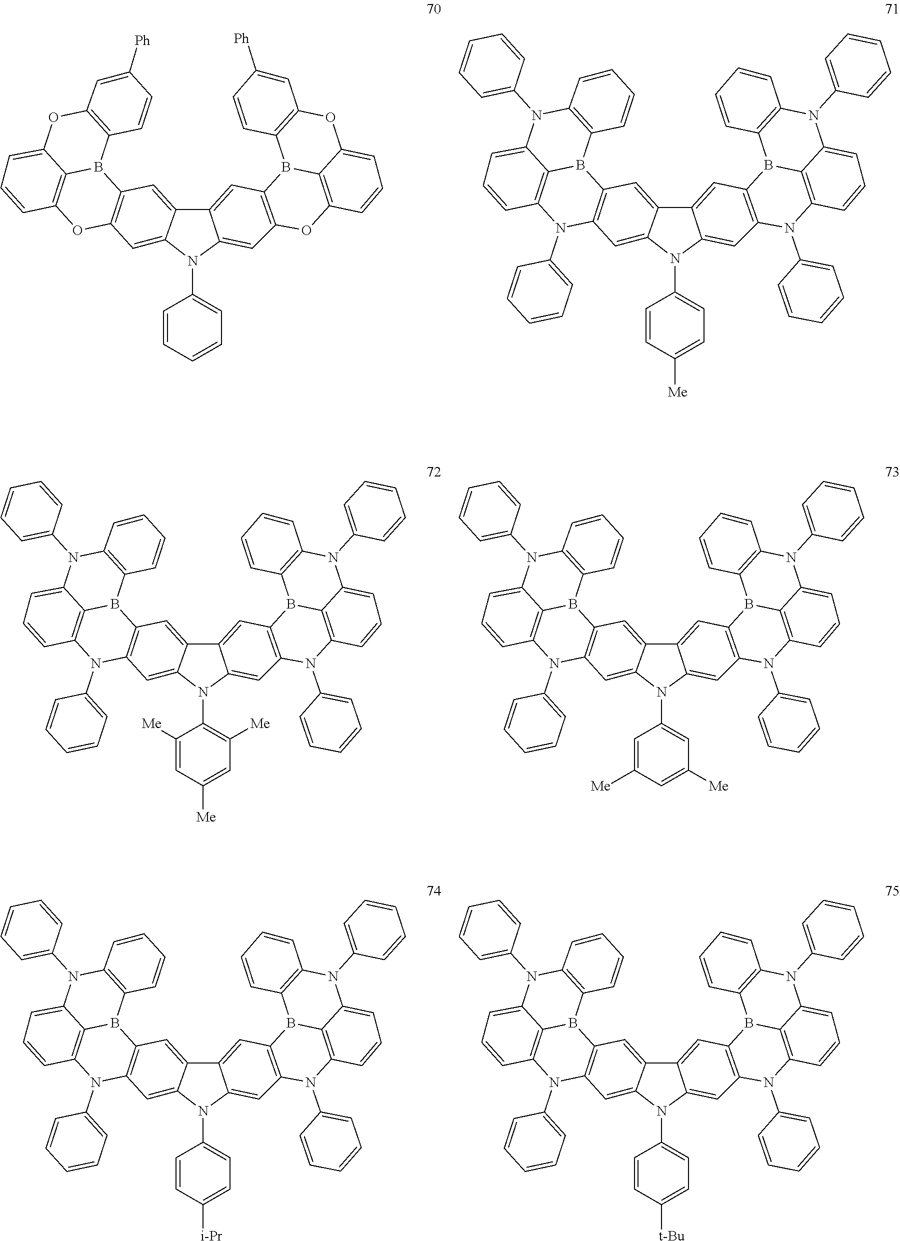 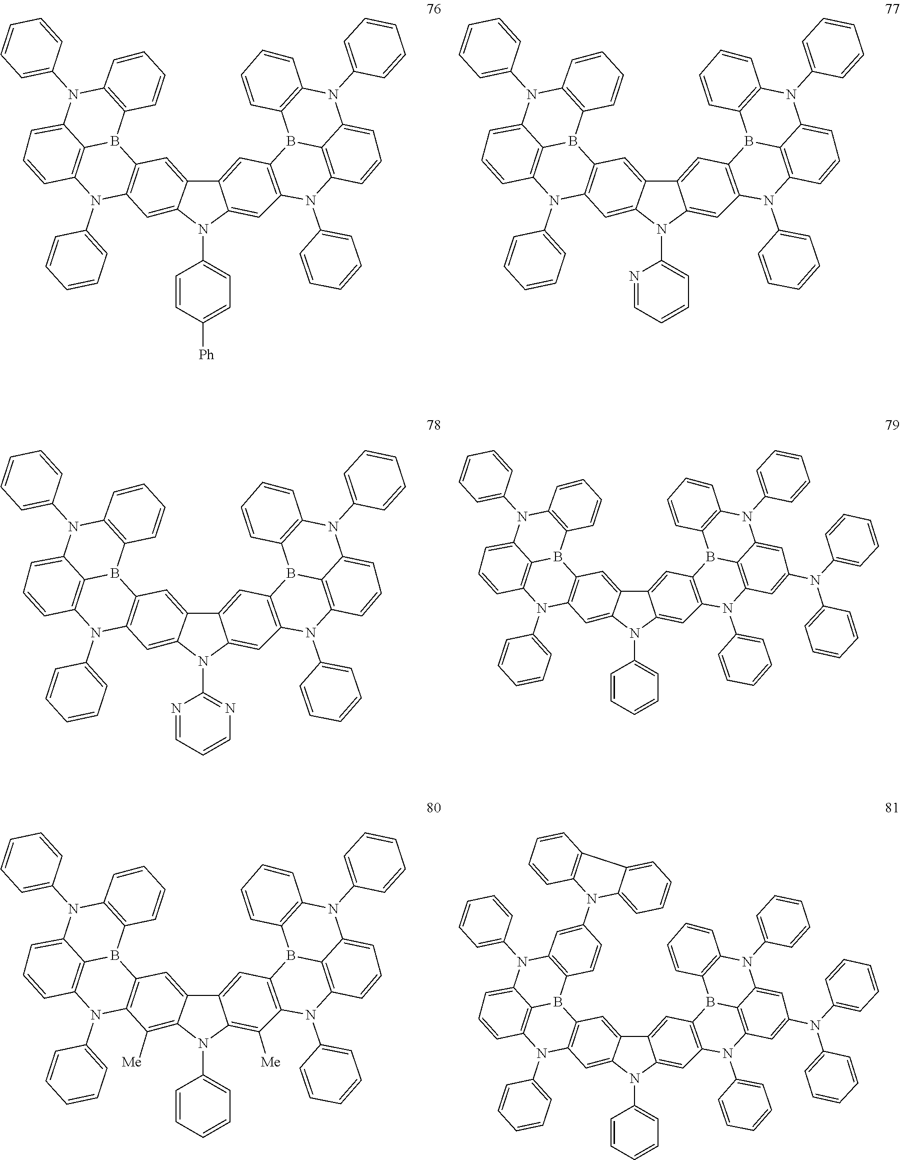 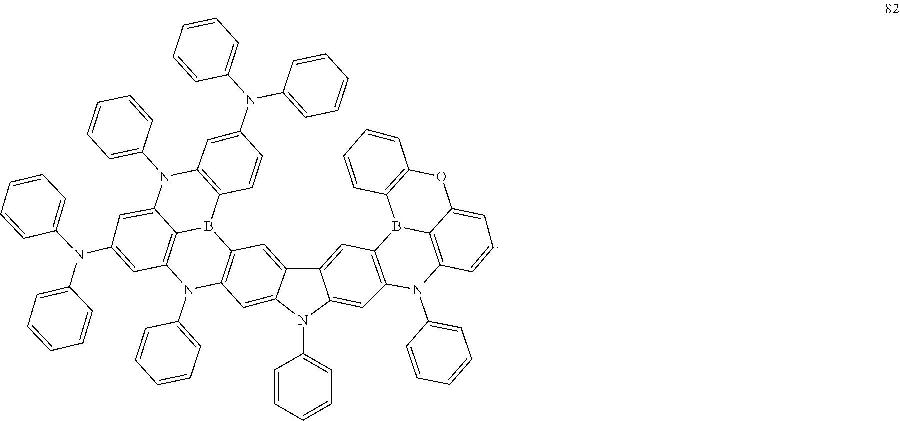 [SMILES: c1ccc(N(c2ccccc2)c2ccc3c(c2)N(c2ccccc2)c2cc(N(c4ccccc4)c4ccccc4)cc4c2B3c2cc3c5cc6c(cc5n(-c5ccccc5)c3cc2N4c2ccccc2)N(c2ccccc2)c2cccc3c2B6c2ccccc2O3)cc1]
